(19) United States
(12) Patent Application Publication
(10) Pub. No.: US 2024/0002281 A1
(43) Pub. Date: Jan. 4, 2024

(54) PRECISION COMPONENT WITH SPECIFIC THERMAL EXPANSION BEHAVIOR

(71) Applicant: Schott AG, Mainz (DE)

(72) Inventor: Ina Mitra, Stadecken-Elsheim (DE)

(73) Assignee: Schott AG, Mainz (DE)

(21) Appl. No.: 18/468,084

(22) Filed: Sep. 15, 2023

Related U.S. Application Data
(63) Continuation of application No. PCT/EP2022/056650, filed on Mar. 15, 2022.

(30) Foreign Application Priority Data
Mar. 16, 2021 (DE) 10 2021 106 417.1
Mar. 16, 2021 (DE) 10 2021 106 419.8
Dec. 22, 2021 (DE) 10 2021 134 308.9
Mar. 15, 2022 (WO) PCT/EP2022/056650

(51) Int. Cl. C03C 10/00

(52) U.S. Cl. CPC C03C 10/0027; C03C 2204/00

(57) ABSTRACT

A precision component has an average coefficient of thermal expansion (CTE) of at most 0±0.1×10⁻⁶/K in a range of from 0 to 50° C. and a thermal hysteresis of <0.1 ppm, at least in a temperature range of from 10° C. to 35° C., and an index F of <1.2, wherein F=TCL (0; 50° C.)/|expansion (0; 50° C.)|. TCL is a total change of length.

### CROSS REFERENCE TO RELATED APPLICATIONS

This is a continuation of International Patent Application No. PCT/EP2022/056650 filed on Mar. 15, 2022, which is incorporated in its entirety herein by reference. International Patent Application No. PCT/EP2022/056650 claims priority to German Patent Application No. 10 2021 134 308.9 filed on Dec. 22, 2021, which is incorporated in its entirety herein by reference. International Patent Application No. PCT/EP2022/056650 also claims priority to German Patent Application No. 10 2021 106 419.8 filed on Mar. 16, 2021, which is incorporated in its entirety herein by reference. International Patent Application No. PCT/EP2022/056650 also claims priority to German Patent Application No. 10 2021 106 417.1 filed on Mar. 16, 2021, which is incorporated in its entirety herein by reference.

### BACKGROUND OF THE INVENTION

### 1. Field of the Invention

The present invention relates to a precision component with a specific thermal expansion behavior and to a glass ceramic with a specific thermal expansion behavior, in particular for precision components.

### 2. Description of the Related Art

Materials and precision components with low thermal expansion or low CTE (coefficient of thermal expansion) are already known in the prior art.

Ceramics, Ti-doped quartz glass and glass ceramics are known as materials for precision components with low thermal expansion in the temperature range around room temperature. Glass ceramics with low thermal expansion are, in particular, lithium aluminum silicate glass ceramics (LAS glass ceramics), which are described, for example, in U.S. Pat. Nos. 4,851,372, 5,591,682, EP 587979 A, U.S. Pat. Nos. 7,226,881, 7,645,714, DE 102004008824 A, and DE 102018111144 A. Other materials for precision components are cordierite ceramics or cordierite glass ceramics.

Such materials are often used for precision components that have to meet particularly stringent requirements in terms of their properties (e.g. mechanical, physical, optical properties). They are used especially in terrestrial and space-based astronomy and earth observation, LCD lithography, microlithography and EUV lithography, metrology, spectroscopy and measurement technology. In this context, it is necessary, in particular, for the components to have an extremely low thermal expansion, depending on the specific application.

In general, the thermal expansion of a material is determined by a static method in which the length of a test specimen is determined at the beginning and at the end of the specific temperature interval, and the average coefficient of expansion a or CTE (coefficient of thermal expansion) is calculated from the difference in length. The CTE is then indicated as the average for this temperature interval, e.g. for the temperature interval of from 0° C. to 50° C. as CTE(0;50) or α(0;50).

In order to meet the ever-increasing requirements, materials have been developed which have a CTE that is better adapted to the field of application of a component formed from the material. For example, the average CTE can be optimized not only for the standard temperature interval CTE(0;50) but, for example, for a temperature interval around the actual application temperature, for example the interval of from 19° C. to 25° C., i.e. CTE(19;25) for certain lithography applications. In addition to determining the average CTE, it is also possible to determine the thermal expansion of a test specimen at very small temperature intervals and thus to represent it as a CTE-T curve. Such a CTE-T curve can optionally have a zero crossing at one or more temperatures, optionally at or near the planned application temperature. At a zero crossing of the CTE-T curve, the relative change in length in the case of a temperature change is particularly small. In the case of some glass ceramics, such a zero crossing of the CTE-T curve can be shifted to the application temperature of the component by suitable temperature treatment. In addition to the absolute CTE value, the slope of the CTE-T curve around the application temperature should also be as small as possible in order to ensure the smallest possible change in the length of the component in the case of slight temperature changes. The above-described optimizations of the CTE or of the thermal expansion in these special zero-expansion glass ceramics are generally carried out by varying the ceramization conditions, while the composition remains the same.

A disadvantageous effect in the case of the known precision components and materials, in particular in the case of glass ceramics such as LAS glass ceramics, is “thermal hysteresis”, hereinafter referred to as “hysteresis” for short. Here, hysteresis means that the change in length of a test specimen during heating at a constant heating rate differs from the change in length of the test specimen during subsequent cooling at a constant cooling rate, even if the absolute value of the cooling rate and the heating rate is the same. If the change in length is represented graphically as a function of the temperature for heating or cooling, a classic hysteresis loop is obtained. Here, the character of the hysteresis loop also depends on the rate of the temperature change. The faster the temperature change occurs, the more pronounced the hysteresis effect. The hysteresis effect makes it clear that the thermal expansion of an LAS glass ceramic is dependent on temperature and on time, i.e., for example, on the rate of temperature change, and this has already been described in isolated instances in the technical literature, e.g., O. Lindig and W. Pannhorst, “Thermal expansion and length stability of ZERODUR® in dependence on temperature and time”, APPLIED OPTICS, Vol. 24, No. 20, October 1985; R. Haug et al., “Length variation in ZERODUR® M in the temperature range from −60° C. to +100° C.”, APPLIED OPTICS, Vol. 8, No. 19, October 1989; R. Jedamzik et al., “Modeling of the thermal expansion behavior of ZERODUR® at arbitrary temperature profiles”, Proc. SPIE Vol. 7739, 2010; D. B. Hall, “Dimensional stability tests over time and temperature for several low-expansion glass ceramics”, APPLIED OPTICS, Vol. 35, No. 10, April 1996.

Since the change in length of a glass ceramic exhibiting thermal hysteresis lags behind or is in advance of the change in temperature, the material or a precision component produced therefrom exhibits a disturbing isothermal change in length, i.e. after a change in temperature, a change in length of the material continues to occur at the time when the temperature is already being kept constant (referred to as “isothermal holding”), to be precise until a stable state is reached. If the material is then reheated and recooled, the same effect occurs again.

With the previously known LAS glass ceramics, it has hitherto not been possible to eliminate the effect of thermal hysteresis without other properties being affected, despite variation of the ceramization conditions with a constant composition.

In respect of the properties of materials, in particular glass ceramics, for use in precision components, a temperature range of from 0° C. to 50° C., in particular from 10° C. to 35° C. or from 19° C. to 25° C., is often relevant, a temperature of 22° C. generally being referred to as room temperature. Since many applications of precision components occur in the temperature range of from greater than 0° C. to room temperature, materials with thermal hysteresis effects and isothermal changes in length are disadvantageous since optical disturbances may occur, for example, in the case of optical components such as lithography mirrors and astronomical or space-based mirrors. In the case of other precision components made of glass ceramic that are used in measurement technology (e.g. precision rules, reference plates in interferometers), measurement inaccuracies may thus be caused.

Some known materials such as ceramics, Ti-doped quartz glass and certain glass ceramics are distinguished by an average coefficient of thermal expansion CTE (0;50) of 0±0.1×10⁻⁶/K (corresponding to 0±0.1 ppm/K). Materials which have such a low average CTE in the temperature range mentioned are referred to as zero-expansion materials for the purposes of this invention. However, glass ceramics, in particular LAS glass ceramics, the average CTE of which is optimized in this way, generally have a thermal hysteresis in the temperature range of from 10° C. to 35° C. That is to say that, particularly in the case of applications around room temperature (i.e. 22° C.), a disturbing hysteresis effect occurs in these materials, which impairs the accuracy of precision components produced with such a material. A glass ceramic material was therefore developed (see U.S. Pat. No. 4,851,372) which has no significant hysteresis at room temperature, although the effect is not eliminated but was only shifted to lower temperatures, with the result that this glass ceramic exhibits a distinct hysteresis at temperatures of 10° C. and below, which can also have a disturbing effect. In order to characterize the thermal hysteresis of a material in a certain temperature range, the thermal behavior of the materials for different temperature points in this range is therefore considered within the scope of this invention. There are even glass ceramics which do not show any significant hysteresis at 22° C. and at 5° C., but these glass ceramics have an average CTE (0;50) of >0±0.1 ppm/K, i.e. they are not zero-expansion glass ceramics in the sense of the above-mentioned definition.

A further requirement on a glass ceramic material is good meltability of the glass components as well as simple management of melting and homogenization of the underlying glass melt in large-scale industrial production plants in order—after ceramization of the glass—to meet the high demands on the glass ceramic with regard to CTE homogeneity, internal quality—especially a small number of inclusions (particularly bubbles), low level of stria—and polishability, etc.

What is needed in the art is a way to provide a precision component having an improved expansion behavior, as well as a way to provide a glass ceramic that could be produced on an industrial scale and has zero expansion and a reduced thermal hysteresis, in particular in the temperature range of from 10° C. to 35° C., in particular for a precision component.

### SUMMARY OF THE INVENTION

According to one aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and a index F of <1.2, wherein F=TCL (0; 50° C.)/|expansion (0; 50° C.)|.

According to another aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and an alternative index f_{T.i.} selected from the group comprising alternative index f_{(20;40)}<0.024 ppm/K, alternative index f_{(20;70)}<0.039 ppm/K, alternative index f_{(-10;30)}><0.015 ppm/K.

According to a further aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and a index F of <1.2, wherein F=TCL (0; 50° C.)/|expansion (0; 50° C.)|, and at least one inorganic material selected from the group comprising doped quartz glass, glass ceramic and ceramic, optionally Ti-doped quartz glass, LAS glass ceramic and cordierite.

According to a further aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and an alternative index f_{T.i.} selected from the group comprising alternative index f_{(20;40)}<0.024 ppm/K, alternative index f_{(20;70)}<0.039 ppm/K, alternative index f_{(-10;30)}0<0.015 ppm/K, and at least one inorganic material selected from the group comprising doped quartz glass, glass ceramic and ceramic, optionally Ti-doped quartz glass, LAS glass ceramic and cordierite.

According to a further aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and a index F of <1.2, wherein F=TCL (0; 50° C.)/|expansion (0; 50° C.)|, wherein the precision component comprises an LAS glass ceramic provided according to the invention.

According to a further aspect, the invention relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and an alternative index f_{T.i.} selected from the group comprising alternative index f_{(20;40)}<0.024 ppm/K, alternative index f_{(20;70)}<0.039 ppm/K, alternative index f_{(-10;30)})<0.015 ppm/K, wherein the precision component comprises an LAS glass ceramic provided according to the invention.

According to a further aspect, the invention relates to a precision component provided according to the invention, which is selected from the group comprising astronomical mirrors and mirror supports for segmented or monolithic astronomical telescopes; reduced-weight or ultralight mirror substrates for, for example, space-based telescopes; high-precision structural components for distance measurement, for example in space; optics for earth observation; precision components, such as standards for precision measurement technology, precision rules, reference plates in interferometers; mechanical precision parts, for example for ring laser gyroscopes, spiral springs for the watch and clock making industry; mirrors and prisms in LCD lithography; mask holders, wafer tables, reference plates, reference frames and grid plates in microlithography and in EUV (extreme UV) microlithography, in which reflective optics are used; mirrors and/or photomask substrates or reticle mask blanks or mask blanks in EUV microlithography; and components for metrology and spectroscopy.

According to a further aspect, the invention relates to a substrate for an EUV microlithography mirror (also called “EUVL mirror”) comprising a precision component provided according to the invention.

According to a further aspect, the invention relates to an EUV microlithography mirror (also called “EUVL mirror”) comprising a precision component provided according to the invention, wherein this component has a relative change in length (dl/l₀) of <|0.10|ppm, optionally of ≤|0.09| ppm, optionally of <10.08| ppm and optionally of <10.07| ppm in the temperature range of from 20° C. to 30° C. and/or a relative change in length (dl/l₀) of <10.17| ppm, optionally of ≤|0.151 ppm, optionally of ≤|0.131 ppm and optionally of ≤|0.111 ppm in the temperature range of from 20° C. to 35° C. and/or wherein it has a relative change in length (dl/l₀) of ≤|0.301 ppm, optionally of ≤|0.251 ppm, optionally of ≤|0.201 ppm and optionally of <10.151 ppm in the temperature range of from 20° C. to 40° C.

According to a further aspect of the invention, an LAS glass ceramic is provided, in particular for a precision component provided according to one aspect of the invention, which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and which comprises the following components (in mol % on an oxide basis):

at least one component selected from the group comprising P₂O₅, R₂O, wherein R₂O may be Na₂O and/or K₂O and/or Cs₂O and/or Rb₂O, and RO, wherein RO may be CaO and/or BaO and/or SrO, nucleating agent having a content of 1.5 to 6 mol %, wherein the nucleating agent is at least one component selected from the group comprising TiO₂, ZrO₂, Ta₂O₅, Nb₂O₅, SnO₂, MoO₃, WO₃.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 shows CTE-T curves of materials known from the prior art with low thermal linear expansion for, for example, precision components;

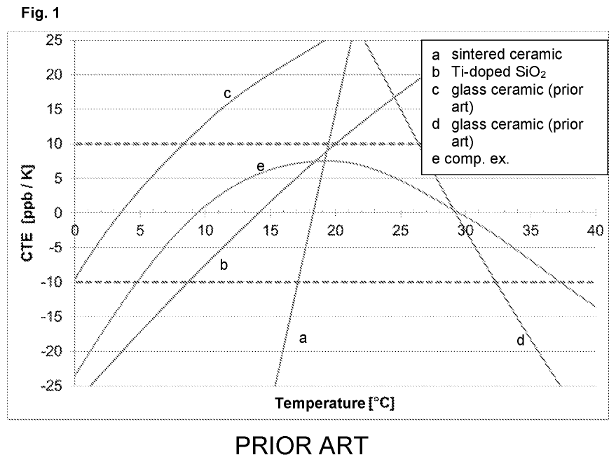

FIG. 2 shows the hysteresis behavior of three glass ceramic samples determined by the same method as that which is also used in the present invention, which illustration is from R. Jedamzik et al., “Modeling of the thermal expansion behavior of ZERODUR® at arbitrary temperature profiles”, Proc. SPIE Vol. 7739, 2010;

FIGS. 3 to 8 show hysteresis curves of known materials of glass ceramics which can be used for the production of known precision components, and which have a thermal hysteresis of >0.1 ppm, at least in the temperature range of from 100 to 35° C. (dashed=cooling curve, dotted=heating curve);

FIG. 9 shows the hysteresis curve (dashed=cooling curve, dotted=heating curve) of a prior art glass ceramic which can be used to produce a precision component, and which has a thermal hysteresis of <0.1 ppm, at least in the temperature range of from 10-35° C., but the steep curve profile shows that the glass ceramic is not a zero-expansion glass ceramic;

FIGS. 10 to 11 show hysteresis curves of precision components provided according to the invention or glass ceramics provided according to the invention (compositions in accordance with examples 6 and 7 in Table 1a), which have a thermal hysteresis of <0.1 ppm, at least in the temperature range of from 100-35° C. (dashed=cooling curve, dotted=heating curve);

FIGS. 12 and 13 show standardized Δl/l₀-T curves (also called dl/l₀ curves) of precision components provided according to the invention and glass ceramics (compositions in accordance with examples 6 and 7 in Table 1a) and auxiliary lines for determining the index F as a measure of the flatness of the expansion curve in the temperature range of from 0° C. to 50° C.;

FIGS. 14 to 17 show standardized Δl/l₀-T curves of known materials, which can be used to produce known precision components, and auxiliary lines for determining the index F as a measure of the flatness of the expansion curve in the temperature ranges of from −20° C. or −10° C. to 70° C. or 80° C.;

FIG. 18 shows standardized Δl/l₀-T curves of the precision components or glass ceramics of FIGS. 12 and 13 in the temperature range of from −30° C. to +70° C.;

FIG. 19 shows standardized Δl/l₀-T curves of known materials in the temperature range of from −30° C. to +70° C.;

FIGS. 20 and 21 show that the CTE-T curves of precision components or glass ceramics of FIGS. 12 and 13 advantageously have a CTE plateau;

FIGS. 22 and 23 show the slopes of CTE-T curves from FIGS. 24 and 25;

FIGS. 24 and 25 show different CTE curves for two examples of composition provided according to the invention, set by different ceramization parameters;

FIG. 26 shows the slope of a CTE-T curve of a precision component or glass ceramic, wherein the glass ceramic has a composition according to example 17 in Table 1a;

FIG. 27 shows a standardized Δl/l₀-T curve of a precision component provided according to the invention or glass ceramic (composition according to example 17 in Table 1a) and auxiliary lines for determining the alternative index f_{(20;40)} as a measure of the flatness of the expansion curve in the temperature range of from 20° C. to 40° C.;

FIG. 28 shows a standardized Δl/l₀-T curve of the precision component or glass ceramic of FIG. 13 and auxiliary lines for determining the alternative index f_{(-10;30)} as a measure of the flatness of the expansion curve in the temperature range of from −10° C. to 30° C.;

FIG. 29 shows a standardized Δl/l₀-T curve of the precision component or glass ceramic of FIG. 13 and auxiliary lines for determining the alternative index f_{(20;70)} as a measure of the flatness of the expansion curve in the temperature range of from 20° C. to 70° C.;

FIG. 30 shows a standardized Δl/l₀-T curve of a precision component provided according to the invention or glass ceramic (composition according to example 14 in Table 1a) and auxiliary lines for determining the alternative index f_{(-10;30)}) as a measure of the flatness of the expansion curve in the temperature range of from −10° C. to 30° C.;

FIGS. 31 to 33 show hysteresis curves of precision components provided according to the invention or glass ceramics provided according to the invention (compositions in accordance with example 2b, example 6b, and example 7b in Table 1b), which have a thermal hysteresis of <0.1 ppm, at least in the temperature range of from 100-35° C. (dashed=cooling curve, dotted=heating curve);

FIG. 34 shows a standardized Δl/l₀-T curve (also referred to as a dl/l₀ curve) of a precision component provided according to the invention or glass ceramic (compositions in accordance with example 7b in Table 1b) and auxiliary lines for determining the index F as a measure of the flatness of the expansion curve in the temperature range of from 0° C. to 50° C.;

FIG. 35 shows another standardized Δl/l₀-T curve of a precision component provided according to the invention or glass ceramic (composition according to example 7b in Table 1b) based on another ceramization and auxiliary lines for determining the alternative index f_{(20;70)} as a measure of the flatness of the expansion curve in the temperature range of from 20° C. to 70° C.;

FIG. 36 shows a standardized Δl/l₀-T curve (also referred to as a dl/l₀ curve) of a precision component provided according to the invention or a glass ceramic (compositions in accordance with example 6b in Table 1b) and auxiliary lines for determining the alternative index f_{(-10;30)} as a measure of the flatness of the expansion curve in the temperature range of from −10° C. to 30° C.;

FIGS. 37, 39 and 41 show that the CTE-T curves of precision components or glass ceramics (compositions in accordance with example 6b, example 7b and example 9b in Table 1b), which can be used to produce advantageous precision components, advantageously have a CTE “plateau”;

FIGS. 38 and 40 show segments of FIGS. 37 and 39, respectively;

FIGS. 42 and 43 show slopes of CTE-T curves of precision components or glass ceramics with compositions in accordance with examples 6b and 7b in Table 1b; and

FIGS. 44 and 45 show different expansion curves for precision components or glass ceramics with compositions in accordance with example 6b and example 7b in Table 1b, set by different ceramization parameters.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

First, the precision component provided according to the invention and its properties are described, followed by an LAS glass ceramic provided according to the invention, which can be used, in particular, for the production of a precision component, wherein the description of advantageous properties according to the invention of the precision component also applies in corresponding fashion to the LAS glass ceramic provided according to the invention (hereinafter referred to as “glass ceramic” for short) and its advantageous further developments.

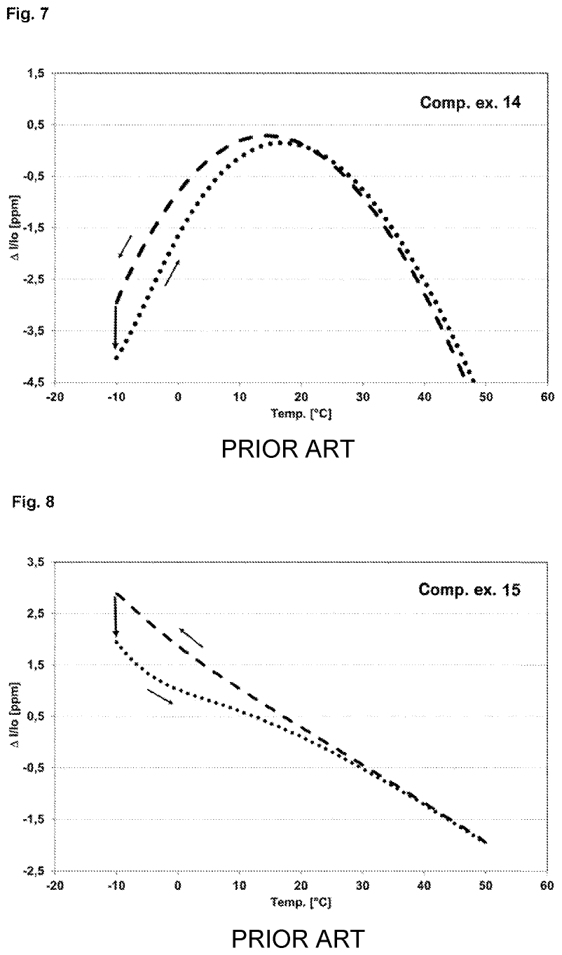

Within the scope of the invention, a precision component that combines a number of relevant properties is provided for the first time: it has an average coefficient of thermal expansion CTE of at most ±0.1×10⁻⁶/K in the range of from 0° to 50° C., i.e. it has zero expansion. In addition, it has a thermal hysteresis of <0.1 ppm, at least in the temperature range of from 10° C. to 35° C., based on a heating rate and cooling rate of 36 K/h in each case, corresponding to 0.6 K/min (see FIGS. 10 and 11 and FIGS. 31 to 33). A precision component with such a low hysteresis effect is referred to as hysteresis-free.

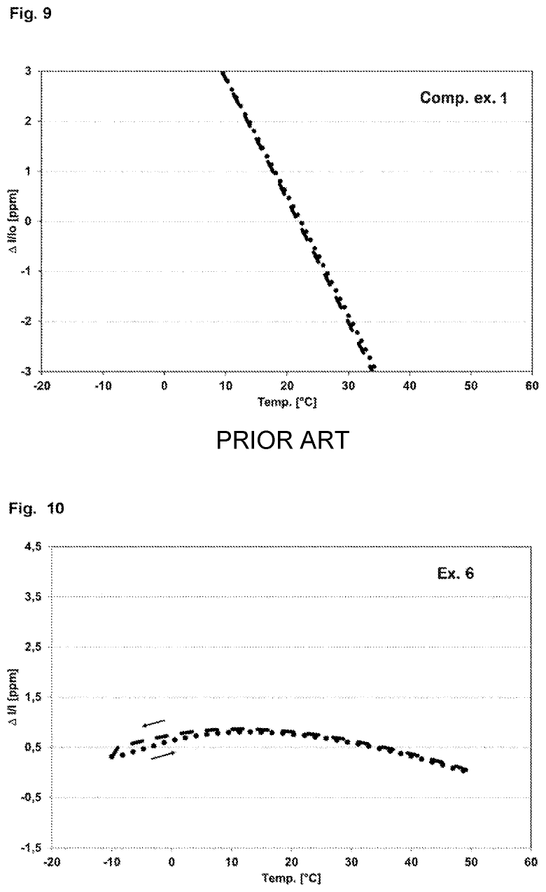

According to some embodiments provided according to the invention, the precision component furthermore has a index F of <1.2, based on a temperature range of from 0° C. to 50° C., where F=TCL (0; 50° C.)/|expansion (0; 50° C.)|. That is to say that the expansion curve (that is to say the Δl/l₀-T curve) shows a flat profile in this temperature range (see, for example, FIGS. 12, 13, 27 and 34).

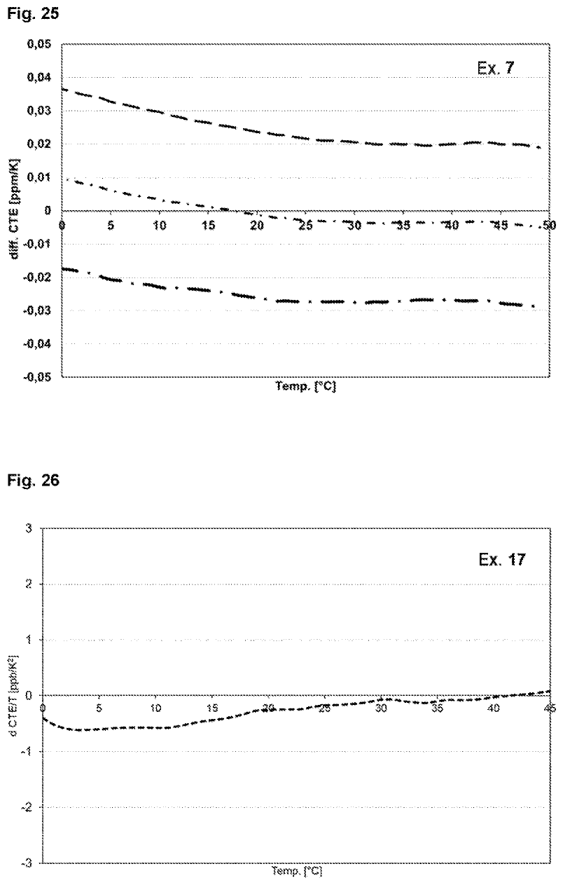

According to some embodiments provided according to the invention, the precision component furthermore has an alternative index f_{T.i.}, selected from the group comprising alternative index f_{(20;40)}<0.024 ppm/K, alternative index f_{(20;70)}<0.039 ppm/K, alternative index f_{(-10;30})><0.015 ppm/K (see, for example, FIGS. 27 to 30, 35 and 36).

CTE

The precision components and glass ceramics provided according to the invention have zero expansion, i.e. they have an average coefficient of thermal expansion CTE of at most 0±0.1×10⁻⁶/K in the range of from 0° to 50° C. Some variants even have an average CTE of at most 0±0.05×10⁻⁶/K in the range of from 0 to 50° C. For certain applications, it may be advantageous if the average CTE is at most 0±0.1×10⁻⁶/K within a relatively wide temperature range, for example in the range of from −30° C. to +70° C., optionally in the range of from −40° C. to +80° C., i.e. there is zero expansion.

To determine the CTE-T curve of the glass ceramics and precision components provided according to the invention and of the comparative examples, the differential CTE(T) is first determined. The differential CTE(T) is determined as a function of temperature. The CTE is then defined according to the following formula (1):

CTE(T)=(1/l₀)×(∂l/∂T) (1)

In order to create a Δl/l₀-T curve or an expansion curve or to plot the change in length Δl/l₀ of a test specimen (precision component or glass ceramic) against the temperature, the temperature-dependent change in length of a test specimen from the initial length l₀ at the initial temperature t₀ to the length lₜ at the temperature t can be measured. In this case, small temperature intervals of, for example, 5° C. or 3° C. or 1° C. are optionally selected for determining a measuring point. Such measurements can be carried out, for example, by dilatometric methods, interferometric methods, for example the Fabry-Perot method, i.e. the evaluation of the displacement of the resonance peak of a laser beam coupled into the material, or other suitable methods. Within the scope of the invention, the dilatometric method with a temperature interval of 1° C. on rod-shaped samples of the test specimens with a length of 100 mm and a diameter of 6 mm was chosen for the determination of the CTE. The chosen method for determining the CTE has an accuracy of optionally at least ±0.05 ppm/K, optionally of at least ±0.03 ppm/K. However, the CTE can of course also be determined using methods which have an accuracy of at least ±0.01 ppm/K, optionally at least ±0.005 ppm/K or, according to some embodiments, even of at least ±0.003 ppm/K or at least ±0.001 ppm/K.

The average CTE for a certain temperature interval, for example for the temperature range of from 0° C. to 50° C. is calculated from the Δl/l₀-T curve.

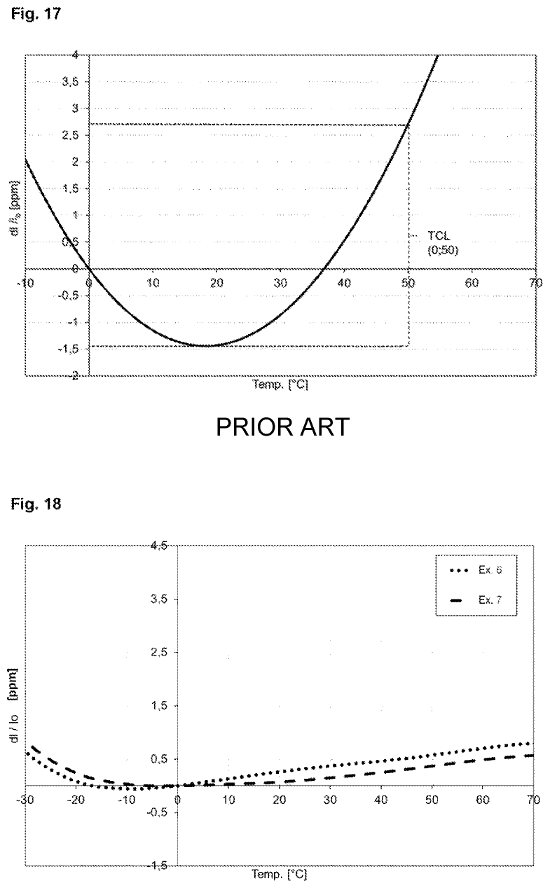

A CTE-T curve is obtained from the derivative of the Δl/l₀-T curve. From the CTE-T curve, it is possible to determine the zero crossing, the slope of the CTE-T curve within a temperature interval. The CTE-T curve is used to determine the shape and position of an advantageous CTE plateau formed in some variants (see below and FIGS. 20 and 21 and FIGS. 37, 39 and 41).

An exemplary embodiment of the precision component has a high CTE homogeneity. Here, the value of the CTE homogeneity (total spatial variation of CTE) is understood to mean the “peak-to-valley value”, i.e. the difference between the respectively highest and the respectively lowest CTE value of the samples taken from a precision component.

In order to determine the CTE homogeneity, a large number of samples, for example at least 5, at least 10, at least 20, at least 30, at least 40 or at least 50 samples, is taken from a precision component at different locations, and the respective CTE value thereof is determined for a defined temperature range, for example the CTE for the temperature range of from 0° C. to 50° C. (CTE(0;50)) or for the temperature range of from 19° C. to 25° C. (CTE(19;25)), which is given in ppb/K, where 1 ppb/K=0.001×10⁻⁶/K. In this case, the thermal expansion of a sample that has been taken is typically determined by the static method already mentioned above, in which the length of a test specimen is determined at the beginning and at the end of the specific temperature interval, and the average coefficient of expansion a or CTE (coefficient of thermal expansion) is calculated from the difference in length. The CTE is then indicated as the average for this temperature interval, e.g. for the temperature interval of from 0° C. to 50° C. as CTE(0;50) or α(0;50) or for the temperature interval of from 19° C. to 25° C. as CTE(19;25).

The CTE homogeneity thus does not refer to the CTE of the material of the component but to the spatial variation of the CTE over the segment considered or the entire precision component. If the CTE homogeneity of a particular component is to be determined for several temperature ranges, for example for the range 19° C. to 25° C. as well as 0° C. to 50° C., the CTE homogeneities for both temperature ranges can generally be determined on the same samples. In this case, however, it is advantageous to first determine the CTE of the narrower temperature range, e.g. CTE(19;25), and then the CTE of the wider temperature range, e.g. CTE(0;50), on the respective sample. However, it may be particularly advantageous if CTE homogeneities of a component for different temperature ranges are determined using different samples of these components.

The CTE homogeneity for the temperature range of from 0° C. to 50° C., i.e. the spatial variation of the CTE(0;50), is also referred to below as CTE homogeneity(0;50). The designation of the CTE homogeneity for other temperature ranges can be implemented in an analogous manner. Thus, for example, the CTE homogeneity for the temperature range of from 19° C. to 25° C., i.e. the spatial variation of the CTE(19;25), is also referred to hereinafter as CTE homogeneity(19;25).

In some embodiments, the precision component provided according to the invention has a CTE homogeneity(0;50) over the entire precision component of at most 5 ppb/K, optionally at most 4 ppb/K, optionally at most 3 ppb/K, and/or a CTE homogeneity(19;25) over the entire precision component of at most 5 ppb/K, optionally at most 4.5 ppb/K, optionally at most 4 ppb/K, optionally at most 3.5 ppb/K, optionally at most 3 ppb/K, optionally at most 2.5 ppb/K. A method for determining the CTE homogeneity and measures for achieving CTE homogeneity are described in WO 2015/124710 A, the disclosure of which is fully incorporated into this application.

Thermal Hysteresis

Within the scope of the invention, the precision components and glass ceramics have a thermal hysteresis of <0.1 ppm, at least in the temperature range of from 10 to 35° C. Thus, at any temperature within the temperature interval of from 10° C. to 35° C., the glass ceramic, after having been subjected to a temperature change, exhibits an isothermal change in length of less than 0.1 ppm at a subsequent constant temperature. In some embodiments, this freedom from hysteresis is present at least in a temperature range of from 5 to 35° C., optionally at least in the temperature range of from 5 to 45° C., optionally at least in the temperature range of from >0° C. to 45° C., optionally at least in the temperature range of from −5° C. to 50° C. In some embodiments, the temperature range in which there is freedom from hysteresis is even wider.

Exemplary application temperatures are in the range of from −60 to 100° C., optionally from −40° C. to +80° C. Some variants provided according to the present invention relate to glass ceramics and precision components for application temperatures T_{A} in the range of from 5° C. to 20° C. or T_{A} of 22° C., 40° C., 60° C., 80° C. and 100° C., for example, which are optionally hysteresis-free even at these temperatures.

For the precision components and glass ceramics provided according to the invention and for the comparative examples, the thermal hysteresis was determined on a precision dilatometer, which can determine the CTE as an absolute value with a reproducibility of ±0.001 ppm/K and ±0.003 ppm/K, with a temperature interval of 1° C., on rod-shaped samples with a length of 100 mm and a diameter of 6 mm of the test specimens (i.e. sample of the precision component or sample of the glass ceramic), in accordance with the method and apparatus structure disclosed in DE 10 2015 113 548 A, the disclosure of which is fully incorporated into this application. For each sample investigated, the change in length Δl/l₀ was determined as a function of temperature between 50° C. and −10° C., cooling at a cooling rate of 36 K/h. After an isothermal holding time of 5 hours at −10° C., the sample was heated to 50° C. at a heating rate of 36 K/h, and the change in length Δl/l₀ as a function of the temperature was recorded. The thermal hysteresis behavior of a test specimen is considered at −5° C., 0° C., 5° C., 10° C., 22° C., 35° C., 40° C.

These points are representative of the temperature range of from −10° C. to 50° C. since the hysteresis decreases with increasing temperature in said temperature interval. Thus, a sample which is hysteresis-free at 22° C. or 35° C. shows no hysteresis, even in the range up to 50° C.

To determine the thermal hysteresis at 10° C., the individual measured values of the change in length were recorded for the five temperatures 8° C., 9° C., 10° C., 11° C. and 12° C., i.e. in each case two temperature points above and below 10° C., both during heating and during cooling of the sample in the range of from −10° C. to 50° C. at the rate of 36 K/h. From the differences between the measured values for the heating curve and the cooling curve at these five measuring points, the average value was formed and listed as “Hyst.@ 10° C.” in the unit [ppm] in the tables.

To determine the thermal hysteresis at 35° C., the individual measured values of the change in length were correspondingly recorded for the five temperatures 33° C., 34° C., 35° C., 36° C. and 37° C., i.e. in each case two temperature points above and below 35° C., both during heating and during cooling of the sample in the range of from −10° C. to 50° C. at the rate of 36 K/h. From the differences between the measured values for the heating curve and the cooling curve at these five measuring points, the average value was formed and listed as “Hyst.@35° C.” in the unit [ppm] in the tables.

A corresponding procedure was followed for the other above-mentioned temperature points.

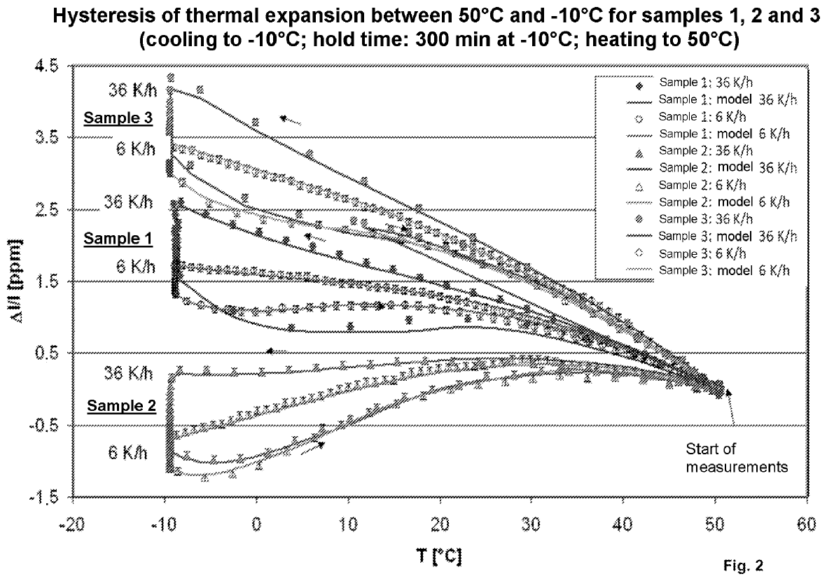

FIGS. 2 to 8 show the thermal hysteresis curves of known materials used for precision components. For better comparability, a range of 6 ppm on the y-axis has been chosen in all cases for the illustration in the figures. The cooling curves (dashed lines) and heating curves (dotted lines) are in each case clearly spaced apart from one another, i.e. clearly separate, precisely at relatively low temperatures. At 10° C., the distance is more than 0.1 ppm, and up to about 1 ppm, depending on the comparative example. In other words, the materials and the precision components produced therefrom exhibit considerable thermal hysteresis in the relevant temperature range of at least 100 to 35° C.

Precision components and glass ceramics provided according to the invention, on the other hand, are hysteresis-free (see, for example, FIGS. 10 and 11 and FIGS. 31 to 33, also shown with a range of 6 ppm on the y-axis), not only in the range of from 10° C. to 35° C., but also may advantageously be at least in the range of from 5 to 35° C. or at least in the range of from 5 to 45° C., optionally at least in the range >0° C. to 45° C., optionally at least in the temperature range of from −5° C. to 50° C., optionally also at even higher and even lower temperatures.

Index F

To describe the expansion behavior of a test specimen (precision component according to the first variant according to the invention or glass ceramic), a TCL value is often specified, where TCL means “total change of length”. Within the scope of the invention, the TCL value is specified for the temperature range 0° C. and 50° C. It is determined from the standardized Δl/l₀-T curve (also dl/I₀-T curve in the Figs.) of the respective test specimen, where “standardized” means that the change in length is 0 ppm at 0° C. The Δl/l₀-T curve for TCL determination is produced by the same method as described above in connection with the CTE determination within the scope of the invention.

The TCL value is the distance between the highest dl/l₀ value and the lowest dl/l₀ value in this temperature range:

TCL(0;50° C.)=|dl/l₀ max.|+|dl/l₀ min.| (2)

where “dl” denotes the change in length at the respective temperature and “l₀” denotes the length of the test specimen at 0° C. In each case, reference is made to the magnitude of the dl/l₀ values in carrying out the calculation.

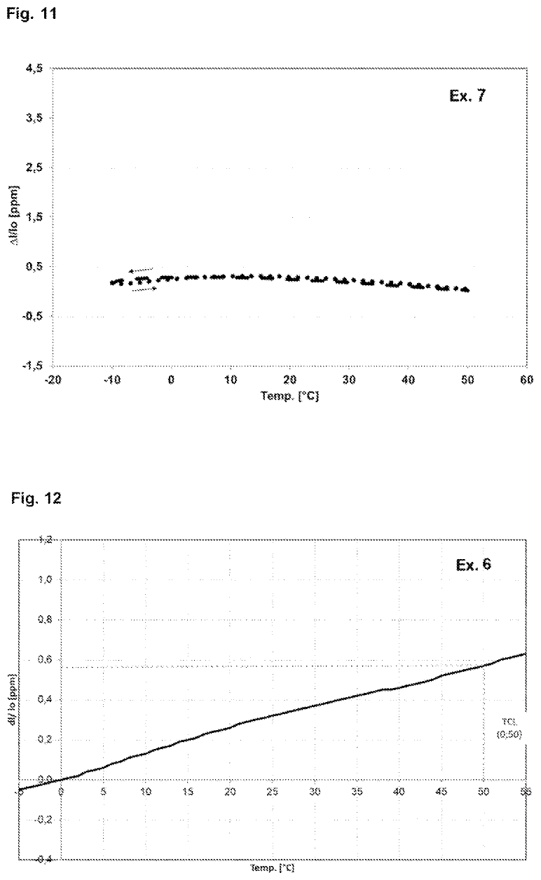

FIGS. 14 to 17 show expansion curves of known materials, from which the dl/l₀ max. values and dl/l₀ min. values can be read off in each case to calculate the TCL value (see also below). The expansion curves each show a curved profile in the temperature range 0° C. to 50° C.

Within the scope of the present invention, on the other hand, a flat profile of the expansion curve in the temperature range 0° C. to 50° C. is a further feature of some embodiments provided according to the invention of the precision component and a feature of the glass ceramic, in particular of a glass ceramic for such a precision component. As an expression of how much the curve profile of the thermal expansion differs from a simple linear profile, the index F is introduced as a measure of the flatness of the expansion curve, thereby enabling classification of CTE curves:

F=TCL(0;50° C.)/|expansion(0;50° C.)| (3)

The index F is calculated by forming the quotient of the TCL (0;50) value [in ppm] (see above) and the difference in expansion between the temperature points of 0° C. and 50° C. [in ppm]. Since the expansion curve for TCL determination is by definition standardized in such a way that the change in length is 0 ppm at 0° C., the “difference in expansion between the temperature points of 0° C. and 50° C.” corresponds to the “expansion at 50° C.”, as indicated in the tables. The magnitude of the expansion at 50° C. is used to calculate the index F.

It is advantageous here if the index F is <1.2, optionally <1.1, optionally at most 1.05. The closer the index F is to 1, the flatter the expansion curve.

FIG. 12 shows, by way of example for the invention, the expansion curve of a precision component or a glass ceramic or component on the basis of a ceramization of composition example 6. A 1.6 ppm segment on the y-axis was selected for the illustration. The highest expansion value (dl/l₀ max.) is at +50° C. (dl/l₀ is +0.57 ppm, i.e. |0.57 ppm|), the lowest expansion value (dl/l₀ min.) is 0 ppm. The difference in expansion between the temperature points of 0° C. and 50° C., corresponding to the amount of “expansion at 50° C.”, is 0.57 ppm. From this, the index F for this material is calculated as follows: F (example 6 from Table 1a)=0.57 ppm/0.57 ppm=1.

FIG. 13 shows a further example of the invention (composition according to example 7 from Table 1a), in which the index F is also 1.

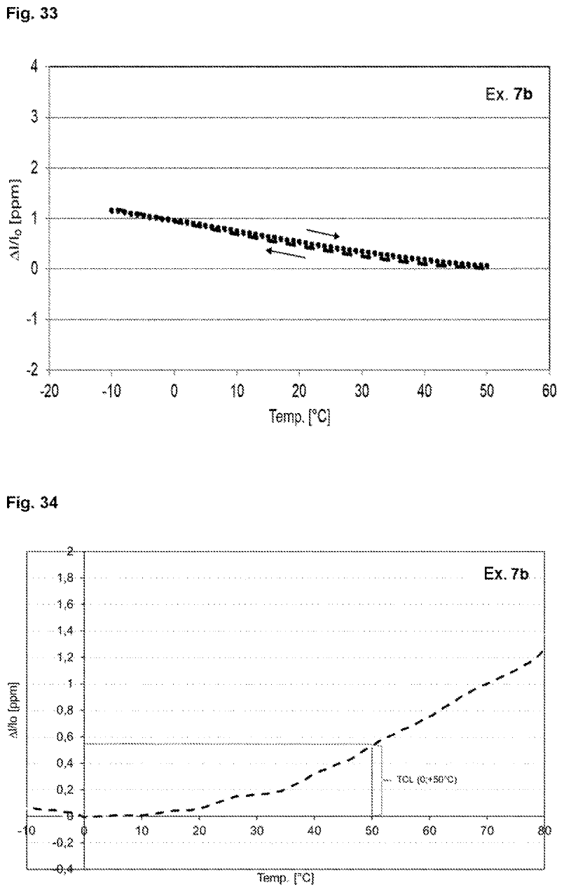

FIG. 34 shows, by way of example, the expansion curve of a further precision component or glass ceramic on the basis of a ceramization (maximum temperature 830° C., duration 3 days) of example 7b. A 2.4 ppm segment on the y-axis was selected for the illustration. The highest expansion value (dl/l₀ max.) is at +50° C. (dl/l₀ is +0.57 ppm, i.e. 10.57 ppm|), the lowest expansion value (dl/l₀ min.) is 0 ppm. The difference in expansion between the temperature points of 0° C. and 50° C., corresponding to the amount of “expansion at 50° C.”, is 0.57 ppm. From this, the index F for this material is calculated as follows: F (example 7b from Table 1b)=0.57 ppm/0.57 ppm=1.

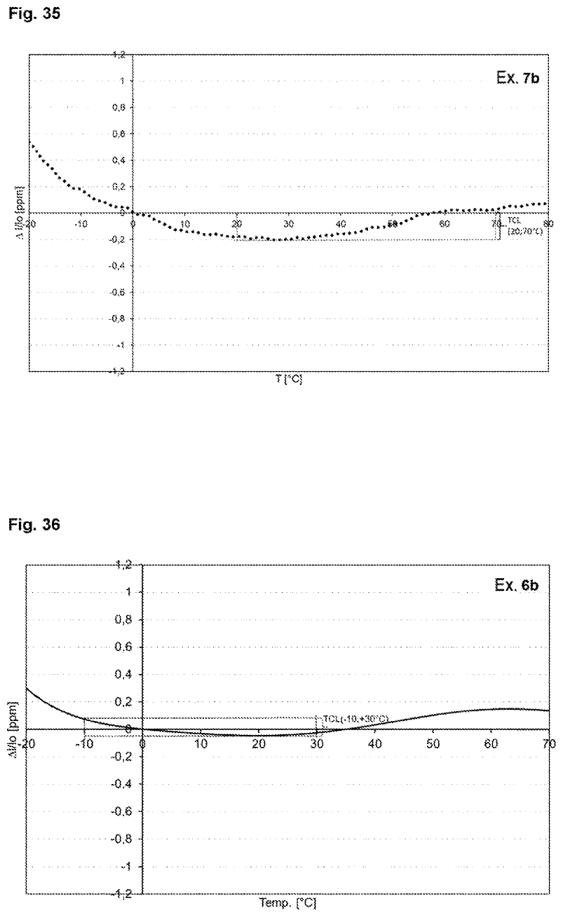

For another precision component or glass ceramic with a different ceramization of the glass ceramic of example 7b from Table 1b (maximum temperature 825° C., duration 3 days), FIG. 35 likewise shows an advantageously flat profile of the expansion curve in the temperature range −10° C. to 80° C.

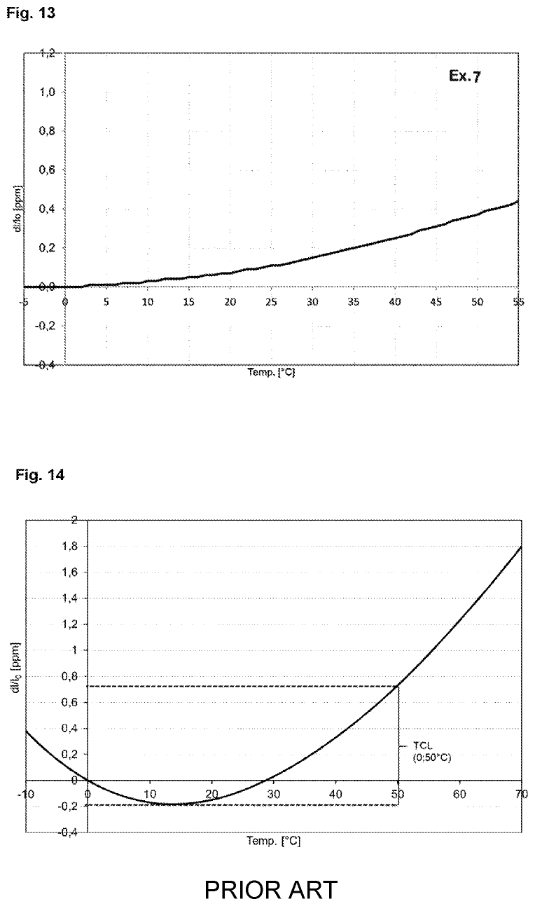

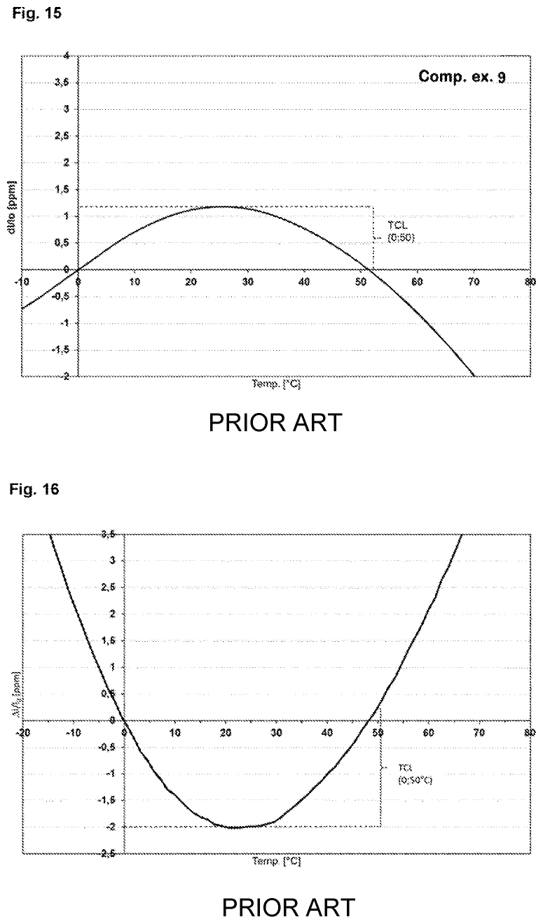

The precision components and glass ceramics of some embodiments provided according to the invention thus have a very flat profile of their expansion curves in the temperature range of from 0° C. to 50° C., i.e. they do not exhibit zero expansion in the temperature range under consideration, but also have little fluctuation in the change in linear expansion and thus in the differential CTE in this range. As can be seen in FIG. 18, some embodiments provided according to the invention also have a flat profile of their expansion curves over an even wider temperature range (here, by way of example, from −30° C. to +70° C.). See, in comparison, the substantially steeper profiles of the expansion curves of known materials with respect to the same temperature range in FIG. 19.

In comparison with the precision components and glass ceramics provided according to the invention, FIGS. 14 to 17 show the expansion behavior of known materials and precision components produced therefrom, from which the index F can be calculated in each case. The expansion behavior of the materials or precision components, as shown in FIGS. 14 to 17 and 19, was determined with the same dilatometer under comparable conditions as the expansion behavior of the precision components and glass ceramics provided according to the invention shown, for example, in FIGS. 12, 13, 18, 27 to 30 and in FIGS. 34 to 36. Overall, the known materials exhibit a curved profile of the expansion curves:

FIG. 14 shows the expansion curve of a commercially available titanium-doped quartz glass in the same dl/l₀ segment as in FIGS. 34 to 36. As can be seen, the sum of the magnitudes of the expansion value, here at +50° C. (dl/l₀ max. is +0.73 ppm, i.e. 10.73 ppm|), and the expansion value at 14° C. (dl/l₀ min. is −0.19 ppm, i.e. |0.19 ppm|) gives a TCL(0;50) value of about 0.92 ppm. The difference in expansion between the temperature points of 0° C. and 50° C., corresponding to the magnitude of the expansion at 50° C.″, is 0.73 ppm. From this, the index F for this material is calculated as follows: F (titanium-doped SiO₂)=0.92 ppm/0.73 ppm=1.26.

The index F for a known LAS glass ceramic or a corresponding precision component (see FIG. 15) is calculated in a corresponding manner as follows: F (known LAS glass ceramic)=1.19 ppm/0.11 ppm=10.82.

The index F for a known cordierite glass ceramic or a corresponding precision component (see FIG. 16) is calculated in a corresponding manner as follows: F (known cordierite glass ceramic)=2.25 ppm/0.25 ppm=9.

The index F for a known sintered cordierite ceramic or a corresponding precision component (see FIG. 17) is calculated in a corresponding manner as follows: F (known sintered cordierite ceramic)=4.2 ppm/2.71 ppm=1.55.

The precision components provided according to the invention and glass ceramics with a flat profile of their expansion curves may be very advantageous since now a component can not only be optimized for the subsequent application temperature, but also has an equally low thermal expansion, for example at higher and/or lower temperature loads, e.g. during production. Precision components for microlithography, EUV (extreme UV) microlithography (also “EUV lithography” or “EUVL” for short) and metrology are usually used under standard cleanroom conditions, in particular a room temperature of 22° C. The CTE can be matched to this application temperature. However, such components are subjected to various method steps, such as, for example, coating with metallic layers, cleaning, structuring and/or exposure processes, at which higher or, in some cases, lower temperatures than those prevailing during later use in the cleanroom may be present. The precision components provided according to the invention and glass ceramics, which have a index F of <1.2 and thus have an optimized zero expansion not only at the application temperature but also at possibly higher and/or lower temperatures during production, may thus be very advantageous. Properties such as freedom from hysteresis and a index <1.2 may be particularly advantageous if the precision component or a glass ceramic is used in EUV lithography, i.e. if, for example, the precision component is an EUV lithography mirror (also referred to as “EUVL mirror” for short) or EUVL mask blank or a corresponding substrate therefor, since, in EUV lithography, the mirrors or masks in particular are heated in a very uneven punctiform manner or in the beam direction by the irradiation with high-energy radiation. For such conditions of use, it is advantageous if the precision component or glass ceramic has a shallow slope of the CTE-T curve into a temperature range around the application temperature (see below).

Some embodiments of precision components and glass ceramics which are even better optimized to a subsequent application temperature at 20 or 22° C., are distinguished by the fact that they have a relative change in length (dl/l₀) of ≤|0.10|ppm, optionally of ≤|0.09| ppm, optionally of <|0.08| ppm and optionally of <|0.07| ppm in the temperature range of from 20° C. to 30° C. and/or a relative change in length (dl/l₀) of ≤|0.17| ppm, optionally of ≤|0.15|ppm, optionally of ≤|0.13| ppm and optionally of ≤|0.111 ppm in the temperature range of from 20° C. to 35° C. Alternatively or in addition, such glass ceramics and precision components can be distinguished by the fact that they have a relative change in length (dl/l₀) of ≤|0.30|ppm, optionally of ≤|0.25|ppm, optionally of ≤|0.20| ppm and optionally of ≤|0.15| ppm in the temperature range of from 20° C. to 40° C. The features relating to the relative change in length with respect to the different temperature intervals can optionally be taken from the dl/l₀ curves of FIGS. 12 to 19, for example. Where reference is made to the relative change in length (dl/l₀), the information relates, of course, to the magnitude of the respective value.

A zero-expansion and hysteresis-free precision component having such an expansion behavior is particularly suitable for use as an EUVL mirror or as a substrate for an EUVL mirror, which is heated to different degrees in light and shadow regions during operation, for example due to the respective exposure mask. Owing to the abovementioned small relative change in length, an EUVL mirror formed from the glass ceramic has lower local gradients or local slopes in the topography of the mirror surface than an EUVL mirror produced with known materials. The same applies analogously to EUVL mask blanks or EUVL masks or EUVL photomasks.

The invention further relates to an EUVL mirror and an EUVL mask blank comprising a precision component provided according to the invention, wherein the mirror has a relative change in length as described above.

Alternative index f_{T.i.}

Some embodiments of a precision component provided according to the invention and glass ceramics, in particular for such a precision component, are characterized by an alternative index f_{T.i.}, as described below.

In order to describe the expansion behavior of a test specimen (precision component or glass ceramic), of the precision component and of a glass ceramic, a TCL_{(T.i.)} value is specified, where TCL means “total change of length” and where T.i. describes the temperature interval considered in each case.

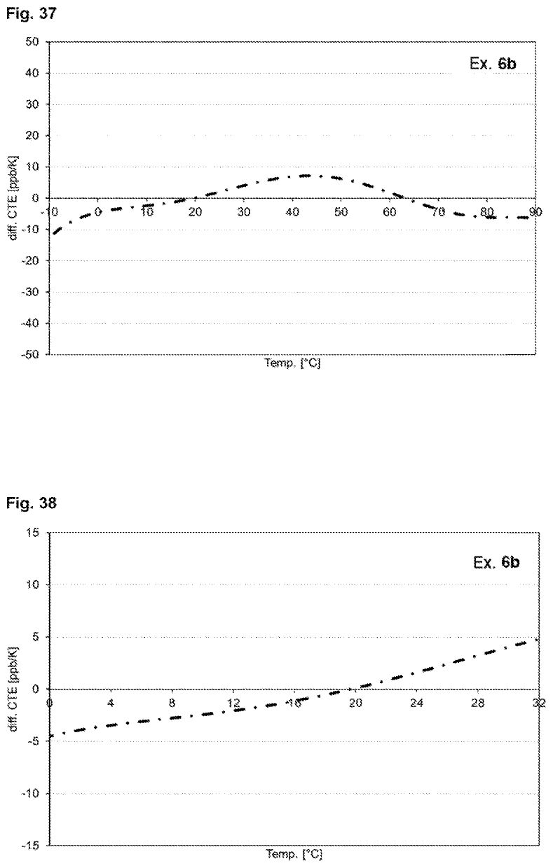

The alternative index f_{Ti.} can be used to consider the expansion behavior in a temperature interval (T.i), optionally in the temperature range (20;40), (20;70) and/or (−10;30). This allows better classification of the expansion behavior with respect to the subsequent fields of application. Particularly in the case of a precision component that has a glass ceramic which, in the temperature range under consideration, shows a very flat profile of the expansion curve which is close to 0 ppm or fluctuates around 0 ppm (see, for example, FIGS. 35, 36)—which may overall be an advantageous expansion behavior—it may be advantageous, as an alternative or in addition to the index F, to introduce a further measure of the flatness of the expansion curve.

The alternative index f_{T.i.} has the unit (ppm/K) and is defined as:

f_{T.i.}=TCL_{(T.i.)}/width of the temperature interval (T.i.) (4),

where T.i. describes the respective temperature interval considered.

The TCL_{(T.i.)} value is the distance between the highest dl/l₀ value and the lowest dl/l₀ value in the respective temperature range (T.i.) considered, wherein, by definition, the expansion curve is also standardized in such a way for the TCL_{(T.i.)} determination that the change in length is 0 ppm at 0° C. Thus, for example:

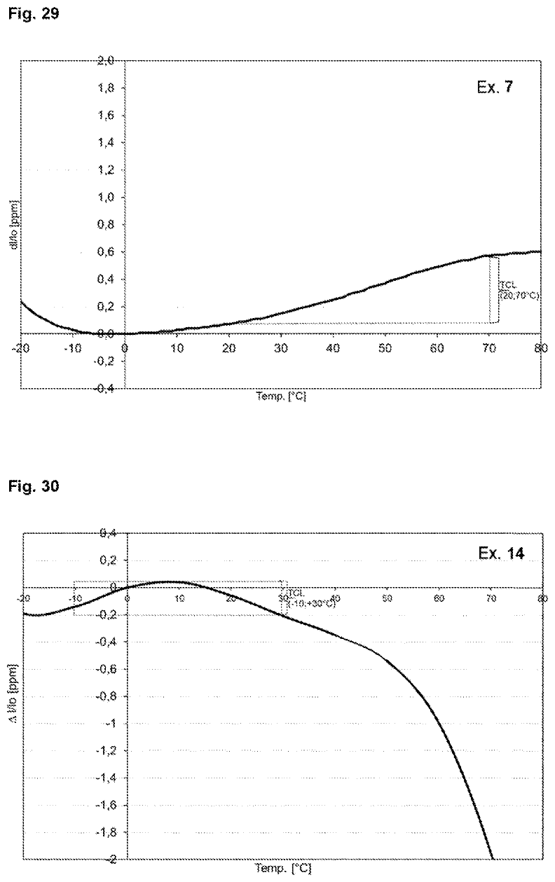

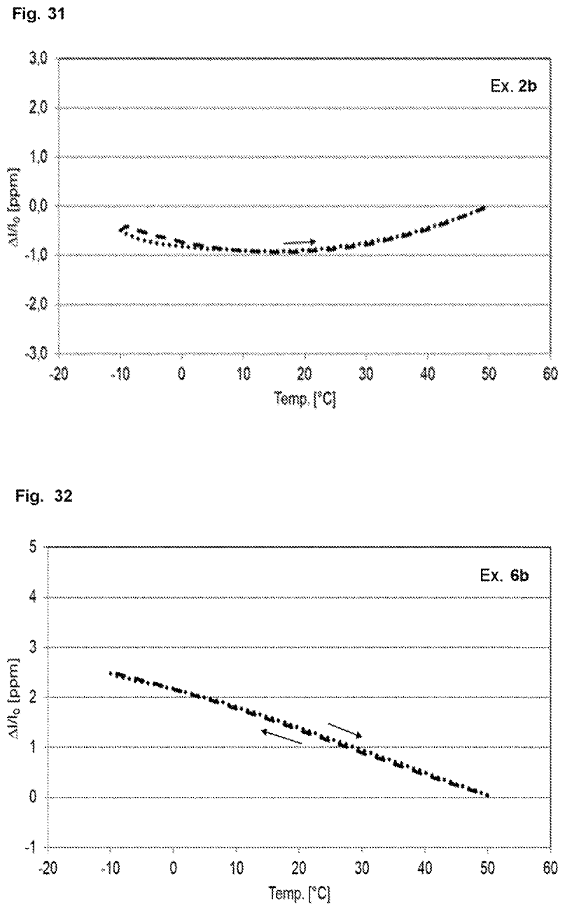

TCL_{(20;40° C.)}=|dl/l₀ max.|+|dl/l₀ min.| (5)

where “dl” denotes the change in length at the respective temperature and “l₀” denotes the length of the test specimen at 0° C. In the calculation, reference is made in each case to the magnitudes of the dl/l₀ values if the curve fluctuates around zero in the temperature interval under consideration (for example FIGS. 30, 35, 36). Otherwise, the TCL_{(T.i.)} is the distance determined from the difference between the highest dl/l₀ value and the lowest dl/l₀ value in the respectively considered temperature interval (T.i.), which is self-evident and can be seen from the Figs. (e.g. FIGS. 27 and 29). In general terms, the TCL_{(T.i.)} can be calculated as follows:

TCL_{(T.i.)}=dl/l₀ max.−dl/l₀ min. (6)

The alternative index f_{T.i.} is calculated according to formula (4) by forming the quotient of the TCL_{(T.i.)} value [in ppm] (see above) and the width of the temperature interval (T.i.), indicated in [K], in which the difference in expansion is considered. The width of the temperature interval considered between 20° C. and 40° C. is 20K. If, on the other hand, the profile of the expansion curve in the interval T.i.=(20;70) or (−10;30) is considered, the divisor for formula (4) is 50K or 40K.

Precision components provided according to the invention and glass ceramics with a very flat profile of the expansion curves may be very advantageous since now the precision component can not only be optimized for the subsequent application temperature but also, for example, for higher and/or lower temperature loads that may be expected. The alternative index f_{T.i.} is suitable for defining a suitable material and providing a corresponding precision component in accordance with the specifications required for certain component applications. Specific precision components and their applications are described below and are included here.

A precision component provided according to the invention or a glass ceramic can have an alternative index f_{(20;40)}<0.024 ppm/K, optionally <0.020 ppm/K, optionally <0.015 ppm/K. A hysteresis-free, zero-expansion component or glass ceramic having such an expansion behavior in the temperature range (20;40) is particularly suitable for use as a precision component for microlithography and EUV microlithography at room temperature. Examples of such precision components and glass ceramics are shown in FIG. 27 and can also be seen, for example, in FIG. 35.

A precision component provided according to the invention or a glass ceramic can have an alternative index f_{(20;70)}<0.039 ppm/K, optionally <0.035 ppm/K, optionally <0.030 ppm/K, optionally <0.025 ppm/K, optionally <0.020 ppm/K. A hysteresis-free, zero-expansion component or glass ceramic having such an expansion behavior in the temperature range (20;70) is likewise particularly suitable for use as a precision component for microlithography and EUV microlithography. It may be particularly advantageous if the component has an equally low thermal expansion even at higher temperature loads, which can occur locally or over an area, for example during the production of the precision component, but also during operation. Further details of the temperature loads which occur in the case of EUVL precision components have already been described above in connection with the index F, to which reference is made here in order to avoid repetitions. One example of such a precision component and glass ceramic is shown in FIG. 29, as well as in FIG. 35.

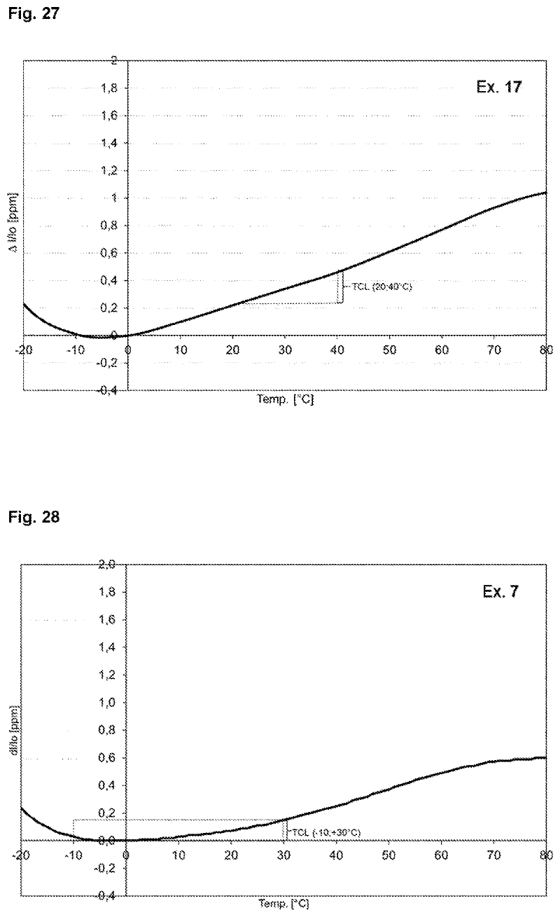

A precision component provided according to the invention or a glass ceramic can have an alternative index f_{(-10;30)})<0.015 ppm/K, optionally <0.013 ppm/K, optionally <0.011 ppm/K. A hysteresis-free, zero-expansion component or glass ceramic having such an expansion behavior in the temperature range (−10;30) it is particularly suitable for use as a precision component, in particular as a mirror substrate for applications in which lower temperatures than room temperature may also occur, for example as a mirror substrate in astronomy or earth observation from space. Corresponding components are described below. Examples of such precision components and glass ceramics are shown in FIGS. 28 and 30, as well as in FIG. 36.

Some embodiments of a precision component or glass ceramic have at least 2 alternative characteristic quantities f_{(T.i.)}.

Some embodiments of a precision component or glass ceramic have the index F and at least one alternative index f_{(T.i.)}.

### Additional Advantageous Features

Some precision components and glass ceramics may even have what is referred to as a CTE plateau (see FIGS. 20 and 21 and FIGS. 37, 39 and 41).

It may be advantageous if the differential CTE has a plateau close to 0 ppm/K, i.e. the differential CTE is less than 0±0.025 ppm/K in a temperature interval T_{P} with a width of at least 40 K, optionally at least 50 K. The temperature interval of the CTE plateau is denoted by T_{P}.

A CTE plateau is thus understood to mean a range extending over a segment of the CTE-T curve in which the differential CTE does not exceed a value of 0±0.025 ppm/K, optionally 0±0.015 ppm/K, optionally 0±0.010 ppm/K, optionally 0±0.005 ppm/K, i.e. a CTE close to 0 ppb/K.

The differential CTE in a temperature interval T_{P} with a width of at least 40 K can be less than 0±0.015 ppm/K, i.e. 0±15 ppb/K. In some embodiments, a CTE plateau of 0±0.01 ppm/K, i.e. 0±10 ppb/K, can be formed over a temperature interval of at least 50 K. In FIG. 25, the average curve even shows a CTE plateau of 0±0.005 ppm/K, i.e. 0±5 ppb/K, between 7° C. and 50° C., i.e. over a width of more than 40 K.

It can be advantageous if the temperature interval T_{P} is in a range of from −10 to +100° C., optionally of from 0 to 80° C.

The position of the CTE plateau is optionally matched to the application temperature T_{A} of the precision component. Exemplary application temperatures T_{A} are in the range of from −60° C. to +100° C., optionally from −40° C. to +80° C. Some embodiments provided according to the present invention relate to precision components and glass ceramics for application temperatures T_{A} of 0° C., 5° C., 10° C., 22° C., 40° C., 60° C., 80° C. and 100° C. The CTE plateau, i.e. the curve region with the small deviation of the differential CTE in the temperature interval Tₚ, can also be in the temperature range of [−10;100]; [0;80], [0;30° C.], [10;40° C.], [20;50° C.], [30;60° C.], [40;70° C.] and/or [50;80° C.]. In some precision components or glass ceramics, the CTE plateau can also be in the temperature range of [−10;30], [0;50], [19:25° C.]; [20;40] and/or [20;70].

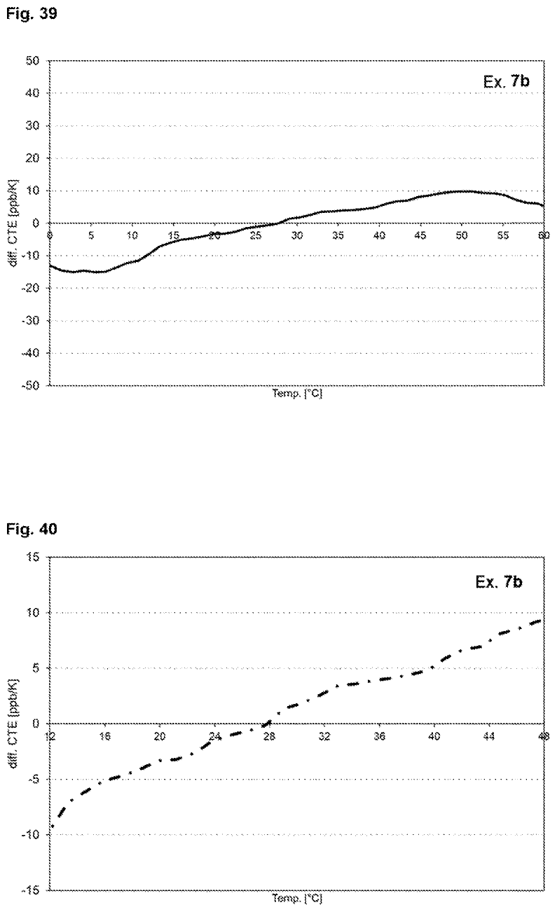

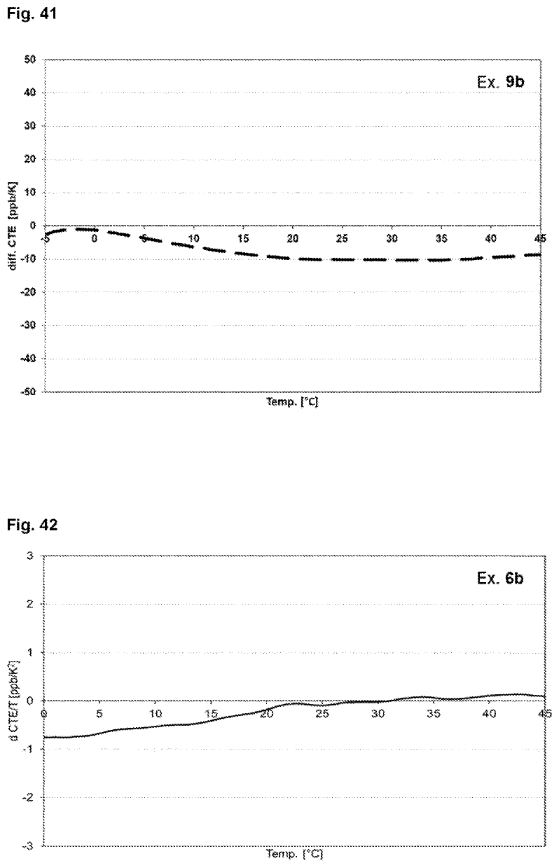

With reference to example 6b from Table 1b, FIG. 37 shows that this precision component or glass ceramic has a CTE of 0±0.010 ppm/K, i.e. a 10-ppb plateau, over the entire temperature range of from −10° C. to 90° C. shown. With more detailed consideration of a segment of this curve (see FIG. 38), it can be seen that the glass ceramic has a CTE of 0±0.005 ppm/K in the temperature range of from −5° C. to 32° C.

This glass ceramic meets the requirements for the average CTE (19;25) which are mentioned in standard SEMI P37-1109 for EUVL substrates and blanks.

FIG. 39 shows, for example 7b from Table 1b, which was ceramized at temperatures of a maximum of 825° C. for 3 days, that, from 12° C., the precision component or glass ceramic has a CTE of 0±0.010 ppm/K, i.e. a 10-ppb plateau whose width is >40K. As can be seen in FIG. 40, the example even has a CTE of 0±0.005 ppm/K in the range between 16° C. and 40° C. and therefore likewise meets the requirements for the average CTE (19;25) which are mentioned in standard SEMI P37-1109 for EUVL substrates and blanks.

FIG. 41 shows, for example 9b from Table 1b, which was ceramized at temperatures of a maximum of 830° C. for 3 days, that the precision component or glass ceramic has a CTE of 0±0.010 ppm/K, i.e. a 10-ppb plateau, in the range between −5° C. and 45° C. shown.

Precision components and glass ceramics with a plateau, i.e. with an optimized zero expansion, offer the same advantages which have already been described above in connection with the flat profile of the expansion curves and the index F or the alternative index f_{Ti}.

According to some embodiments provided according to the invention, the CTE-T curve of the precision component or glass ceramic has at least one curve segment with a shallow slope, in particular a slope of at most 0±2.5 ppb/K², advantageously of at most 0±2 ppb/K², advantageously of at most 0±1.5 ppb/K², optionally of at most 0±1 ppb/K², optionally of at most 0±0.8 ppb/K², according to some embodiments even of at most 0±0.5 ppb/K², in a temperature interval which has at least a width of 30 K, optionally at least a width of 40 K, optionally at least a width of 50 K.

The temperature interval with a shallow slope is optionally matched to the application temperature T_{A} of the precision component. Exemplary application temperatures T_{A} are in the range of from −60° C. to +100° C., optionally from −40° C. to +80° C. Some variants of the present invention relate to precision components and glass ceramics for application temperatures T_{A} of 0° C., 5° C., 10° C., 22° C., 40° C., 60° C., 80° C. and 100° C. The temperature interval with a shallow slope can also be in the temperature range of [−10;100]; [0;80], [0;30° C.], [10;40° C.], [20;50° C.], [30;60° C.], [40;70° C.] and/or [50;80° C.]. In the case of further precision components or glass ceramics, the temperature interval with a shallow slope can also be in the temperature range of [−10;30], [0;50], [19:25° C.]; [20;40] and/or [20;70].

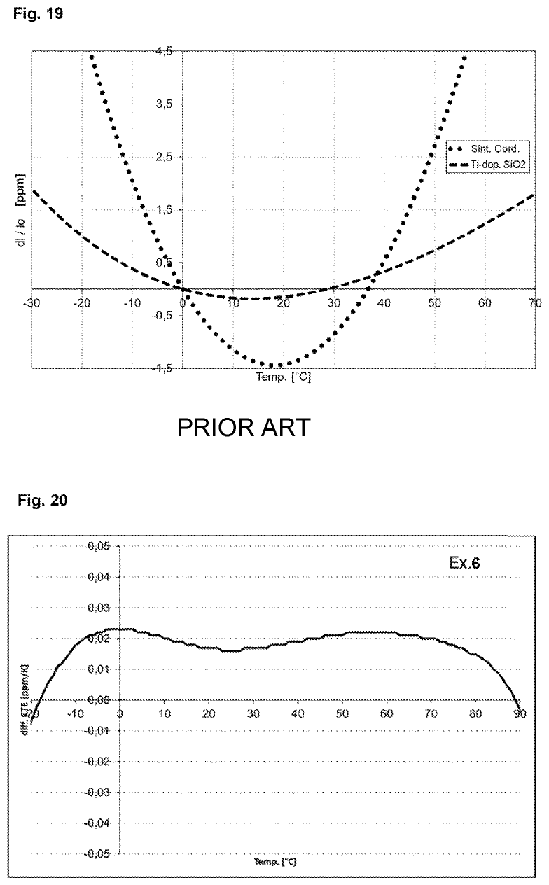

FIG. 22 shows the slope of the CTE-T curve in the temperature range of from 0° C. to 45° C. of a precision component or glass ceramic on the basis of the composition of example 6 from Table 1a. The CTE slope is below 0±2.5 ppb/K² in the entire temperature range and even below 0±1.5 ppb/K² in an interval with a width of at least 30 K.

It can be seen in FIG. 23 that the CTE slope of a precision component or glass ceramic according to composition example 7 from Table 1a is below 0±1.0 ppb/K² in the entire temperature range of from 0° C. to 40° C. with a width of at least 40 K and even below 0±0.5 ppb/K² in an interval with a width of at least 30 K.

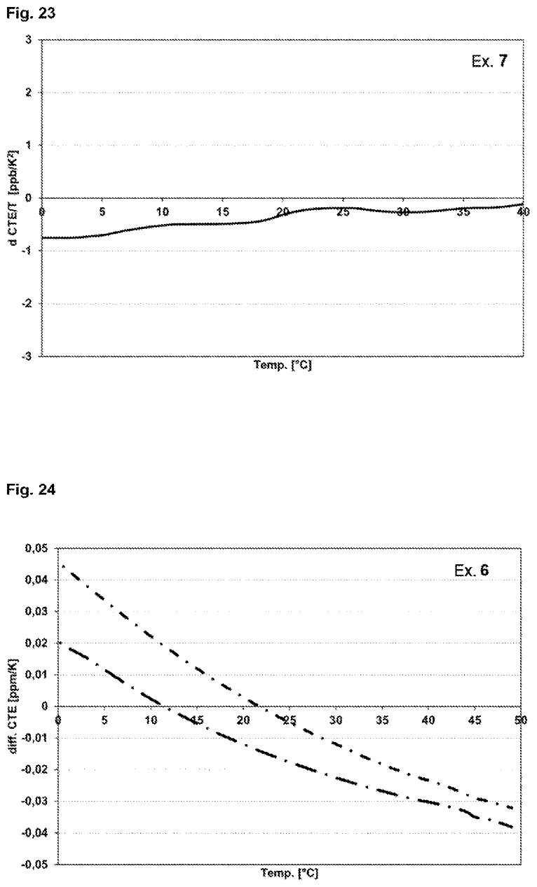

It can be seen in FIG. 26 that the CTE slope of a precision component or glass ceramic according to example 17 from Table 1a is below 0±1.0 ppb/K² in the entire temperature range of from 0° C. to 45° C. with a width of at least 45 K and even below 0±0.5 ppb/K² in an interval with a width of at least 30 K.

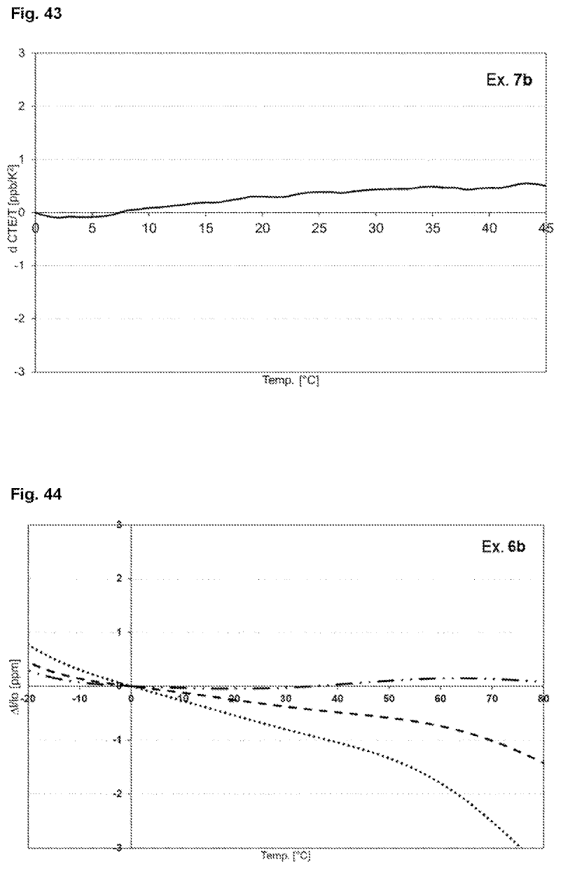

FIG. 42 shows the slope of a CTE-T curve in the temperature range of from 0° C. to 45° C. of a precision component or glass ceramic on the basis of the composition of example 6b from Table 1b. The CTE slope is below 0±1 ppb/K² in the entire temperature range and even below 0±0.5 ppb/K² in an interval with a width of at least 30 K (from about 12° C.).

It can be seen in FIG. 43 that the CTE slope of a precision component or glass ceramic according to example 7b from Table 1b is below 0±1.0 ppb/K² in the entire temperature range of from 0° C. to 45° C. with a width of at least 45 K and even below 0±0.5 ppb/K² in an interval with a width of at least 40 K (between 0 and 42° C. in the range illustrated).

Glass ceramics and precision components having such an expansion behavior are particularly well suited for EUV lithography applications (e.g. as mirrors or substrates for mirrors or masks or mask blanks) since in this sector the requirements on the materials and precision components used for the optical components are becoming ever higher with regard to extremely low thermal expansion, a zero crossing of the CTE-T curve close to the application temperature and, in particular, a shallow slope of the CTE-T curve. Within the scope of the invention, some embodiments of a precision component or glass ceramic have a very flat CTE profile, wherein the profile shows both a zero crossing and a very shallow CTE slope and optionally a very flat plateau.

The feature of the shallow slope can be present with or without formation of a CTE plateau.

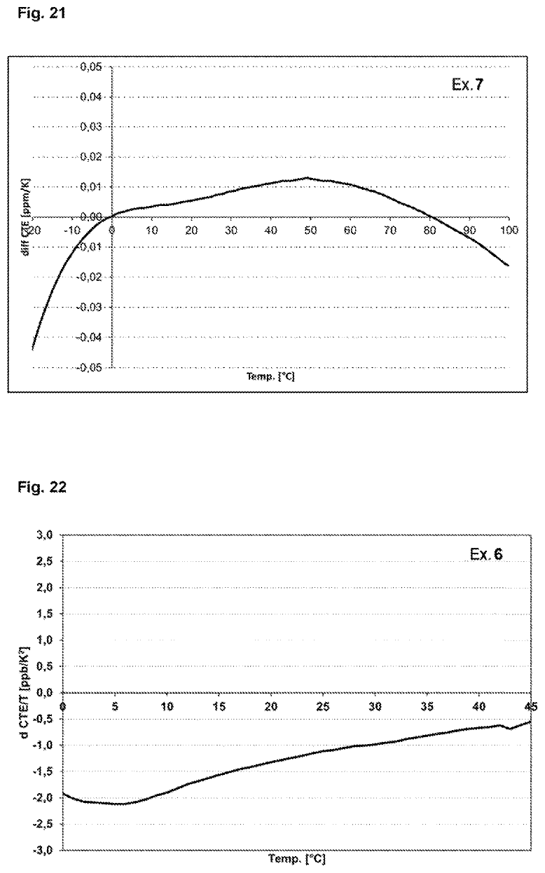

FIGS. 24 and 25 show how the CTE profile can be adapted to different application temperatures by varying the ceramization temperature and/or ceramization duration. As can be seen in FIG. 24, the zero crossing of the CTE-T curve can be shifted from, for example, 12° C. to a value of 22° C. by raising the ceramization temperature by 10 K. As an alternative to increasing the ceramization temperature, the ceramization duration can also be correspondingly extended. FIG. 25 demonstrates by way of example that the very flat profile of the CTE-T curve can be raised by raising the ceramization temperature by 5 or 10 K, for example. As an alternative to raising the ceramization temperature, the ceramization duration can also be correspondingly extended.

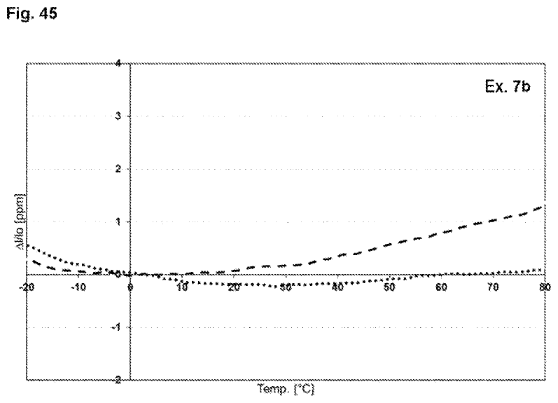

FIGS. 44 and 45 show how the expansion curve can be adapted to different application temperatures by varying the ceramization temperature and/or ceramization duration.

FIG. 44 shows, on the basis of example 6b from Table 1b, that the resulting expansion curves of the precision component or glass ceramic can be selectively influenced by the choice of the maximum ceramization temperature used to treat the initial green glass. The dotted curve shows the expansion curve of a glass ceramic, the underlying green glass of which was ceramized at a maximum of 810° C. for 2.5 days, whereas the dash-dotted curve shows the expansion curve of a glass ceramic, the underlying green glass of which was ceramized at a maximum of 820° C. for 2.5 days.

In addition, FIG. 44 shows by way of example that the glass ceramics provided according to the invention can be post-ceramized, which means that targeted fine adjustment of the expansion curve of the glass ceramic is possible by subjecting already ceramized material to another temperature treatment. In this case, material of the glass ceramic which had been ceramized at a maximum of 810° C. for 2.5 days was post-ceramized again at 810° C. for 1.25 days, i.e. with a shortened holding time. The effect of this post-ceramization is shown in the form of the dashed expansion curve. Comparing the expansion curves, it can be seen that the expansion curves and thus the average CTE (0;50) before and after the post-ceramization are different. However, XRD analyses of the samples before and after post-ceramization show the same results in terms of the average crystal size and the crystal phase content within the scope of the measurement accuracy.

FIG. 45 shows, for example 7b from Table 1b, the adjustability of the expansion curve by way of different maximum ceramization temperatures during the ceramization of the same initial green glass. Shown in dashed lines: ceramization at a maximum of 830° C. for 3 days; shown in dotted lines: ceramization at a maximum of 825° C. for 3 days.

As an alternative to raising the ceramization temperature, the ceramization duration can also be correspondingly extended.

Advantageous precision components and glass ceramics also may have good internal quality. They optionally have at most 5 inclusions per 100 cm³, optionally at most 3 inclusions per 100 cm³, optionally at most 1 inclusion per 100 cm³. According to the invention, inclusions are understood to mean both bubbles and crystallites which have a diameter of more than 0.3 mm.

According to some embodiments provided according to the invention, precision components are provided which have a diameter or an edge length of at most 800 mm and a thickness of at most 250 or 100 mm and which have at most 5, optionally at most 3, optionally at most 1 inclusion in each case per 100 cm³ with a diameter of more than 0.03 mm.

In addition to the number of inclusions, the maximum diameter of the detected inclusions also serves as a measure of the level of the internal quality. The maximum diameter of individual inclusions in the total volume of a precision component with a diameter of less than 500 mm or edge lengths of less than 500 mm is optionally at most 0.6 mm, optionally at most 0.4 mm in the volume critical for the application, for example in the vicinity of the surface.

The maximum diameter of individual inclusions in glass ceramic components with a diameter of from 500 mm to less than 2 m or edge lengths of from 500 mm to less than 2 m is optionally at most 3 mm, optionally at most 1 mm in the volume critical for the application, for example in the vicinity of the surface. This can be advantageous in order to achieve the surface quality required for the application.

Some embodiments relate to precision components with relatively small dimensions, in particular in the case of (rect)angular shapes with edge lengths (width and/or depth) or with round surfaces with diameters of at least 50 mm, optionally at least 100 mm and/or a maximum of 1500 mm, optionally a maximum of 1000 mm and/or a thickness of less than 50 mm, optionally less than 10 mm and/or at least 1 mm, optionally at least 2 mm. Such precision components can be used in microlithography and EUV lithography, for example.

Some embodiments relate to precision components with very small dimensions, in particular with edge lengths (width and/or depth) or diameters and/or thicknesses of a few mm (for example at most 20 mm or at most 10 mm or at most 5 mm or at most 2 mm or at most 1 mm) to a few tenths of a mm (for example at most 0.7 mm or at most 0.5 mm). These precision elements can be, for example, a spacer, for example in an interferometer, or a component for ultra-stable clocks in quantum technology.

However, it is also possible to produce very large precision components. Some embodiments provided according to the invention thus relate to components with a large volume. For the purposes of this application, this should be understood to mean a component with a mass of at least 300 kg, optionally at least 400 kg, optionally at least 500 kg, optionally at least 1 t, optionally at least 2 t, optionally at least 5 t, or with edge lengths (width and/or depth) in the case of (rect)angular shapes of at least 0.5 m, optionally at least 1 m, and/or with a thickness (height) of at least 50 mm, optionally at least 100 mm, optionally at least 200 mm, optionally at least 250 mm, or in the case of round shapes with a diameter of at least 0.5 m, optionally at least 1 m, optionally at least 1.5 m and/or with a thickness (height) of at least 50 mm, optionally at least 100 mm, optionally at least 200 mm, optionally at least 250 mm.

Some embodiments provided according to the invention may also be even larger components with, for example, a diameter of at least 3 m or at least 4 m or larger and/or a thickness of 50 mm to 400 mm, optionally 50 mm to 300 mm. According to some variants, the invention also relates to rectangular components, wherein optionally at least one surface has an area of at least 1 m², optionally at least 1.2 m², optionally at least 1.4 m², for some variants optionally at least 3 m² or at least 4 m² and/or the thickness is 50 mm to 400 mm, optionally 50 mm to 300 mm. As a rule, large-volume components which have a significantly larger base area than height are produced. However, they may also be large-volume components which have a shape approximated to a cube or a sphere.

With a glass ceramic provided according to the invention, it is possible to produce precision components in the sizes described above.

In some embodiments, the precision component comprises at least one inorganic material selected from the group comprising doped quartz glass, glass ceramic and ceramic, optionally Ti-doped quartz glass, LAS glass ceramic and cordierite.

The invention also relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and an index F of <1.2, wherein F=TCL (0; 50° C.)/|expansion (0; 50° C.)|, and at least one inorganic material selected from the group comprising doped quartz glass, glass ceramic and ceramic, optionally Ti-doped quartz glass, LAS glass ceramic and cordierite.

The invention also relates to a precision component which has an average coefficient of thermal expansion CTE of at most 0±0.1×10⁻⁶/K in the range of from 0 to 50° C. and a thermal hysteresis of <0.1 ppm, at least in the temperature range of from 10° C. to 35° C., and an alternative index f_{T.i.}, selected from the group comprising alternative index f_{(20;40)}<0.024 ppm/K, alternative index f_{(20;70)}><0.039 ppm/K, alternative index f_{(-10;30)}<0.015 ppm/K, and at least one inorganic material selected from the group comprising doped quartz glass, glass ceramic and ceramic, optionally Ti-doped quartz glass, LAS glass ceramic and cordierite.

In some embodiments, the inorganic material is a hysteresis-free, zero-expansion LAS glass ceramic. It may be advantageous if the LAS glass ceramic contains less than 0.6 mol % of MgO and/or ZnO. It can advantageously contain 60-71 mol % of SiO₂ and 7-9.4 mol % of Li₂O. An exemplary variant of the precision component comprises an LAS glass ceramic provided according to the invention, the features according to the invention and advantageous developments of which are described in detail below. The statements concerning the LAS glass ceramic below and the advantageous developments thereof apply correspondingly to the precision component which comprises such an LAS glass ceramic, and therefore attention is drawn to the statements below with regard to the advantageous composition and advantageous features of the material.

Moreover, the invention also relates to a precision component, wherein this is a precision component which is selected from the group comprising astronomical mirrors and mirror supports for segmented or monolithic astronomical telescopes; reduced-weight or ultralight mirror substrates for, for example, space-based telescopes; high-precision structural components for distance measurement, for example in space; optics for earth observation; precision components, such as standards for precision measurement technology, precision rules, reference plates in interferometers; mechanical precision parts, for example for ring laser gyroscopes, spiral springs for the watch and clock making industry; mirrors and prisms in LCD lithography; mask holders, wafer tables, reference plates, reference frames and grid plates in microlithography and in EUV (extreme UV) microlithography, in which reflective optics are used, as well as mirrors or mirror substrates and/or photomask substrates or photomask blanks or reticle mask blanks or mask blanks in EUV microlithography, and components for metrology and spectroscopy. The precision component can also in each case form a substrate for the components mentioned.

The invention also relates to the use of a precision component.

The precision component can be used in metrology, spectroscopy, astronomy, earth observation from space, measurement technology, LCD lithography, microlithography and/or EUV lithography, for example as a precision component selected from the abovementioned group.

Precision components can be, for example, optical components, more specifically a “normal incidence mirror”, i.e. a mirror which is operated close to the vertical incidence of radiation, or a “grazing incidence mirror”, i.e. a mirror which is operated with a grazing incidence of radiation. In addition to the substrate, such a mirror comprises a coating which reflects the incident radiation. Particularly in the case of a mirror for X-rays, the reflective coating is, for example, a multilayer system or multilayer having a multiplicity of layers with a high reflectivity in the X-ray range in the case of non-grazing incidence. Such a multilayer system of a normal incidence mirror optionally comprises 40 to 200 layer pairs, consisting of alternating layers, for example one of the material pairs Mo/Si, Mo/Bi, Ru/Si and/or MoRu/Be.

In particular, the optical elements provided according to the invention can be X-ray optical elements, i.e. optical elements which are used in conjunction with X-rays, in particular soft X-rays or EUV radiation, in particular reticle masks or photomasks operated in reflection, in particular for EUV microlithography. They can be mask blanks. Furthermore, the precision component can be used as a mirror or as a substrate for a mirror for EUV lithography.

Furthermore, the precision component provided according to the invention can be a component, in particular a mirror for astronomical applications. Such components can be used for astronomical applications both terrestrially and in space. High-precision structural components for distance measurements, for example in space, are another advantageous field of application.

The precision component provided according to the invention can be a lightweight structure. The component provided according to the invention can furthermore comprise a lightweight structure. This means that, in some regions of the component, cavities are provided for weight reduction. Lightweight machining is optionally used to reduce the weight of a component by at least 80%, optionally at least 90%, in comparison with the unmachined component.

The invention furthermore comprises an LAS glass ceramic, in particular for a precision component provided according to the invention, wherein the glass ceramic has an average coefficient of thermal expansion CTE of at most 0±0.1×10⁻⁶/K in the range of from 0 to 50° C. and a thermal hysteresis of <0.1 ppm, at least in the temperature range of from 10° C.-35° C., and comprises the following components (in mol % on an oxide basis):
SiO₂ 60-71
Li₂O 7-9.4
MgO+ZnO 0-<0.6
at least one component selected from the group comprising P₂O₅, R₂O, wherein R₂O may be Na₂O and/or K₂O and/or Cs₂O and/or Rb₂O, and RO, wherein RO may be CaO and/or BaO and/or SrO,
nucleating agent having a content of 1.5 to 6 mol %, wherein the nucleating agent is at least one component selected from the group comprising TiO₂, ZrO₂, Ta₂O₅, Nb₂O₅, SnO₂, MoO₃, WO₃.

In some embodiments, the precision component can comprise a substrate comprising the glass ceramic provided according to the invention.

Within the scope of the invention, a zero-expansion glass ceramic which has an extremely low thermal hysteresis of <0.1 ppm, at least in the temperature range of from 10° C. to 35° C., is provided for the first time. A material with such a low hysteresis effect of <0.1 ppm in the temperature range mentioned is hereinafter referred to as “hysteresis-free”. Since the extent of the hysteresis, as already mentioned above, depends on the rate of temperature change used for determination, the statements on the hysteresis within the scope of the invention relate to a heating rate/cooling rate of 36 K/h, i.e. 0.6 K/min. In some embodiments, the LAS glass ceramic can be hysteresis-free at least in the temperature range of from 5° C. to 35° C. or at least 5° C. to 40° C., optionally at least in the temperature range >0° C. to 45° C., optionally at least in the temperature range of from −5° C. to 50° C.

CTE and thermal hysteresis have already been described in detail above in connection with the precision component. All explanations—including the indicated differences with respect to the prior art—also apply correspondingly to the LAS glass ceramic provided according to the invention.

According to the invention, a glass ceramic is understood to mean inorganic, non-porous materials having a crystalline phase and a glassy phase, wherein, as a rule, the matrix, i.e. the continuous phase, is a glass phase. To produce the glass ceramic, the components of the glass ceramic are first mixed, melted and fined, and what is referred to as a green glass is cast. After cooling, the green glass is crystallized in a controlled manner by reheating (referred to as “controlled volume crystallization”). The chemical composition (analysis) of the green glass and the glass ceramic produced therefrom are the same, only the internal structure of the material being changed by the ceramization. When, therefore, the composition of the glass ceramic is referred to in the following, what has been said applies in the same way to the precursor of the glass ceramic, i.e. the green glass.

Within the scope of the invention, it was recognized for the first time that both components, MgO and ZnO, promote the occurrence of thermal hysteresis in the temperature range considered and it is therefore essential for the provision of a zero-expansion LAS glass ceramic that is hysteresis-free, at least in the temperature range of from 10° C. to 35° C., to limit the content of MgO and ZnO. In contrast, it has hitherto been assumed that these glass components are necessary, in combination or in each case individually, precisely in the case of zero-expansion LAS glass ceramics, in order to achieve the zero expansion and to make the CTE-T curve of the material “flat”, i.e. with a shallow slope of the CTE-T curve in the relevant temperature range. There was therefore a conflict of aims in that an LAS glass ceramic could be either zero-expansion or hysteresis-free.

This conflict of aims is solved by the invention if not only is the use of MgO and ZnO largely dispensed with but the contents of SiO₂ and Li₂O are additionally selected from the ranges specified by the invention. Within the scope of the invention, it was found that, in the range specified by the contents for SiO₂ (60-71 mol %) and for Li₂O (7-9.4 mol %), it is surprisingly possible to obtain glass ceramics which are zero-expansion and are hysteresis-free.

LAS glass ceramics contain a negative-expansion crystal phase, which, within the scope of the invention, may comprise or consist of high quartz mixed crystal, also called β-eucryptite, and a positive-expansion glass phase. In addition to SiO₂ and Al₂O₃, Li₂O is a main component of the mixed crystal. If present, ZnO and/or MgO are also incorporated into the mixed crystal phase and, together with Li₂O, influence the expansion behavior of the crystal phase. This means that the abovementioned specifications according to the invention (reduction, optionally exclusion, of MgO and ZnO) have a significant influence on the nature and properties of the mixed crystal formed in the course of ceramization. Within the scope of the invention, in contrast to the known zero-expansion glass ceramics, in which in particular MgO and ZnO are used to adjust the desired expansion behavior of the glass ceramic, at least one component selected from the group comprising P₂O₅, R₂O, where R₂O may be Na₂O and/or K₂O and/or Rb₂O and/or Cs₂O, and RO, where RO may be CaO and/or BaO and/or SrO, is used for this purpose. Unlike MgO and ZnO, the stated alkaline earth metal oxides and alkali metal oxides, if present, remain, but in the glass phase, and are not incorporated into the high quartz mixed crystal.

Within the scope of the invention, it has been found that it can be advantageous for the provision of a zero-expansion and hysteresis-free glass ceramic if the composition satisfies the condition: molar content SiO₂+(5× molar content Li₂O)≥106 or optionally ≥106.5, optionally molar content SiO₂+(5× molar content Li₂O)≥107 or ≥107.5. Alternatively or in addition, an upper limit of <115.5 or of <114.5 or of <113.5 can apply to the condition “molar content SiO₂+(5× molar content Li₂O)”.

In some embodiments, the glass ceramic can comprise the following components, either individually or in any combination in mol %:

| | |
|---|---|
| Al₂O₃ | 10 to 22 |
| P₂O₅ | 0 to 6 |
| MgO | 0 to 0.35 |
| ZnO | 0 to 0.5 |
| R₂O | 0 to 6 |
| RO | 0 to 6 |
| TiO₂ + ZrO₂ | 1.5 to 6. |

In some embodiments, the glass ceramic can comprise the following components, either individually or in any combination in mol %:

| | |
|---|---|
| Al₂O₃ | 10 to 22 |
| P₂O₅ | 0 to 6 |
| MgO | 0 to 0.3 |
| ZnO | 0 to 0.4 |
| R₂O | 0 to 6 |
| RO | 0 to 6 |
| TiO₂ + ZrO₂ | 1.5 to 6. |

Optionally, the following components may be present in the glass ceramic, individually or in any combination in mol %, within the limits mentioned above for the sums R₂O, RO and TiO₂+ZrO₂:

| | |
|---|---|
| Na₂O | 0 to 3 |
| K₂O | 0 to 3 |
| Cs₂O | 0 to 2 |
| Rb₂O | 0 to 2 |
| CaO | 0 to 5 |
| BaO | 0 to 4 |
| SrO | 0 to 3 |
| TiO₂ | 0 to 5 |
| ZrO₂ | 0 to 3. |

In some embodiments, the LAS glass ceramic comprises (in mol % on an oxide basis):

| | |
|---|---|
| Al₂O₃ | 10 to 22 |
| P₂O₅ | 0 to 6 |
| MgO | 0 to 0.35 |
| ZnO | 0 to 0.5 |
| R₂O | 0 to 6 |
| RO | 0 to 6 |
| Nucleating | 1.5 to 6, |
| agent | |

wherein the nucleating agent is optionally TiO₂ and/or ZrO₂.

In some embodiments, the LAS glass ceramic comprises (in mol % on an oxide basis):

| | |
|---|---|
| Al₂O₃ | 10 to 22 |
| P₂O₅ | 0 to 6 |
| MgO | 0 to 0.3 |
| ZnO | 0 to 0.4 |
| R₂O | 0 to 6 |
| RO | 0 to 6 |
| Nucleating | 1.5 to 6, |
| agent | |

wherein the nucleating agent is optionally TiO₂ and/or ZrO₂.

In some embodiments, the LAS glass ceramic comprises (in mol % on an oxide basis):

| | |
|---|---|
| SiO₂ | 60.50 to 69 |
| Li₂O | 8 to 9.4 |
| Al₂O₃ | 11 to 21 |
| P₂O₅ | 0.5 to 6 |
| MgO | 0 to 0.2 |
| ZnO | 0 to 0.3 |
| R₂O | 0 to 4 |
| RO | 0.2 to 4.5 |
| Nucleating | 2.5 to 5, |
| agent | |

wherein the nucleating agent is optionally TiO₂ and/or ZrO₂.

The glass ceramic contains a proportion of silicon dioxide (SiO₂) of at least 60 mol %, optionally at least 60.5 mol %, also optionally at least 61 mol %, also optionally at least 61.5 mol %, optionally at least 62.0 mol %. The proportion of SiO₂ is at most 71 mol % or less than 71 mol %, optionally at most 70 mol % or less than 70 mol %, optionally at most 69 mol %, and also optionally at most 68.5 mol %. In the case of relatively large proportions of SiO₂, the mixture is more difficult to melt and the viscosity of the melt is higher, which can lead to problems with the homogenization of the melts in large-scale industrial production plants. Therefore, a content of 71 mol %, optionally 70 mol %, should not be exceeded. If the viscosity of a melt is high, the processing temperature Va of the melt increases. Very high temperatures are required for refining and homogenizing the melt, but they lead to corrosion of the linings of the melting equipment owing to the increasing aggressiveness of the melt with temperature. Moreover, even relatively high temperatures may not be sufficient to produce a homogeneous melt, with the result that the green glass may have streaks and inclusions (in particular bubbles and particles originating from the lining of the melting equipment), such that, after ceramization, the requirements on the homogeneity of the properties of the glass ceramic produced, for example the homogeneity of the coefficient of thermal expansion, are not met. For this reason, lower SiO₂ contents than the stated upper limit may be preferred.

The proportion of Al₂O₃ is optionally at least 10 mol %, optionally at least 11 mol %, optionally at least 12 mol %, optionally at least 13 mol %, also optionally at least 14 mol %, also optionally at least 14.5 mol %, optionally at least 15 mol %. If the content is too low, no or too little low-expansion mixed crystal is formed. The proportion of Al₂O₃ is optionally at most 22 mol %, optionally at most 21 mol %, optionally at most 20 mol %, optionally at most 19.0 mol %, optionally at most 18.5 mol %. An excessively high Al₂O₃ content leads to an increased viscosity and promotes the uncontrolled devitrification of the material.

The glass ceramic provided according to the invention can contain 0 to 6 mol % of P₂O₅. The phosphate content P₂O₅ of the glass ceramic can optionally be at least 0.1 mol %, optionally at least 0.3 mol %, optionally at least 0.5 mol %, also optionally at least 0.6 mol %, optionally at least 0.7 mol %, optionally at least 0.8 mol %. P₂O₅ is incorporated essentially into the crystal phase of the glass ceramic and has a positive effect on the expansion behavior of the crystal phase and hence of the glass ceramic. In addition, the melting of the components and refining behavior of the melt are improved. However, if the P₂O₅ content is too high, the profile of the CTE-T curve in the temperature range of from 0° C. to 50° C. does not show a flat profile.

Therefore, optionally a maximum of 6 mol %, optionally a maximum of 5 mol %, optionally a maximum of 4 mol %, optionally less than 4 mol %, of P₂O₅ should be present in the glass ceramic. According to some embodiments, the glass ceramics can be free from P₂O₅.

Within the scope of the invention, certain sums and ratios of the components SiO₂, Al₂O₃ and/or P₂O₅, i.e. of the components which form the high quartz mixed crystal, may be conducive to the formation of a glass ceramic provided according to the invention.

The total proportion in mol % of the basic constituents of the LAS glass ceramic, SiO₂ and Al₂O₃, may be at least 75 mol %, optionally at least 78 mol %, optionally at least 79 mol %, optionally at least 80 mol % and/or optionally at most 90 mol %, optionally at most 87 mol %, optionally at most 86 mol %, optionally at most 85 mol %. If this total is too high, the viscosity curve of the melt is shifted to higher temperatures, which is disadvantageous, as already explained above in connection with the component SiO₂. If the total is too low, too little mixed crystal is formed.

The overall proportion in mol % of the basic constituents of the LAS glass ceramic, SiO₂, Al₂O₃ and P₂O₅, is optionally at least 77 mol %, optionally at least 81 mol %, optionally at least 83 mol %, optionally at least 84 mol % and/or optionally at most 91 mol %, optionally at most 89 mol %, optionally at most 87 mol %, optionally at most 86 mol %.

The ratio of the mol % proportions of P₂O₅ to SiO₂ is optionally at least 0.005, optionally at least 0.01, optionally at least 0.012 and/or optionally at most 0.1, optionally at most 0.08, optionally at most 0.07.

As a further constituent, the glass ceramic contains at least 7 mol %, optionally at least 7.5 mol %, optionally at least 8 mol %, optionally at least 8.25 mol %, of lithium oxide (Li₂O). The proportion of Li₂O is limited to at most 9.4 mol %, optionally at most 9.35 mol %, optionally at most or less than 9.3 mol %. Li₂O is a constituent of the mixed crystal phase and contributes substantially to the thermal expansion of the glass ceramic. The stated upper limit of 9.4 mol % should not be exceeded since otherwise glass ceramics with a negative coefficient of thermal expansion CTE (0;50) result. If the Li₂O content is less than 7 mol %, too little mixed crystal is formed and the CTE of the glass ceramic remains positive.

The glass ceramic can contain at least one alkaline earth metal oxide selected from the group comprising CaO, BaO, SrO, this group being referred to collectively as “RO”. The components from the group RO remain substantially in the amorphous glass phase of the glass ceramic and can be important for maintaining the zero expansion of the ceramized material. If the sum of CaO+BaO+SrO is too high, the desired CTE (0;50) according to the invention is not achieved. Therefore, the proportion of RO is optionally at most 6 mol % or at most 5.5 mol %, optionally at most 5 mol %, optionally at most 4.5 mol %, optionally at most 4 mol %, optionally at most 3.8 mol %, optionally at most 3.5 mol %, and also optionally at most 3.2 mol %. If the glass ceramic contains RO, an optional lower limit can be at least 0.1 mol %, optionally at least 0.2 mol %, optionally at least 0.3 mol %, also optionally at least 0.4 mol %. According to some embodiments, the glass ceramics can be free from RO.

The proportion of CaO can optionally be at most 5 mol %, optionally at most 4 mol %, optionally at most 3.5 mol %, optionally at most 3 mol %, optionally at most 2.8 mol %, optionally at most 2.6 mol %. The glass ceramic can optionally contain at least 0.1 mol %, optionally at least 0.2 mol %, optionally at least 0.4 mol %, optionally at least 0.5 mol % of CaO. The glass ceramic can optionally contain at least 0.1 mol %, optionally at least 0.2 mol % and/or at most 4 mol %, optionally at most 3 mol %, optionally at most 2.5 mol %, optionally at most 2 mol %, optionally at most 1.5 mol %, also optionally at most 1.4 mol %, of the component BaO, which is a good glass former. The glass ceramic can contain at most 3 mol %, optionally at most 2 mol %, optionally at most 1.5 mol %, optionally at most 1.3 mol %, optionally at most 1.1 mol %, optionally at most 1 mol %, also optionally at most 0.9 mol % and/or optionally at least 0.1 mol %, of SrO. According to some embodiments, the glass ceramics are free from CaO and/or BaO and/or SrO.

Sodium oxide (Na₂O) and/or potassium oxide (K₂O) and/or cesium oxide (Cs₂O) and/or rubidium oxide (Rb₂O) are optionally contained in the glass ceramic, i.e. Na₂O-free and/or K₂O-free and/or CS₂O-free and/or Rb₂O-free variants are possible. The proportion of Na₂O can optionally be at most 3 mol %, optionally at most 2 mol %, optionally at most 1.7 mol %, optionally at most 1.5 mol %, optionally at most 1.3 mol %, optionally at most 1.1 mol %. The proportion of K₂O can optionally be at most 3 mol %, optionally at most 2.5 mol %, optionally at most 2 mol %, optionally at most 1.8 mol %, optionally at most 1.7 mol %. The proportion of Cs₂O can optionally be at most 2 mol %, optionally at most 1.5 mol %, optionally at most 1 mol %, optionally at most 0.6 mol %. The proportion of Rb₂O can optionally be at most 2 mol %, optionally at most 1.5 mol %, optionally at most 1 mol %, optionally at most 0.6 mol %. According to some embodiments, the glass ceramics are free from Na₂O and/or K₂O and/or Cs₂O and/or Rb₂O.

Na₂O, K₂O, Cs₂O, Rb₂O can in each case and independently of one another be present in the glass ceramic in a proportion of at least 0.1 mol %, optionally at least 0.2 mol %, optionally at least 0.5 mol %. The components Na₂O, K₂O, Cs₂O and Rb₂O remain substantially in the amorphous glass phase of the glass ceramic and can be important for maintaining the zero expansion of the ceramized material.

Therefore, the sum R₂O of the contents of Na₂O, K₂O, Cs₂O and Rb₂O can optionally be at least 0.1 mol %, optionally at least 0.2 mol %, optionally at least 0.3 mol %, optionally at least 0.4 mol %. A low R₂O content of optionally at least 0.2 mol % can help to increase the temperature range in which the expansion curve of the glass ceramic exhibits a flat profile. The sum R₂O of the contents of Na₂O, K₂O, Cs₂O and Rb₂O can optionally be at most 6 mol %, optionally at most 5 mol %, optionally at most 4 mol %, optionally at most 3 mol %, optionally at most 2.5 mol %. If the sum of Na₂O+K₂O+Cs₂O+Rb₂O is too small or too great, it may be that the CTE (0;50) desired according to the invention is not achieved. According to some embodiments, the glass ceramics can be free from R₂O.

The glass ceramic can contain a maximum of 0.35 mol % of magnesium oxide (MgO). A further optional upper limit can be a maximum of 0.3 mol %, a maximum of 0.25 mol %, a maximum of 0.2 mol %, a maximum of 0.15 mol %, a maximum of 0.1 mol % or a maximum of 0.05 mol %. In some embodiments, the glass ceramics provided according to the invention are free from MgO. As already described above, the component MgO in the glass ceramic causes thermal hysteresis in the temperature range of from 0° C. to 50° C. The less MgO the glass ceramic contains, the less the hysteresis in the temperature range mentioned.

The glass ceramic can contain a maximum of 0.5 mol % of zinc oxide (ZnO). A further optional upper limit can be a maximum of 0.45 mol %, a maximum of 0.4 mol %, a maximum of 0.35 mol %, a maximum of 0.3 mol %, a maximum of 0.25 mol %, a maximum of 0.2 mol %, a maximum of 0.15 mol %, a maximum of 0.1 mol % or a maximum of 0.05 mol %. In some embodiments, the glass ceramics provided according to the invention are free from ZnO. As already described above as a finding of the inventors, the component ZnO in the glass ceramic causes thermal hysteresis in the temperature range of from 0° C. to 50° C. The less ZnO the glass ceramic contains, the less the hysteresis in the temperature range mentioned.

With regard to the hysteresis-free nature of the glass ceramic provided according to the invention, it is important that the condition MgO+ZnO less than 0.6 mol % is satisfied. A further upper limit for the sum of MgO+ZnO can be a maximum of 0.55 mol %, a maximum of 0.5 mol % or less than 0.5 mol %, a maximum of 0.45 mol %, a maximum of 0.4 mol %, a maximum of 0.35 mol %, a maximum of 0.3 mol %, a maximum of 0.25 mol %, a maximum of 0.2 mol %, a maximum of 0.15 mol %, a maximum of 0.1 mol % or a maximum of 0.05 mol %.

The glass ceramic also contains at least one crystal nucleating agent selected from the group comprising TiO₂, ZrO₂, Ta₂O₅, Nb₂O₅, SnO₂, MoO₃, WO₃. The nucleating agent can be a combination of two or more of the components mentioned. Another nucleating agent can be HfO₂. In some embodiments, the glass ceramic therefore comprises HfO₂ and at least one crystal nucleating agent selected from the group comprising TiO₂, ZrO₂, Ta₂O₅, Nb₂O₅, SnO₂, MoO₃, WO₃. The sum of the proportions of the nucleating agents is optionally at least 1.5 mol %, optionally at least 2 mol % or more than 2 mol %, optionally at least 2.5 mol %, according to certain variants at least 3 mol %. An upper limit can be a maximum of 6 mol %, optionally a maximum of 5 mol %, optionally a maximum of 4.5 mol % or a maximum of 4 mol %. In some variants, the stated upper and lower limits apply to the sum of TiO₂ and ZrO₂.

The glass ceramic can contain titanium oxide (TiO₂), optionally in a proportion of at least 0.1 mol %, optionally at least 0.5 mol %, optionally at least 1.0 mol %, optionally at least 1.5 mol %, optionally at least 1.8 mol % and/or optionally at most 5 mol %, optionally at most 4 mol %, optionally at most 3 mol %, optionally at most 2.5 mol %, optionally 2.3 mol %. TiO₂-free variants of the glass ceramic provided according to the invention are possible.

The glass ceramic can optionally also contain at most 3 mol %, optionally at most 2.5 mol %, optionally at most 2 mol %, optionally at most 1.5 mol % or at most 1.2 mol %, of zirconium oxide (ZrO₂). ZrO₂ can optionally be present in a proportion of at least 0.1 mol %, optionally at least 0.5 mol %, at least 0.8 mol % or at least 1.0 mol %. ZrO₂-free variants of the glass ceramic provided according to the invention are possible.

According to some embodiments provided according to the invention, from 0 to 5 mol %, individually or in total, of Ta₂O₅ and/or Nb₂O₅ and/or SnO₂ and/or MoO₃ and/or WO₃ can be present in the glass ceramic and can be used, for example, as alternative or additional nucleating agents or for modulating the optical properties, for example the refractive index. HFO₂ can likewise be an alternative or additional nucleating agent. For modulation of the optical properties, some variants can contain Gd₂O₃, Y₂O₃, HfO₂, Bi₂O₃ and/or GeO₂, for example.

The glass ceramic can further comprise one or more conventional fining agents selected from the group comprising As₂O₃, Sb₂O₃⁴, SnO₂, S₄²⁻, F⁻, Cl⁻, Br⁻, or a mixture thereof, in a proportion of more than 0.05 mol % or at least 0.1 mol % and/or at most 1 mol %. However, the fining agent fluorine can reduce the transparency of the glass ceramic, and therefore this component, if it is present, may optionally be limited to a maximum of 0.5 mol %, optionally a maximum of 0.3 mol %, optionally a maximum of 0.1 mol %. The glass ceramic is optionally free from fluorine.

An exemplary embodiment provided according to the invention is an LAS glass ceramic, in particular for a precision component or a precision component, wherein the glass ceramic has As₂O₃ as refining agent.

In some embodiments of the LAS glass ceramic or of the precision component, the LAS glass ceramic contains a maximum of 0.05 mol % of As₂O₃ as fining agent. Optionally, the As₂O₃ content in the glass ceramic is <0.04 mol %, optionally <0.03 mol %, optionally <0.025 mol %, optionally 0.02 mol %, optionally 0.015 mol %. It is advantageous if the glass ceramic contains as little As₂O₃ as possible. Exemplary variants of the glass ceramic are substantially As₂O₃-free, wherein “substantially As₂O₃-free or As-free” means that the component As₂O₃ is not intentionally added to the composition as a component but is at most contained as an impurity, wherein for As₂O₃-free glass ceramics an impurity limit for As₂O₃ is 0.01 mol %, optionally ≤0.005 mol %. According to some embodiments, the glass ceramic is free from As₂O₃.

It has been found that in the ranges specified by the invention it is surprisingly possible to obtain zero-expansion and hysteresis-free glass ceramics, even if the glass ceramic is fined in a more environmentally friendly manner according to some embodiments, i.e. contains a maximum of 0.05 mol % of As₂O₃ and is optionally substantially free from As₂O₃.

In order to provide the embodiments of the hysteresis-free and zero-expansion glass ceramic despite the reduced As₂O₃ content or in the desired internal quality even without the use of As₂O₃, in particular with a low number of bubbles and few stria, some embodiments use at least one chemical fining agent.

In some embodiments, the glass ceramic can have at least one alternative redox refining agent and/or at least one evaporation refining agent and/or at least one decomposition refining agent instead of As₂O₃ or in addition to the small proportion of As₂O₃ (a maximum of 0.05 mol %) as a chemical refining agent. Since As₂O₃ is also a redox refining agent, redox refining agents which are used as an alternative or in addition to As₂O₃ are referred to within the scope of the invention as “alternative redox refining agents”.

In some embodiments, the total content of the chemical refining agents that can be detected in the glass ceramic (without the content of As₂O₃—if As₂O₃ is present in the glass ceramic) can be in the range of from 0 mol % to 1 mol %. In some embodiments, the total content of the refining agents that can be detected in the glass ceramic (without As₂O₃) is more than 0.01 mol %, optionally at least 0.05 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol % of refining agent. The proportions of the respective components can be detected in an analysis of the glass ceramic. This applies especially to all the fining agents mentioned below with the exception of the sulfate component described.

Redox fining agents contain multivalent or polyvalent ions, which can occur in at least two oxidation stages, which are in a temperature-dependent equilibrium with one another, wherein a gas, usually oxygen, is released at high temperatures. Certain multivalent metal oxides can therefore be used as redox refining agents. In some embodiments, the alternative redox fining agent can be at least one component selected from the group comprising Sb₂O₃, SnO₂, CeO₂, MnO₂, Fe₂O₃. In principle, however, other redox compounds are also suitable if they release their fining gas in the temperature range relevant for fining and either change into an oxide having a different valence state of the metal ion or into a metallic form. Numerous such compounds are described in DE 19939771 A, for example. An alternative redox fining agent may be used which gives off fining gas, in particular oxygen, at a temperature of less than 1700° C., such as, for example, Sb₂O₃, SnO₂, CeO₂.

An analysis of the glass ceramic can be used to determine the content of As₂O₃ and/or the content of the at least one alternative redox fining agent, from which experts can draw conclusions as to the type and quantity of fining agent used. The alternative redox fining agents can be added to the mixture as oxides, for example.

In some embodiments, the total content of the alternative redox fining agents can be in the range of from 0 mol % to 1 mol %. In some embodiments, the total content of the alternative fining agents that can be detected in the glass ceramic is more than 0.01 mol %, optionally at least 0.05 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol % of an alternative fining agent.

The glass ceramic can contain 0 mol % to 1 mol % of antimony oxide (Sb₂O₃) as an alternative redox fining agent. In some embodiments, the glass ceramic contains more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of Sb₂O₃. Since Sb₂O₃ is considered to be environmentally hazardous, it may be advantageous to use as little Sb₂O₃ as possible for the fining process. In some embodiments the glass ceramic is substantially Sb₂O₃-free or Sb-free, wherein “substantially Sb₂O₃-free” means that Sb₂O₃ is not intentionally added to the composition as a raw material component but is at most contained as an impurity, wherein, for Sb₂O₃-free glass ceramics, an impurity limit is a maximum of 0.01 mol %, optionally a maximum of 0.005 mol %. According to some embodiments, the glass ceramic is Sb₂O₃-free.

The glass ceramic can contain 0 mol % to 1 mol % of tin oxide (SnO₂) as an alternative redox fining agent. In some embodiments, the glass ceramic contains more than 0.01 mol %, optionally at least 0.05 mol %, optionally at least 0.1 mol %, optionally at least 0.15 mol %, optionally at least 0.2 mol %, optionally at least 0.3 mol % and/or optionally at most 1 mol %, optionally at most 0.7 mol %, optionally at most 0.6 mol %, of SnO₂. In some variants, an upper limit of at most 0.5 mol %, optionally at most 0.4 mol %, optionally at most 0.3 mol % can be advantageous. If the content of SnO₂ is too high, it may be that the ceramization process of the green glass is more difficult to control since, at higher contents, SnO₂ acts not only as a fining agent but also as a crystal nucleating agent. SnO₂-free or Sn-free variants of the glass ceramic provided according to the invention are possible and can be advantageous, i.e. no Sn-containing raw material was added to the mixture to fine the underlying green glass, wherein a limit for contamination by SnO₂ introduced by raw materials or the process is a maximum of 0.01 mol %, optionally a maximum of 0.005 mol %.

The glass ceramic can contain 0 mol % to 1 mol % of CeO₂ and/or MnO₂ and/or Fe₂O₃ as an alternative redox fining agent. These components can be present in each case and independently of one another, optionally in a proportion of more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %. Exemplary variants of the glass ceramic are free from CeO₂ and/or MnO₂ and/or Fe₂O₃, i.e. no Ce-containing raw material and/or Mn-containing raw material and/or Fe-containing raw material was added to the mixture to fine the underlying green glass, wherein a limit for contamination by CeO₂ and/or MnO₂ and/or MnO₃ and/or Fe₂O₃ introduced by raw materials or the process is a maximum of 0.01 mol %, optionally a maximum of 0.005 mol %.

Evaporation fining agents are components which are volatile at high temperatures on account of their vapor pressure, with the result that the gas formed in the melt develops a fining action.

In some embodiments, the evaporation fining agent can have a halogen component.

In some embodiments, the evaporation fining agent can comprise at least one halogen with a fining action, in particular one selected from the group comprising chlorine (Cl), bromine (Br) and iodine (I). Fluorine is not a halogen with a fining action since it is already volatile at excessively low temperatures. The glass ceramic can nevertheless contain fluorine. However, the fluorine may reduce the transparency of the glass ceramic, and therefore this component, if it is present, should optionally be limited to a maximum of 0.5 mol %, optionally a maximum of 0.3 mol %, optionally a maximum of 0.1 mol %. The glass ceramic is optionally free from fluorine.

The halogen with a fining action can be added in different forms. In some embodiments, it is added to the mixture as a salt with an alkali metal cation or alkaline earth metal cation or as aluminum halogen. In some embodiments, the halogen is used as a salt and the cation in the salt corresponds to a cation present as an oxide in the glass ceramic. The halogen with a refining action can be used in the form of a halogen compound, in particular a halide compound. Suitable halide compounds are, in particular, salts of chlorine anions, bromine anions and/or iodine anions with alkali metal cations or alkaline earth metal cations or aluminum cations. Preferred examples are chlorides such as LiCl, NaCl, KCl, CaCl₂, BaCl₂, SrCl₂, AlCl₃ and combinations thereof. Corresponding bromides and iodides such as LiBr, LiI, NaBr, NaI, KBr, KI, CaI₂, CaBr₂ and combinations thereof are also possible. Other examples are BaBr₂, BaI₂, SrBr₂, SrI₂ and combinations thereof.

In some variants, the total content of halogen with a fining action (that is to say Cl and/or Br and/or I) can be in the range of from 0 mol % to 1 mol %. In some embodiments, the total content of halogen with a fining action which can be detected in the glass ceramic is more than 0.03 mol %, optionally at least 0.04 mol %, optionally at least 0.06 mol %, optionally at least 0.08 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol %, of halogen with a fining action. The contents stated refer to the quantities of halogen detectable in the glass ceramic. It is a matter of routine for those skilled in the art to use these data to calculate the amount of halogen or halide compound required for refining.

The glass ceramic can contain from 0 mol % to 1 mol % of chlorine (determined atomically and indicated as Cl). In some embodiments, the glass ceramic contains more than 0.03 mol %, optionally at least 0.04 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of Cl. Some glass ceramics can be free from Cl, i.e. no Cl-containing raw material was added to the mixture to fine the underlying green glass. Cl is at most present as an impurity, wherein the limit for Cl contamination is a maximum of 0.03 mol %.

The same stated ranges and limits apply to Br as a halogen with a fining action. The same stated ranges and limits apply to I as a halogen with a fining action. Exemplary variants of the glass ceramic are free from Br and/or I.

As an alternative or in addition to an evaporation fining agent and/or an alternative redox fining agent, the chemical fining agent can contain at least one decomposition fining agent. A decomposition fining agent is an inorganic compound which decomposes at high temperatures, releasing fining gas, and the decomposition product has a sufficiently high gas pressure, in particular greater than 10⁵ Pa. The decomposition fining agent can optionally be a salt containing an oxo anion, in particular a sulfate component. The decomposition fining agent optionally comprises a sulfate component. Decomposition of the component added as a sulfate results in the release of SO₂ and O₂ at high temperatures, which contribute to the fining of the melt.

A sulfate component can be added in different forms. In some embodiments, it is added to the mixture as a salt with an alkali metal cation or alkaline earth metal cation. In some embodiments, the sulfate is used as a salt and the cation in the salt corresponds to a cation present as an oxide in the glass ceramic. By way of example, the following components can optionally be used as a sulfate source: Li₂SO₄, Na₂SO₄, K₂SO₄, CaSO₄, BaSO₄, SrSO₄.

Within the scope of the invention, sulfate is determined as SO₃ in material analysis.

However, since LAS glass ceramics have only a very low solubility for sulfate, the sulfate component (i.e. SO₃) in the melt product can no longer be detected after melting by the usual X-ray fluorescence analysis. Therefore, in the case of sulfate-fined exemplary embodiments (see below), it is indicated how many mol % of SO₄²⁻ or mol % of SO₃ have been used, based on the synthesis of the glass melt. The fact that a sulfate component has been used as fining agent can be determined, for example, by analyzing the residual gas content (SO₂) in the glass ceramic.

During synthesis, more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of SO₃, were added by way of at least one corresponding sulfate compound to a glass ceramic which has been fined with a sulfate component. Sulfate-free (i.e. SO₃-free or SO₄₂-free) fined glass ceramics are possible and may be advantageous. The proportion of fining sulfate added in the synthesis of a glass ceramic can thus be in the range of from 0 mol % to 1 mol % of SO₃.

According to some embodiments provided according to the invention, the glass ceramic or the underlying glass can be fined using a suitable metal sulfide as a decomposition refining agent, as described, for example, in US 2011/0098171 A. In some embodiments, the cation in the sulfide corresponds to a cation present as an oxide in the glass ceramic. Examples of suitable metal sulfides are alkali metal sulfide, alkaline earth metal sulfide and/or aluminum sulfide, which release SO₃ in the melt under oxidizing conditions. In order for a metal sulfide to be able to fulfill the role as a fining agent well, it may advantageously be used in combination with an oxidizing agent, optionally a nitrate, and/or sulfate.

Some glass ceramics having a reduced As₂O₃ content, or some As₂O₃-free glass ceramics can have a combination of chemical fining agents. In this context, the following combinations can be advantageous, the respective glass ceramic optionally having the stated fining agents within the abovementioned limits for the individual components and/or the sums. Exemplary embodiments comprise:
SnO₂ and/or Sb₂O₃ each with a maximum of 0.05 mol % of As₂O₃; or
As₂O₃-free combinations such as: Sb₂O₃ with SnO₂; Sb₂O₃ with Cl, Sb₂O₃ with SO₃; or
As₂O₃-free and Sb₂O₃-free combinations such as: SnO₂ with Cl, SnO₂ with SO₃, Cl with SO₃.

Alternatively, glass ceramics fined with only one fining agent can also be advantageous, for example glass ceramics which contain only Sb₂O₃ or only SnO₂ as a fining agent.

Alternatively or in addition to the above-described fining of the melt with chemical fining agents, the principle of which consists in the addition of compounds which decompose and release gases or which are volatile at higher temperatures or which give off gases in an equilibrium reaction at higher temperatures, it is also possible to use known physical fining processes, e.g. reducing the viscosity of the glass melt by increasing the temperature, vacuum fining, high-pressure fining, etc.

In some embodiments provided according to the invention, the mixture can contain nitrates (NO₃), which act as oxidizing agents in the melting and refining process and ensure that oxidizing conditions are present in the melt in order to increase the effectiveness of the fining agents used, in particular of the alternative redox fining agents. In some embodiments, the nitrate is used as a salt and the cation in the salt corresponds to a cation present as an oxide in the glass ceramic. Examples thereof can be: aluminum nitrate, alkali metal nitrate, alkaline earth metal nitrate, zirconium nitrate, but ammonium nitrate can also serve as a nitrate source. A nitrate compound or a mixture of several nitrate compounds can be used. If the mixture contains a nitrate compound or a mixture of nitrate compounds to support the refining process, the total NO₃ is optionally at least 0.4 mol %, optionally at least 0.5 mol %, optionally at least 0.8 mol %, optionally at least 1 mol % and/or optionally at most 5 mol %, optionally at most 4 mol %. In some variants, at most 3 mol % of nitrate can also be used. Nitrate can no longer be detected in the glass or glass ceramic owing to the volatility.

The above glass compositions may optionally contain additives of coloring oxides, such as, for example, Nd₂O₃, Fe₂O₃, CoO, NiO, V₂O₅, MnO₂, CuO, CeO₂, Cr₂O₃, or rare earth oxides, in amounts of in each case individually or in total 0-3 mol %. Exemplary variants are free from coloring oxides.

B₂O₃ can have a negative effect on the transparency of the glass ceramic. Therefore, in some variants, the content of this component is limited to <0.2 mol %, optionally at most 0.1 mol %. Exemplary variants are free from B₂O₃.

According to some embodiments provided according to the present invention, the composition is free from components which have not been mentioned above.

According to some embodiments provided according to the present invention, the glass ceramic provided according to the invention or the green glass optionally comprises at least 90 mol %, optionally at least 95 mol %, optionally at least 99 mol % of the abovementioned components or optionally of the components SiO₂, Al₂O₃, Li₂O, P₂O₅, R₂O, RO and nucleating agents.

According to some embodiments of the glass ceramic, it is substantially free from one or more glass components selected from the group comprising MgO, ZnO, PbO, B₂O₃, CrO₃, F, Cd compounds.

According to the invention, the expression “X-free” or “free from a component X” means that the glass ceramic essentially does not contain this component X, i.e. that such a component is present at most as an impurity in the glass but is not added to the composition as an individual component. With regard to contamination, in particular with MgO and/or ZnO, a limit of 0.03 mol %, optionally 0.01 mol %, based on a single component in each case, should not be exceeded in the case of MgO-free and/or ZnO-free variants. In the case of other glass components, higher impurity contents of up to a maximum of 0.1 mol %, optionally a maximum of 0.05 mol %, optionally a maximum of 0.01 mol %, optionally a maximum of 0.005 mol %, for some components optionally a maximum of 0.003 mol %, may be possible, based in each case on one component. Here, X stands for any desired component, such as, for example, PBO. These stated limits do not refer to the fining agents, for which separate contamination limits are described above.

The glass ceramics provided according to the invention have high quartz mixed crystal as the main crystal phase. The main crystal phase is the crystalline phase which has the largest proportion by volume in the crystal phase. High quartz mixed crystal is a metastable phase which, depending on the crystallization conditions, changes its composition and/or structure or is converted into another crystal phase. The high quartz-containing mixed crystals have a very low thermal expansion or even a thermal expansion which decreases as the temperature rises. In some embodiments, the crystal phase contains no β-spodumene and no keatite.

Some embodiments of the LAS glass ceramic have a crystal phase content of less than 70 vol % and/or more than 45 vol %. The crystal phase consists of high quartz mixed crystal, which is also referred to as β-eucryptite mixed crystal. The average crystallite size of the high quartz mixed crystal is optionally <100 nm, optionally <80 nm, optionally <70 nm. The small crystallite size has the effect that the glass ceramic is transparent and can also be better polished. In some variants, the average crystallite size of the high quartz mixed crystal can be ≤60 nm, optionally ≤50 nm. The crystal phase, the proportion thereof and the average crystallite size are determined in a known manner by X-ray diffraction analysis.

According to some embodiments provided according to the present invention, a transparent glass ceramic is produced. By virtue of the transparency, many properties of such a glass ceramic, in particular of course its internal quality, can be better assessed. The glass ceramics provided according to the invention are transparent, i.e. they have an internal transmittance of at least 70% in the wavelength range of from 350 to 650 nm. B₂O₃ and/or higher fluorine contents can reduce transparency. Therefore, some variants do not contain one or both of the components mentioned. Furthermore, the glass ceramics produced within the scope of the invention are free from pores and cracks. Within the scope of the invention, “free from pores” means a porosity of less than 1%, optionally less than 0.5%, optionally less than 0.1%. A crack is a gap, i.e. discontinuity, in an otherwise continuous structure.

To enable the production of a homogeneous glass ceramic in a large-scale industrial production plant, it may be advantageous if the processing temperature Va of the green glass on which the glass ceramic is based (and thus of the glass ceramic) is a maximum of 1330° C., optionally a maximum of 1320° C. Some variants can have a processing temperature of a maximum of 1310° C. or a maximum of 1300° C. or less than 1300° C. The processing temperature Va is the temperature at which the melt has a viscosity of 10⁴ dPas. Homogeneity refers, in particular, to the homogeneity of the CTE of the glass ceramic over a large volume and a small number, optionally freedom from inclusions such as bubbles and particles. This is a quality feature of glass ceramics and a prerequisite for use in precision components, especially in very large precision components.

The processing temperature is determined by the composition of the glass ceramic. Since, in particular, the glass network-forming component SiO₂ is to be regarded as a decisive component for increasing viscosity and thus the processing temperature, the maximum SiO₂ content should be selected in accordance with the abovementioned specifications.

CTE

The glass ceramics provided according to the invention are zero-expansion (see Tables 1a and 1b), i.e. they have an average coefficient of thermal expansion CTE of at most 0±0.1×10⁻⁶/K in the range of from 0 to 50° C. Some variants even have an average CTE of at most 0±0.05×10⁻⁶/K in the range of from 0 to 50° C. For certain applications, it may be advantageous if the average CTE is at most 0±0.1×10⁻⁶/K over a relatively wide temperature range, for example in the range of from −30° C. to +70° C., optionally in the range of from −40° C. to +80° C. Further details on the average and differential CTE have already been described above in connection with the precision component provided according to the invention. This disclosure is fully incorporated into the description of the glass ceramic.

Thermal Hysteresis

Within the scope of the invention, the glass ceramic has a thermal hysteresis of <0.1 ppm at least in the temperature range of from 10° C. to 35° C. and is therefore hysteresis-free (see FIGS. 10 and 11 and FIGS. 31 to 33). In some embodiments, this freedom from hysteresis is present at least in a temperature range of from 5 to 35° C., optionally at least in the temperature range of from 5 to 45° C., optionally at least in the temperature range of from >0° C. to 45° C., optionally at least in the temperature range of from −5° C. to 50° C. The temperature range of freedom from hysteresis may be even wider, making the material or the component also suitable for applications at temperatures of up to at least 100° C. and even above that.

Further details on the thermal hysteresis have already been described above in connection with the precision component provided according to the invention. This disclosure is fully incorporated into the description of the glass ceramic.

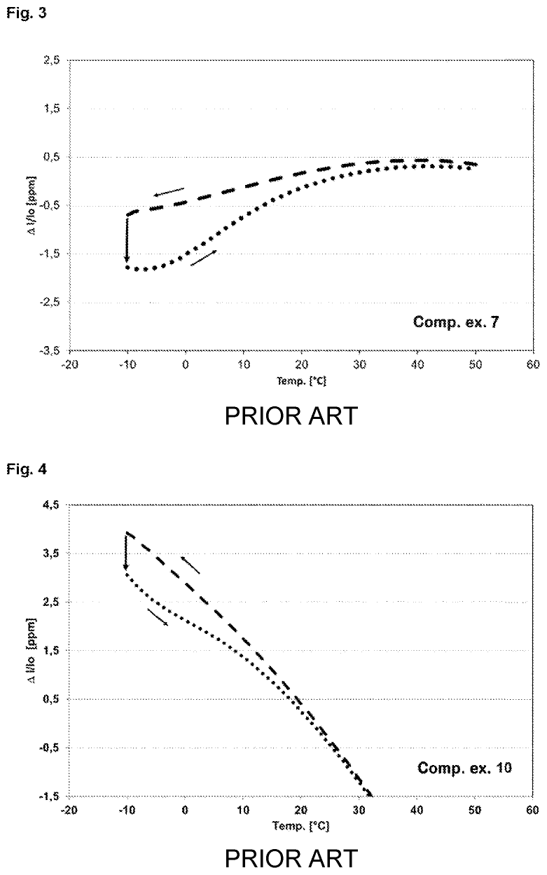

FIGS. 2 to 9 show the thermal expansion curves of known LAS glass ceramics, the curves all being produced by the same method as the LAS glass ceramics provided according to the invention (FIGS. 10 and 11 and FIGS. 31 to 33). In the case of the materials shown in FIGS. 3 to 8, the cooling curves (dashed lines) and heating curves (dotted lines) are in each case clearly spaced apart from one another precisely at lower temperatures. At 10° C., the difference is more than 0.1 ppm, and up to about 1 ppm in the case of individual comparative examples. In other words, the materials exhibit considerable thermal hysteresis in the relevant temperature range of at least 10° C. to 35° C.

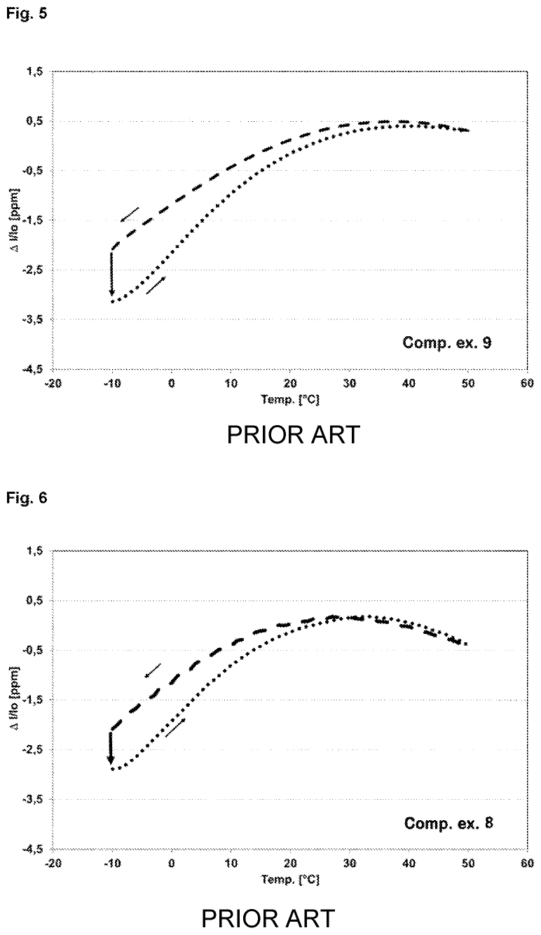

The LAS glass ceramics investigated, which are shown in FIGS. 2 to 5 (comparative examples 7, 9 and 10 in Table 2), all contain MgO and ZnO and have thermal hysteresis over wide ranges within the temperature interval 10° C. to 35° C. FIGS. 6 and 7 show the hysteresis curves of LAS glass ceramics (comparative examples 8 and 14 in Table 2) which are MgO-free but contain ZnO. Both materials exhibit strongly increasing thermal hysteresis below 15° C. FIG. 8 shows the hysteresis curve of an LAS glass ceramic (comparative example 15 in Table 2) which is ZnO-free but contains MgO. This material likewise exhibits a strongly increasing thermal hysteresis below 15° C. As can be seen in FIG. 9, this known material (comparative example 1 in Table 2) has no thermal hysteresis, but the steep curve shows that it is not a zero-expansion material. The average CTE here is −0.24 ppm/K.

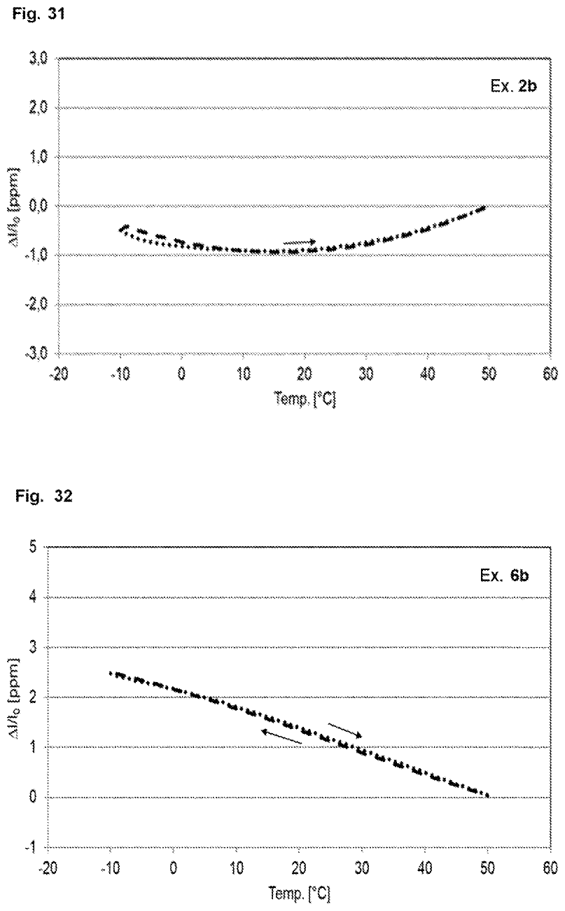

LAS glass ceramics provided according to the invention have a very low content of MgO and/or ZnO or are optionally free from MgO and ZnO. As can be seen in FIGS. 10 and 11 as well as in FIGS. 31 to 33, the heating curves and the cooling curves lie one above the other at least in the temperature range of from 10° C. to 35° C. However, the materials are not only hysteresis-free in the range of from 10° C. to 35° C., but also at least in the range of from 5 to 35° C., optionally at least in the temperature range of from 5 to 45° C., optionally at least in the range of from >0° C. to 45° C. Example 7 from FIG. 11 is also hysteresis-free at least in the temperature range of from −5° C. to 50° C., optionally also at even higher and even lower temperatures.

Index F

It may be advantageous if the expansion curve of the LAS glass ceramic has a flat profile in the temperature range of from 0° C. to 50° C. As an indication of the extent to which the curve profile of the thermal expansion deviates from a single linear profile, the index F can be used as a measure of the flatness of the expansion curve, where F=TCL (0; 50° C.)/expansion (0; 50° C.)|. It may thus be advantageous if the index F is <1.2, optionally <1.1, optionally at most 1.05. The closer the index F is to 1, the flatter the expansion curve. FIGS. 12, 13, 18 and 34 show that some embodiments of the LAS glass ceramic have a flat profile of the expansion curve (here F=1), both in the temperature range 0° C. to 50° C. and in the wider temperature range −30° C. to 70° C. In comparison, FIGS. 14 to 17 and 19 show that known materials exhibit a substantially steeper and curved profile of the expansion curves in the temperature ranges considered.

Alternative index f_{T.i.}

For some variants, depending on the field of application of the component, a flat profile of the expansion curve can also be desired for another temperature interval (T.i.), optionally in the temperature range (20;40), (20;70) and/or (−10; 30). The alternative index f_{T.i.} has the unit (ppm/K) and is defined as f_{T.i.}=TCL_{(T.i.)}/width of the temperature interval (T.i.), where T.i. describes the respective temperature interval considered. It may be advantageous if the glass ceramic has an alternative index f_{(20;40)}><0.024 ppm/K and/or an alternative index f_{(20;70)}<0.039 ppm/K and/or an alternative index f_{(-10;30)}<0.015 ppm/K, which can be seen in FIGS. 27 to 30, 35 and 36.

Further details on the index F and on the alternative index f_{T.i.} and on the relative change in length (dl/l₀) in the temperature ranges of from 20° C. to 30° C., from 20° C. to 35° C. and/or from 20° C. to 40° C. have already been described above in connection with the precision component provided according to the invention. This disclosure is fully incorporated into the description of the glass ceramic.

Additional Advantageous Features

FIGS. 20 and 21 as well as 37 to 41 show that some embodiments of the LAS glass ceramic have a CTE plateau. A glass ceramic with a plateau, i.e. with an optimized zero expansion over a wide temperature range, may offer the same advantages which have already been described above in connection with the flat profile of the expansion curves and the index F as well as the alternative index f_{T}i.

It may be advantageous if the differential CTE has a plateau close to 0 ppm/K, i.e. the differential CTE is less than 0±0.025 ppm/K in a temperature interval T_{P} with a width of at least 40 K, optionally at least 50 K. The temperature interval of the CTE plateau is denoted by Tₚ. In some embodiments, the differential CTE can be less than 0±0.015 ppm/K in a temperature interval T_{P} with a width of at least 40 K.

FIGS. 22, 23 and 26 as well as FIGS. 42 and 43, which have already been described above in connection with the precision component, show that some embodiments of the LAS glass ceramic have CTE curves, the slope of which is very small in wide temperature ranges. It may be advantageous if the CTE-T curve in a temperature interval having a width of at least 30 K has a slope of <0±2.5 ppb/K², optionally <0±2 ppb/K², optionally <0±1.5 ppb/K², optionally <0±1 ppb/K², according to some variants <0 0.8 ppb/K², according to some variants even <0±0.5 ppb/K².

The feature of the shallow slope can be present with or without formation of an advantageous CTE plateau.

The glass ceramic provided according to the invention or precision component made from the glass ceramic provided according to the invention optionally has a modulus of elasticity, determined according to ASTM C 1259 (2021), of 75 GPa to 100 GPa, optionally of 80 GPa to 95 GPa. The use of such precision components in “high-NA-EUVL systems” or in other EUVL systems with increased wafer throughput can be advantageous since, inter alia, the dynamic positioning accuracy of a photomask can be increased by the higher modulus of elasticity.

Further details regarding the CTE plateau, the slope of the CTE-T curve, the zero crossing of the CTE-T curve and the adaptation of the CTE profile or the expansion profile to different application temperatures by varying the ceramization temperature and/or ceramization duration (see, for example, FIGS. 24, 25, 44, 45) etc. have already been described above in connection with the precision component provided according to the invention. This disclosure is fully incorporated into the description of the glass ceramic.

### Examples

Tables 1a, 1b and 2 show compositions of examples of glass ceramics provided according to the invention, in particular for precision components and compositions of comparative examples, as well as their properties.

The compositions stated in Table 1a were melted from commercial raw materials, such as oxides, carbonates and nitrates, in conventional preparation processes. The green glasses produced according to Table 1a were first ceramized at the respectively specified maximum temperature over the specified duration.

The production of the glass ceramic for precision components, in particular large precision components, is described, for example, in WO 2015/124710 A1.

Table 1a shows 23 examples (Ex.) provided according to the invention which are hysteresis-free at least in a temperature range of from 10° C. to 35° C. and have zero expansion. Examples 6, 18, 19 and 20 show incipient thermal hysteresis only from about 0° C., examples 11, 17 and 23 only from −5° C. Examples 7, 12, 14, 15 and 22 are hysteresis-free over the entire temperature range from −5° C. to 45° C. In addition, the index F<1.2, i.e. the profile of the expansion curve in the temperature range of from 0° C. to 50° C., is flat in all examples. Furthermore, the examples have a processing temperature ≤1330° C., thus enabling the glass ceramics to be produced with high homogeneity in large-scale industrial production plants. The processing temperatures as indicated in Tables 1a, 1b and 2 were determined in accordance with DIN ISO 7884-1 (2014—Source: Schott Techn. Glass Catalogue).

In example 5, after ceramization at a maximum of 780° C. over a period of 2.5 days, the average CTE was determined for further temperature intervals with the following result: CTE (20; 300° C.): −0.17 ppm/K, CTE (20; 500° C.): −0.02 ppm/K, CTE (20; 700° C.): 0.17 ppm/K.

For example 7, the average CTE was determined for the temperature range 19° C. to 25° C. with the result that example 7 has a CTE (19;25) of −1.7 ppb/K.

The compositions stated in Table 1b were melted from commercial raw materials, such as oxides, carbonates and nitrates, in conventional production processes, using different fining agents or fining agent combinations. Within the scope of the invention, As₂O₃ as a fining agent was significantly reduced, or fining agents without As₂O₃ were used. In example 7b, fined with ₄SnO₂ and sulfate, 0.19 mol % of SO₃ as Na₂SO₄ was added to the synthesis, which corresponds to 0.22 mol % of SO₄²⁻. In the X-ray fluorescence analysis of the green glass or the glass ceramic, the SO₃ content was below the detection limit of <0.02% by weight. The green glasses produced according to Table 1b were first ceramized at the respectively specified maximum temperature over the specified duration. For examples 6b and 7b, samples were also prepared which were ceramized with different ceramization parameters (in particular different maximum temperatures), as has already been explained above in connection with the figures.

The production of a glass ceramic for a precision component, in particular a large precision component, is described, for example, in WO 2015/124710 A1.

Table 1b shows 15 examples (Ex.) provided according to the invention which are hysteresis-free at least in a temperature range of from 10° C. to 35° C. and have zero expansion. Examples 1b, 8b and 13b show incipient thermal hysteresis only from about 5° C., examples 2b and 9b only from about −5° C. Examples 3b, 5b, 6b and 7b are hysteresis-free over the entire temperature range from −5° C. to 45° C. In addition, the index F<1.2, i.e. the profile of the expansion curve in the temperature range of from 0° C. to 50° C., is flat in all examples. Furthermore, the examples have a processing temperature <1330° C., thus enabling the glass ceramics to be produced with high homogeneity in large-scale industrial production plants. The processing temperatures as indicated in Tables 1a, 1b and 2 were determined in accordance with DIN ISO 7884-1 (2014—Source: Schott Techn. Glass Catalogue).

In example 7b, after ceramization at a maximum of 810° C. over a period of 2.5 days, the average CTE was determined for further temperature intervals with the following result: CTE (20; 300° C.): +0.13 ppm/K, CTE (20; 500° C.): +0.34 ppm/K, CTE (20; 700° C.): +0.59 ppm/K.

For examples 6b and 7b, the average CTE was determined for the temperature range 19° C. to 25° C., example 6b having a CTE (19;25) of 0.77 ppb/K and example 7b having a CTE (19;25) of 0.37 ppb/K.

Example 10b was fined with SnO₂. In addition, nitrate was contained as an oxidizing agent, more specifically the components BaO and Na₂O were each used as nitrate raw materials in order to make the melt oxidizing.

Example 15b was fined with SnO₂. SnO₂ also served as a nucleating agent. Another nucleating agent was ZrO₂.

Table 2 shows comparative examples (Comp. ex.). Comparative examples 1, 2, 5 and 6 have neither MgO nor ZnO, but the average CTE(0;50) is greater than 0±0.1×10⁻⁶/K, i.e. these comparative examples are not zero-expansion. Furthermore, comparative examples 1 and 2 have a processing temperature >1330° C. These materials are very viscous, and it is therefore impossible to produce components with high homogeneity from them in large-scale industrial production plants.

Comparative examples 7 to 16 all contain MgO and/or ZnO, and most of them are zero-expansion. However, these comparative examples show a thermal hysteresis of substantially more than 0.1 ppm, at least in the temperature range of from 10° C. to 35° C. At room temperature, i.e. 22° C., this group of comparative examples has thermal hysteresis except for comparative examples 14 and 16. Comparative example 9 further has, although it is zero-expansion, an unfavorably steep profile of the expansion curve in the temperature range of from 0° C. to 50° C., which can be seen from the high value of the index F.

Where there are blank fields in the composition information in the following tables, this means that this (these) component(s) was (were) intentionally not added or not included.

Table 3a shows the calculated alternative index f_{(T.i.)} for different temperature intervals for some embodiments provided according to the invention from Table 1a and for a comparative example, from which it is clear that the expansion curves of the examples in the designated temperature ranges each have a flatter profile than the comparative example.

Table 3b shows the calculated alternative index f_{(T.i.)} for different temperature intervals for some embodiments provided according to the invention from Table 1b and for a comparative example, from which it is clear that the expansion curves of the examples in the designated temperature ranges each have a flatter profile than the comparative example.

Table 4a shows the CTE homogeneity for different component sizes for components with a composition according to example 7 provided according to the invention from Table 1a, from which it is clear that the components investigated have high CTE homogeneities both in the temperature range of from 0° C. to 50° C. and in the temperature range of from 19 to 25° C. The modulus of elasticity (also referred to as E modulus), determined in accordance with ASTM C 1259 (2021), is also indicated.

Table 4b shows the CTE homogeneity for different component sizes for components with a composition according to example 6b provided according to the invention from Table b, from which it is clear that the components investigated have high CTE homogeneities both in the temperature range of from 0° C. to 50° C. and in the temperature range of from 19 to 25° C. The modulus of elasticity (also referred to as E modulus), determined in accordance with ASTM C 1259 (2021), is also indicated.

It is clear to those skilled in the art that, depending on the application temperature of the glass ceramic or the precision component comprising the glass ceramic, a glass ceramic having the desired properties, in particular with regard to thermal hysteresis and/or average CTE and/or CTE homogeneity, is selected.

TABLE 1a
Compositions, ceramization and properties (mol %)

| Example No. (Ex.) | 1 | 2 | 3 | 4 | 5 | 6 |
|---|---|---|---|---|---|---|
| Li₂O | 8.5 | 8.6 | 8.65 | 8.75 | 9.0 | 8.7 |
| Na₂O | 0.6 | 0.5 | 0.5 | 0.4 | | 0.2 |
| K₂O | 1.65 | 1.6 | 1.65 | 1.45 | 0.75 | 0.6 |
| MgO | | | | | | |
| ZnO | | | | | | |
| CaO | 0.45 | 0.7 | 1.2 | 1.6 | 2.1 | 2.35 |
| BaO | | | | 0.4 | 0.4 | 0.75 |
| SrO | | | | | | |
| Al₂O₃ | 16.1 | 15.2 | 16.65 | 17.55 | 15.85 | 16.4 |
| SiO₂ | 68.1 | 67.95 | 66.5 | 65.1 | 65.5 | 65.2 |
| P₂O₅ | 1.35 | 2.25 | 1.65 | 1.6 | 3.05 | 2.5 |
| TiO₂ | 2.05 | 2.0 | 2.0 | 1.95 | 2.1 | 2.05 |
| ZrO₂ | 0.95 | 0.95 | 0.95 | 0.95 | 1.05 | 1.0 |
| As₂O₃ | 0.25 | 0.25 | 0.25 | 0.25 | 0.2 | 0.25 |
| Sum | 100.0 | 100.0 | 100.0 | 100.0 | 100.0 | 100.0 |
| SiO₂ + (5 × Li₂O) | 110.60 | 110.95 | 109.75 | 108.85 | 110.50 | 108.70 |
| MgO + ZnO | | | | | | |
| ΣR₂O (R = Na, K, Cs, Rb) | 2.25 | 2.1 | 2.15 | 1.85 | 0.75 | 0.8 |
| ΣRO (R = Ca, Ba, Sr) | 0.45 | 0.7 | 1.2 | 2.0 | 2.5 | 3.10 |
| Va [° C.] | 1312 | 1318 | 1292 | 1271 | | 1275 |
| Ceram. temperature [° C.] | 760 | 780 | 780 | 760 | 780 | 770 |
| Ceram. duration [days] | 2.5 | 2.5 | 2.5 | 2.5 | 2.5 | 2.5 |
| Cryst. phase [% by volume] | 53 | 54 | 53 | 49 | 64 | 57 |
| Cryst. size [nm] | 39 | 40 | 45 | 42 | 40 | 40 |
| Average CTE(0; +50° C.) | 0.05 | 0.07 | 0.10 | 0.10 | −0.03 | 0.01 |
| [ppm/K] | | | | | | |
| TCL (0; +50° C.) | 2.47 | 3.41 | 5.22 | 5.1 | 1.64 | 0.57 |
| \|Expansion at 50° C.\| | 2.47 | 3.41 | 5.22 | 5.1 | 1.64 | 0.57 |
| Index F | 1.00 | 1.00 | 1.00 | 1.00 | 1.00 | 1.00 |
| Hyst. @ 45° C. [ppm] | <0.1 | <0.1 | <0.1 | <0.1 | <0.1 | <0.1 |
| Hyst. @ 35° C. [ppm] | <0.1 | <0.1 | <0.1 | <0.1 | <0.1 | <0.1 |
| Hyst. @ 30° C. [ppm] | <0.1 | <0.1 | <0.1 | <0.1 | <0.1 | <0.1 |
| Hyst. @ 22° C. [ppm] | <0.1 | <0.1 | <0.1 | <0.1 | <0.1 | <0.1 |
| Hyst. @ 10° C. [ppm] | <0.1 | <0.1 | <0.1 | <0.1 | <0.1 | <0.1 |
| Hyst. @ +5° C. [ppm] | <0.1 | <0.1 | <0.1 | <0.1 | <0.1 | <0.1 |
| Hyst. @ 0° C. [ppm] | | | | | | 0.1 |
| Hyst. @ −5° C. [ppm] | | | | | | 0.16 |
| Ceram. temperature [° C.] | 760 | 780 | 780 | 760 | 800 | 780 |
| Ceram. duration [days] | 2.5 | 2.5 | 2.5 | 2.5 | 2.5 | 2.5 |
| Average CTE | 0.03 | 0.06 | 0.09 | 0.08 | 0.02 | 0.01 |
| (−30; +70° C.)[ppm/K] | | | | | | |
| Average CTE | 0.02 | 0.05 | 0.08 | 0.08 | 0.004 | 0.006 |
| (−40; +80° C.)[ppm/K] | | | | | | |

Compositions, ceramization and properties (mol %)

| Example No. (Ex.) | 7 | 8 | 9 | 10 | 11 | 12 |
|---|---|---|---|---|---|---|
| Li₂O | 9.15 | 9.0 | 8.9 | 9.25 | 8.35 | 9.3 |
| Na₂O | 0.6 | 0.45 | | 0.1 | 1.1 | 0.8 |
| K₂O | 0.9 | 0.5 | | 0.65 | | 0.2 |
| MgO | | | | | | |
| ZnO | | | | | | |
| CaO | 0.95 | 2.5 | 2.5 | 1.8 | 1.1 | |
| BaO | 0.55 | | | 0.6 | 0.85 | 1.4 |
| SrO | | | 0.6 | | 0.8 | |
| Al₂O₃ | 17.95 | 17.3 | 17.2 | 18.35 | 17.4 | 17.9 |
| SiO₂ | 64.0 | 63.05 | 64.55 | 62.55 | 66.35 | 64.1 |
| P₂O₅ | 2.6 | 3.85 | 2.9 | 3.35 | 0.8 | 2.85 |
| TiO₂ | 2.05 | 2.05 | 2.1 | 2.05 | 2.0 | 2.15 |
| ZrO₂ | 1.0 | 1.05 | 1.05 | 1.05 | 1.0 | 1.05 |
| As₂O₃ | 0.25 | 0.25 | 0.25 | 0.25 | 0.25 | 0.25 |
| Sum | 100.0 | 100.0 | 100.0 | 100.0 | 100.0 | 100.0 |
| SiO₂ + (5 × Li₂O) | 109.75 | 108.05 | 109.05 | 108.80 | 108.10 | 110.60 |
| MgO + ZnO | | | | | | |
| ΣR₂O (R = Na, K, Cs, Rb) | 1.50 | 0.95 | | 0.75 | 1.1 | 1.0 |
| ΣRO (R = Ca, Ba, Sr) | 1.5 | 2.5 | 3.1 | 2.4 | 2.75 | 1.4 |
| Va [° C.] | 1267 | 1256 | 1258 | 1248 | | |
| Ceram. temperature [° C.] | 810 | 800 | 800 | 810 | 780 | 820 |
| Ceram. duration [days] | 2.5 | 2.5 | 2.5 | 2.5 | 2.5 | 2.5 |
| Cryst. phase [% by volume] | 58 | 62 | 64 | 64 | 52 | 60 |
| Cryst. size [nm] | 48 | 47 | 45 | 46 | 47 | 47 |
| Average CTE(0; +50° C.) | 0.007 | 0.06 | −0.08 | −0.08 | −0.03 | −0.08 |
| [ppm/K] | | | | | | |
| TCL (0; +50° C.) | 0.37 | 3 | 3.88 | 3.89 | 1.34 | 3.96 |
| \|Expansion at 50° C.\| | 0.37 | 2.88 | 3.78 | 3.89 | 1.34 | 3.96 |
| Index F | 1.00 | 1.04 | 1.03 | 1.00 | 1.00 | 1.00 |
| Hyst. @ 45° C. [ppm] | <0.1 | <0.1 | <0.1 | <0.1 | <0.1 | <0.1 |
| Hyst. @ 35° C. [ppm] | <0.1 | <0.1 | <0.1 | <0.1 | <0.1 | <0.1 |
| Hyst. @ 30° C. [ppm] | <0.1 | <0.1 | <0.1 | <0.1 | <0.1 | <0.1 |
| Hyst. @ 22° C. [ppm] | <0.1 | <0.1 | <0.1 | <0.1 | <0.1 | <0.1 |
| Hyst. @ 10° C. [ppm] | <0.1 | <0.1 | <0.1 | <0.1 | <0.1 | <0.1 |
| Hyst. @ +5° C. [ppm] | <0.1 | <0.1 | <0.1 | <0.1 | <0.1 | <0.1 |
| Hyst. @ 0° C. [ppm] | <0.1 | | | | <0.1 | <0.1 |
| Hyst. @ −5° C. [ppm] | <0.1 | | | | 0.15 | <0.1 |
| Ceram. temperature [° C.] | 820 | 780 | 800 | 810 | 780 | 820 |
| Ceram. duration [days] | 2.5 | 2.5 | 2.5 | 2.5 | 2.5 | 2.5 |
| Average CTE | 0.03 | 0.006 | −0.08 | −0.07 | −0.05 | −0.10 |
| (−30; +70° C.)[ppm/K] | | | | | | |
| Average CTE | 0.02 | −0.01 | −0.10 | −0.08 | −0.05 | −0.1 |
| (−40; +80° C.)[ppm/K] | | | | | | |

Compositions, ceramization and properties (mol %)

| Example No. (Ex.) | 13 | 14 | 15 | 16 | 17 | 18 |
|---|---|---|---|---|---|---|
| Li₂O | 9.1 | 9.35 | 8.9 | 8.6 | 9.05 | 8.7 |
| Na₂O | 0.1 | 0.45 | 0.45 | 0.65 | 0.6 | 0.9 |
| K₂O | 0.6 | 1.1 | 0.95 | 1.65 | 0.85 | 0.3 |
| MgO | | | | | 0.25 | |
| ZnO | | | | | 0.15 | 0.45 |
| CaO | 1.3 | 1.1 | 1.25 | | 0.85 | 0.65 |
| BaO | 1.1 | 0.4 | 1.05 | | 0.45 | 1.15 |
| SrO | | | | | | |
| Al₂O₃ | 17.9 | 18.85 | 16.95 | 16.35 | 18.0 | 18.1 |
| SiO₂ | 62.0 | 61.6 | 67.15 | 67.9 | 63.75 | 64.0 |
| P₂O₅ | 4.6 | 3.95 | | 1.6 | 2.75 | 2.45 |
| TiO₂ | 2.1 | 2.0 | 2.05 | 2.05 | 2.05 | 2.1 |
| ZrO₂ | 1.05 | 1.0 | 1.05 | 1.0 | 1.05 | 1.0 |
| As₂O₃ | 0.15 | 0.2 | 0.2 | 0.2 | 0.2 | 0.2 |
| Sum | 100.0 | 100.0 | 100.0 | 100.0 | 100.0 | 100.0 |
| SiO₂ + (5 × Li₂O) | 107.50 | 108.35 | 111.65 | 110.90 | 109.00 | 107.50 |
| MgO + ZnO | | | | | 0.40 | 0.45 |
| ΣR₂O (R = Na, K, Cs, Rb) | 0.70 | 1.55 | 1.4 | 2.3 | 1.45 | 1.2 |
| ΣRO (R = Ca, Ba, Sr) | 2.40 | 1.50 | 2.3 | | 1.3 | 1.8 |
| Va [° C.] | | | | | | |
| Ceram. temperature [° C.] | 790 | 815 | 815 | 770 | 830 | 815 |
| Ceram. duration [days] | 2.5 | 2.5 | 2.5 | 2.5 | 2.5 | 2.5 |
| Cryst. phase [% by volume] | 62 | 61 | 53 | 52 | 59 | 59 |
| Cryst. size [nm] | 46 | 50 | 46 | 39 | 48 | 48 |
| Average CTE(0; +50° C.) | 0.08 | −0.01 | 0.08 | 0.04 | 0.01 | −0.015 |
| [ppm/K] | | | | | | |
| TCL (0; +50° C.) | 4.00 | 0.58 | 4.14 | 2.07 | 0.61 | 0.74 |
| \|Expansion at 50° C.\| | 4.00 | 0.54 | 4.14 | 2.07 | 0.61 | 0.74 |
| Index F | 1.00 | 1.07 | 1.00 | 1.00 | 1.00 | 1.00 |
| Hyst. @ 45° C. [ppm] | <0.1 | <0.1 | <0.1 | | <0.1 | <0.1 |
| Hyst. @ 35° C. [ppm] | <0.1 | <0.1 | <0.1 | | <0.1 | <0.1 |
| Hyst. @ 30° C. [ppm] | <0.1 | <0.1 | <0.1 | | <0.1 | <0.1 |
| Hyst. @ 22° C. [ppm] | <0.1 | <0.1 | <0.1 | | <0.1 | <0.1 |
| Hyst. @ 10° C. [ppm] | <0.1 | <0.1 | <0.1 | | <0.1 | <0.1 |
| Hyst. @ +5° C. [ppm] | 0.11 | <0.1 | <0.1 | | <0.1 | <0.1 |
| Hyst. @ 0° C. [ppm] | 0.19 | <0.1 | <0.1 | | <0.1 | 0.11 |
| Hyst. @ −5° C. [ppm] | 0.22 | <0.1 | <0.1 | | 0.13 | 0.18 |
| Ceram. temperature [° C.] | 790 | 815 | | 770 | 820 | 815 |
| Ceram. duration [days] | 2.5 | 2.5 | | 2.5 | 2.5 | 2.5 |
| Average CTE | 0.12 | −0.02 | | 0.02 | −0.06 | −0.03 |
| (−30; +70° C.)[ppm/K] | | | | | | |
| Average CTE | 0.11 | −0.04 | | 0.01 | −0.07 | −0.04 |
| (−40; +80° C.)[ppm/K] | | | | | | |

Compositions, ceramization and properties (mol %)

| Example No. (Ex.) | 19 | 20 | 21 | 22 | 23 |
|---|---|---|---|---|---|
| Li₂O | 9.15 | 8.1 | 9.35 | 9.15 | 8.85 |
| Na₂O | 0.55 | 0.4 | 0.7 | 0.45 | 0.55 |
| K₂O | 0.85 | 1.0 | 0.25 | 0.6 | 0.85 |
| MgO | 0.30 | | | | |
| ZnO | 0.20 | | | | |
| CaO | 0.8 | 2.25 | 1.25 | 0.8 | 1.0 |
| BaO | 0.45 | | 1.1 | 0.8 | 0.70 |
| SrO | | | | | |
| Al₂O₃ | 17.75 | 15.45 | 16.85 | 16.85 | 14.45 |
| SiO₂ | 64.0 | 68.05 | 64.45 | 67.35 | 67.95 |
| P₂O₅ | 2.75 | 1.55 | 3.35 | | 2.50 |
| TiO₂ | 2.0 | 1.95 | | 3.80 | 1.95 |
| ZrO₂ | 1.0 | 1.0 | 2.5 | | 1.0 |
| As₂O₃ | 0.2 | 0.25 | 0.2 | 0.2 | 0.2 |
| Sum | 100.0 | 100.0 | 100.0 | 100.0 | 100.0 |
| SiO₂ + (5 × Li₂O) | 109.75 | 108.55 | 111.20 | 113.10 | 112.20 |
| MgO + ZnO | 0.5 | | | | |
| ΣR₂O (R = Na, K, Cs, Rb) | 1.4 | 1.4 | 0.95 | | 1.4 |
| ΣRO (R = Ca, Ba, Sr) | 1.25 | 2.25 | 2.35 | | 1.7 |
| Va [° C.] | | | | | |
| Ceram. temperature [° C.] | 815 | 770 | 810 | 825 | 800 |
| Ceram. duration [days] | 2.5 | 2.5 | 2.5 | 2.5 | 2.5 |
| Cryst. phase [% by volume] | 61 | 51 | 62 | 63 | 59 |
| Cryst. size [nm] | 50 | 33 | 76 | 33 | 42 |
| Average CTE(0; +50° C.) | −0.075 | 0.07 | −0.075 | −0.03 | 0.035 |
| [ppm/K] | | | | | |
| TCL (0; +50° C.) | 3.73 | 3.38 | 3.75 | 1.7 | 1.77 |
| \|Expansion at 50° C.\| | 3.73 | 3.38 | 3.75 | 1.7 | 1.77 |
| Index F | 1.00 | 1.00 | 1.00 | 1.00 | 1.00 |
| Hyst. @ 45° C. [ppm] | <0.1 | <0.1 | <0.1 | <0.1 | <0.1 |
| Hyst. @ 35° C. [ppm] | <0.1 | <0.1 | <0.1 | <0.1 | <0.1 |
| Hyst. @ 30° C. [ppm] | <0.1 | <0.1 | <0.1 | <0.1 | <0.1 |
| Hyst. @ 22° C. [ppm] | <0.1 | <0.1 | <0.1 | <0.1 | <0.1 |
| Hyst. @ 10° C. [ppm] | <0.1 | <0.1 | <0.1 | <0.1 | <0.1 |
| Hyst. @ +5° C. [ppm] | <0.1 | <0.1 | 0.12 | <0.1 | <0.1 |
| Hyst. @ 0° C. [ppm] | 0.14 | 0.1 | 0.17 | <0.1 | <0.1 |
| Hyst. @ −5° C. [ppm] | 0.21 | 0.17 | 0.21 | <0.1 | 0.11 |
| Ceram. temperature [° C.] | 815 | 770 | 810 | 825 | |
| Ceram. duration [days] | 2.5 | 2.5 | 2.5 | 2.5 | |
| Average CTE | −0.09 | 0.05 | −0.09 | −0.05 | |
| (−30; +70° C.)[ppm/K] | | | | | |
| Average CTE | −0.10 | 0.04 | −0.10 | −0.06 | |
| (−40; +80° C.)[ppm/K] | | | | | |

TABLE 1b
Compositions, ceramization and properties (mol %)

| Example No. (Ex.) | 1b | 2b | 3b | 4b | 5b | 6b | 7b |
|---|---|---|---|---|---|---|---|
| Li₂O | 8.9 | 8.35 | 8.9 | 8.6 | 9.1 | 9.15 | 9.1 |
| Na₂O | | 1.1 | 0.45 | 0.7 | 0.6 | 0.6 | 0.65 |
| K₂O | | | 1.0 | 1.65 | 0.9 | 0.85 | 0.9 |
| MgO | | | | | | | |
| ZnO | | | | | 0.21 | | |
| CaO | 2.5 | 1.1 | 1.25 | | 0.9 | 0.9 | 1.05 |
| BaO | | 0.85 | 1.05 | | 0.5 | 0.5 | 0.55 |
| SrO | 0.6 | 0.8 | | | | | |
| Al₂O₃ | 17.2 | 17.4 | 16.95 | 16.35 | 18.1 | 18.1 | 18.05 |
| SiO₂ | 64.35 | 66.15 | 67.2 | 67.95 | 63.8 | 63.8 | 63.7 |
| P₂O₅ | 2.9 | 0.8 | | 1.5 | 2.65 | 2.65 | 2.7 |
| TiO₂ | 2.1 | 2.0 | 2.0 | 2.05 | 2.05 | 2.0 | 2.05 |
| ZrO₂ | 1.05 | 1.0 | 1.0 | 1.0 | 1.0 | 1.05 | 1.05 |
| SnO₂ | 0.2 | | | | | 0.2 | 0.2 |
| Cl | | 0.2 | | | | | |
| Sb₂O₃ | 0.2 | 0.25 | 0.2 | 0.2 | 0.2 | 0.2 | |
| As₂O₃ | | | | | | | |
| Sum | 100.0 | 100.0 | 100.0 | 100.0 | 100.0 | 100.0 | 100.0 |
| SiO₂ + (5 × Li₂O) | 108.85 | 107.90 | 111.70 | 110.95 | 109.30 | 109.55 | 109.20 |
| MgO + ZnO | | | | | 0.21 | | |
| ΣR₂O (R = Na, K, Cs, Rb) | | 1.1 | 1.45 | 2.35 | 1.5 | 1.45 | 1.55 |
| ΣRO (R = Ca, Ba, Sr) | 3.1 | 2.75 | 2.30 | | 1.4 | 1.4 | 1.60 |
| Va [° C.] | 1258 | | | 1312 | | | |
| Ceram. temperature [° C.] | 800 | 790 | 815 | 800 | 820 | 820 | 825 |
| Ceram. duration [days] | 2.5 | 2.5 | 2.5 | 2.5 | 2.5 | 2.5 | 3 |
| Cryst. phase [% by | 64 | 52 | 53 | 52 | 57 | 58 | 58 |
| volume] | | | | | | | |
| Cryst. size [nm] | 45 | 47 | 46 | 45 | 47 | 49 | 49 |
| Average CTE(0; +50° C.) | −0.08 | 0.02 | 0.10 | 0.07 | −0.04 | 0.00 | −0.002 |
| [ppm/K] | | | | | | | |
| TCL (0; +50° C.) | 3.88 | 1.18 | 4.14 | 3.54 | 2.19 | 0.1 | 0.08 |
| \|Expansion at 50° C.\| | 3.78 | 1.18 | 4.14 | 3.54 | 2.19 | 0.1 | 0.08 |
| Index F | 1.03 | 1.00 | 1.00 | 1.00 | 1.00 | 1.00 | 1.00 |
| Hyst. @ 45° C. [ppm] | <0.1 | <0.1 | <0.1 | <0.1 | <0.1 | <0.1 | <0.1 |
| Hyst. @ 35° C. [ppm] | <0.1 | <0.1 | <0.1 | <0.1 | <0.1 | <0.1 | <0.1 |
| Hyst. @ 30° C. [ppm] | <0.1 | <0.1 | <0.1 | <0.1 | <0.1 | <0.1 | <0.1 |
| Hyst. @ 22° C. [ppm] | <0.1 | <0.1 | <0.1 | <0.1 | <0.1 | <0.1 | <0.1 |
| Hyst. @ 10° C. [ppm] | <0.1 | <0.1 | <0.1 | <0.1 | <0.1 | <0.1 | <0.1 |
| Hyst. @ +5° C. [ppm] | 0.12 | <0.1 | <0.1 | <0.1 | <0.1 | <0.1 | <0.1 |
| Hyst. @ 0° C. [ppm] | 0.2 | <0.1 | <0.1 | | <0.1 | <0.1 | <0.1 |
| Hyst. @ −5° C. [ppm] | 0.3 | 0.15 | <0.1 | | <0.1 | <0.1 | <0.1 |
| Ceram. temperature [° C.] | 800 | 780 | 830 | 800 | 820 | 820 | 830 |
| Ceram. duration [days] | 2.5 | 2.5 | 2.5 | 2.5 | 2.5 | 2.5 | 2.5 |
| Average CTE (−30; +70° C.) | −0.08 | −0.05 | 0.08 | 0.05 | −0.06 | −0.01 | −0.04 |
| [ppm/K] | | | | | | | |
| Average CTE (−40; +80° C.) | −0.10 | −0.05 | 0.08 | n.a. | −0.07 | −0.02 | −0.05 |
| [ppm/K] | | | | | | | |

Compositions, ceramization and properties (mol %)

| Example No. (Ex.) | 8b | 9b | 10b | 11b | 12b | 13b | 14b |
|---|---|---|---|---|---|---|---|
| Li₂O | 9.2 | 8.95 | 8.85 | 8.9 | 8.1 | 9.35 | 9.2 |
| Na₂O | | 0.6 | 0.4 | 0.55 | 0.4 | 0.7 | 0.45 |
| K₂O | | 0.8 | 0.9 | 0.8 | 1.0 | 0.25 | 0.6 |
| MgO | | 0.17 | | 0.35 | | | |
| ZnO | | 0.13 | | 0.15 | | | |
| CaO | 2.5 | 1.0 | 1.3 | 0.9 | 2.3 | 1.25 | 0.8 |
| BaO | | 0.5 | 0.85 | 0.45 | | 1.1 | 0.8 |
| SrO | 0.7 | | | | | | |
| Al₂O₃ | 18.7 | 18.1 | 18.05 | 17.9 | 15.5 | 16.8 | 16.8 |
| SiO₂ | 62.45 | 63.7 | 62.3 | 63.8 | 68.1 | 64.45 | 67.3 |
| P₂O₅ | 3.1 | 2.8 | 4.0 | 2.9 | 1.5 | 3.3 | |
| TiO₂ | 2.0 | 2.0 | 2.0 | 2.0 | 1.9 | | 3.85 |
| ZrO₂ | 1.05 | 1.05 | 1.05 | 1.05 | 1.0 | 2.55 | |
| SnO₂ | 0.2 | 0.2 | 0.3 | | | | |
| Cl | 0.1 | | | | | | |
| Sb₂O₃ | | | | 0.25 | 0.2 | 0.25 | 0.2 |
| As₂O₃ | | 0.025 | | | | | |
| Sum | 100.0 | 100.0 | 100.0 | 100.0 | 100.0 | 100.0 | 100.0 |
| SiO₂ + (5 × Li₂O) | 108.45 | 108.45 | 106.55 | 108.30 | 108.60 | 111.20 | 113.30 |
| MgO + ZnO | | 0.30 | | 0.50 | | | |
| ΣR₂O (R = Na, K, Cs, Rb) | | 1.4 | 1.3 | 1.35 | 1.4 | 0.95 | 1.05 |
| ΣRO (R = Ca, Ba, Sr) | 3.2 | 1.5 | 2.15 | 1.35 | 2.3 | 2.35 | 1.6 |
| Va [° C.] | | | | | | | |
| Ceram. temperature [° C.] | 830 | 830 | 800 | 830 | 780 | 800 | 815 |
| Ceram. duration [days] | 3.75 | 2.5 | 2.5 | 2.5 | 2.5 | 2.5 | 2.5 |
| Cryst. phase [% by | 67 | 57 | 57 | 60 | 52 | | 64 |
| volume] | | | | | | | |
| Cryst. size [nm] | 39 | 50 | 51 | 49 | 33 | | 33 |
| Average CTE(0; +50° C.) | 0.04 | −0.008 | 0.05 | 0.06 | 0.06 | 0.02 | −0.09 |
| [ppm/K] | | | | | | | |
| TCL (0; +50° C.) | 4.64 | 0.4 | 2.61 | 3.2 | 3.19 | 1.02 | 4.55 |
| \|Expansion at 50° C.\| | 4.16 | 0.4 | 2.61 | 3.2 | 3.19 | 1.02 | 4.55 |
| Index F | 1.12 | 1.00 | 1.00 | 1.00 | 1.00 | 1.00 | 1.00 |
| Hyst. @ 45° C. [ppm] | <0.1 | <0.1 | <0.1 | <0.1 | <0.1 | <0.1 | <0.1 |
| Hyst. @ 35° C. [ppm] | <0.1 | <0.1 | <0.1 | <0.1 | <0.1 | <0.1 | <0.1 |
| Hyst. @ 30° C. [ppm] | <0.1 | <0.1 | <0.1 | <0.1 | <0.1 | <0.1 | <0.1 |
| Hyst. @ 22° C. [ppm] | <0.1 | <0.1 | <0.1 | <0.1 | <0.1 | <0.1 | <0.1 |
| Hyst. @ 10° C. [ppm] | <0.1 | <0.1 | <0.1 | <0.1 | <0.1 | <0.1 | <0.1 |
| Hyst. @ +5° C. [ppm] | 0.16 | <0.1 | <0.1 | <0.1 | <0.1 | 0.13 | <0.1 |
| Hyst. @ 0° C. [ppm] | 0.26 | <0.1 | <0.1 | 0.14 | 0.1 | 0.22 | |
| Hyst. @ −5° C. [ppm] | 0.4 | 0.11 | 0.11 | 0.205 | 0.17 | 0.27 | |
| Ceram. temperature [° C.] | 830 | 830 | 830 | 830 | 780 | | 815 |
| Ceram. duration [days] | 3.75 | 2.5 | 2.5 | 2.5 | 2.5 | | 2.5 |
| Average CTE (−30; +70° C.) | 0.18 | 0.01 | 0.05 | 0.05 | 0.05 | | −0.03 |
| [ppm/K] | | | | | | | |
| Average CTE (−40; +80° C.) | 0.18 | 0.00 | 0.04 | 0.04 | 0.04 | | −0.01 |
| [ppm/K] | | | | | | | |

Compositions, ceramization and properties (mol %)

| Example No. (Ex.) | 15b |
|---|---|
| Li₂O | 9.0 |
| Na₂O | 0.65 |
| K₂O | 0.7 |
| MgO | |
| ZnO | |
| CaO | 1.0 |
| BaO | 1.55 |
| SrO | |
| Al₂O₃ | 18.1 |
| SiO₂ | 64.65 |
| P₂O₅ | 2.15 |
| TiO₂ | |
| ZrO₂ | 1.6 |
| SnO₂ | 0.6 |
| Cl | |
| Sb₂O₃ | |
| As₂O₃ | |
| Sum | 100.0 |
| SiO₂ + (5 × Li₂O) | 109.65 |
| MgO + ZnO | |
| ΣR₂O (R = Na, K, Cs, Rb) | 1.35 |
| ΣRO (R = Ca, Ba, Sr) | 2.55 |
| Va [° C.] | |
| Ceram. temperature [° C.] | 840 |
| Ceram. duration [days] | 2.5 |
| Cryst. phase [% by | 52 |
| volume] | |
| Cryst. size [nm] | 61 |
| Average CTE(0; +50° C.) | −0.10 |
| [ppm/K] | |
| TCL (0; +50° C.) | 5.04 |
| \|Expansion at 50° C.\| | 5.04 |
| Index F | 1.00 |
| Hyst. @ 45° C. [ppm] | <0.1 |
| Hyst. @ 35° C. [ppm] | <0.1 |
| Hyst. @ 30° C. [ppm] | <0.1 |
| Hyst. @ 22° C. [ppm] | <0.1 |
| Hyst. @ 10° C. [ppm] | <0.1 |
| Hyst. @ +5° C. [ppm] | <0.1 |
| Hyst. @ 0° C. [ppm] | 0.13 |
| Hyst. @ −5° C. [ppm] | 0.18 |
| Ceram. temperature [° C.] | |
| Ceram. duration [days] | |
| Average CTE (−30; +70° C.) | |
| [ppm/K] | |
| Average CTE (−40; +80° C.) | |
| [ppm/K] | |

TABLE 2
Compositions, ceramization and properties (mol %)

| | Comparative Example No. (Comp. ex.) | | | |
|---|---|---|---|---|
| | 1 | 2 | 5 | 6 |
| Li₂O | 8.1 | 9.15 | 9.45 | 9.5 |
| Na₂O | 0.4 | 0.4 | 0.2 | 0.1 |
| K₂O | 0.15 | 0.2 | 0.7 | 0.55 |
| MgO | | | | |
| ZnO | | | | |
| CaO | 4.15 | | 2.2 | 0.4 |
| BaO | | 0.6 | | 1.75 |
| SrO | | | | |
| Al₂O₃ | 12.45 | 14.2 | 16.75 | 16.6 |
| SiO₂ | 72.3 | 71.7 | 64.15 | 65.55 |
| P₂O₅ | | 0.62 | 3.3 | 2.2 |
| TiO₂ | 1.3 | 1.75 | 2.05 | 2.1 |
| ZrO₂ | 1.0 | 1.2 | 1.0 | 1.05 |
| As₂O₃ | 0.15 | 0.15 | 0.2 | 0.2 |
| Sum | 100.0 | 100.0 | 100.0 | 100.0 |
| SiO₂ + (5 × Li₂O) | | | | |
| MgO + ZnO | | | | |
| ΣR₂O (R = Na, K, Cs, Rb) | 0.55 | 0.6 | 0.9 | 0.65 |
| ΣRO (R = Ca, Ba, Sr) | 4.15 | 0.6 | 2.2 | 2.15 |
| Va [° C.] | 1345 | 1340 | | |
| Ceram. temperature [° C.] | 760 | | 800 | 800 |
| Ceram. duration [days] | 10 | | 2.5 | 2.5 |
| Cryst. phase [% by volume] | 60 | | 66 | 58 |
| Cryst. size [nm] | 63 | | 45 | 47 |
| Average CTE(0; +50° C.) | −0.25 | | −0.27 | −0.46 |
| [ppm/K] | | | | |
| TCL (0; +50° C.) | | | | |
| \|Expansion at 50° C.\| | | | | |
| Index F | | | | |
| Hyst. @ 45° C. [ppm] | | | | |
| Hyst. @ 35° C. [ppm] | | | | |
| Hyst. @ 30° C. [ppm] | | | | |
| Hyst. @ 22° C. [ppm] | <0.1 | | | |
| Hyst. @ 10° C. [ppm] | <0.1 | | | |
| Hyst. @ +5° C. [ppm] | <0.1 | | | |
| Hyst. @ 0° C. [ppm] | 0.13 | | | |
| Hyst. @ −5° C. [ppm] | 0.24 | | | |
| Ceram. temperature [° C.] | | | | |
| Ceram. duration [days] | | | | |
| Average CTE (−30; +70° C.)[ppm/K] | | | | |
| Average CTE (−40; +80° C.)[ppm/K] | | | | |

Compositions, ceramization and properties (mol %)

| | Comparative Example No. (Comp. ex.) | | | | | |
|---|---|---|---|---|---|---|
| | 7 | 8 | 9 | 10 | 11 | 12 |
| Li₂O | 8.5 | 7.78 | 9.32 | 9.2 | 9.4 | 9.0 |
| Na₂O | 0.1 | 0.8 | | 0.1 | 0.2 | 0.1 |
| K₂O | 0.5 | | | | | |
| MgO | 1.8 | | 1.2 | 1.6 | 1.2 | 1.6 |
| ZnO | 1.3 | 1.8 | 0.4 | 0.6 | 0.6 | 0.4 |
| CaO | | 2.42 | 1.0 | 1.2 | 1.0 | 1.3 |
| BaO | | 1.07 | 0.36 | 0.4 | 0.3 | 0.5 |
| SrO | | | | | | |
| Aₗ2O₃ | 16.9 | 15.39 | 19.11 | 16.2 | 19.0 | 16.4 |
| SiO₂ | 64.3 | 65.42 | 61.4 | 63.3 | 61.4 | 63.9 |
| P₂O₅ | 3.4 | 2.47 | 3.97 | 3.8 | 3.9 | 3.5 |
| TiO₂ | 1.9 | 1.67 | 1.92 | 2.2 | 1.9 | 2.1 |
| ZrO₂ | 1.1 | 0.92 | 1.07 | 1.1 | 1.1 | 1.2 |
| As₂O₃ | 0.2 | 0.26 | 0.25 | 0.2 | 0.2 | 0.1 |
| Sum | 100.0 | 100.0 | 100.0 | 100.0 | 100.0 | 100.1 |
| SiO₂ + (5 × Li₂O) | | | | | | |
| MgO + ZnO | 3.1 | 1.8 | 1.6 | 2.2 | 1.8 | 2.0 |
| ΣR₂O (R = Na, K, Cs, Rb) | 0.6 | 0.8 | | 0.1 | 0.2 | 0.1 |
| ΣRO (R = Ca, Ba, Sr) | | 3.49 | 1.36 | 1.6 | 1.3 | 1.8 |
| Va [° C.] | | | | | | |
| Ceram. temperature [° C.] | 810 | | | 760 | 810 | 760 |
| Ceram. duration [days] | 10 | | | 10 | 5 | 10 |
| Cryst. phase [% by volume] | 76 | | | | | |
| Cryst. size [nm] | 72 | | | | | |
| Average CTE(0; +50° C.) | 0.03 | 0.02 | 0.002 | −0.15 | 0.03 | −0.05 |
| [ppm/K] | | | | | | |
| TCL (0; +50° C.) | | | 1.19 | 3.68 | 1.32 | 0.35 |
| \|Expansion at 50° C.\| | | | 0.11 | 3.68 | 1.28 | 0.35 |
| Index F | | | 10.82 | 1.00 | 1.03 | 1.00 |
| Hyst. @ 45° C. [ppm] | 0.11 | <0.1 | <0.1 | <0.1 | <0.1 | <0.1 |
| Hyst. @ 35° C. [ppm] | 0.14 | <0.1 | 0.12 | <0.1 | <0.1 | <0.1 |
| Hyst. @ 30° C. [ppm] | 0.18 | <0.1 | 0.16 | <0.1 | 0.1 | 0.11 |
| Hyst. @ 22° C. [ppm] | 0.27 | 0.14 | 0.24 | 0.14 | 0.16 | 0.17 |
| Hyst. @ 10° C. [ppm] | 0.61 | 0.42 | 0.54 | 0.38 | 0.85 | 0.43 |
| Hyst. @ +5° C. [ppm] | 0.85 | 0.61 | 0.74 | 0.56 | 0.61 | 0.61 |
| Hyst. @ 0° C. [ppm] | 1.1 | 0.81 | 0.92 | 0.76 | 0.85 | 0.82 |
| Hyst. @ −5° C. [ppm] | 1.2 | 0.96 | 1.16 | 0.93 | 1.04 | 0.97 |
| Ceram. temperature [° C.] | | | | | | |
| Ceram. duration [days] | | | | | | |
| Average CTE (−30; +70° C.)[ppm/K] | | | | | | |
| Average CTE (−40; +80° C.)[ppm/K] | | | | | | |

Compositions, ceramization and properties (mol %)

| | Comparative Example No. (Comp. ex.) | | | |
|---|---|---|---|---|
| | 13 | 14 | 15 | 16 |
| Li₂O | 8.4 | 8.2 | 9.4 | 9.3 |
| Na₂O | 0.05 | 0.35 | 0.1 | 0.25 |
| K₂O | | | 0.6 | 0.25 |
| MgO | | | 1.8 | |
| ZnO | 0.95 | 1.2 | | 0.60 |
| CaO | 2.3 | 2.35 | | 1.0 |
| BaO | | | | 0.85 |
| SrO | | | | |
| Al₂O₃ | 16.55 | 16.5 | 17 | 18.95 |
| SiO₂ | 65.15 | 64.8 | 64.4 | 61.5 |
| P₂O₅ | 3.4 | 3.3 | 3.5 | 4.05 |
| TiO₂ | 2.0 | 2.0 | 1.95 | 2.05 |
| ZrO₂ | 1.1 | 1.1 | 1.05 | 1.05 |
| As₂O₃ | 0.15 | 0.2 | 0.2 | 0.15 |
| Sum | 100.0 | 100.0 | 100.0 | 100.0 |
| SiO₂ + (5 × Li₂O) | | | | |
| MgO + ZnO | 0.95 | 1.2 | 1.8 | 0.60 |
| ΣR₂O (R = Na, K, Cs, Rb) | 0.05 | 0.35 | 0.7 | 0.50 |
| ΣRO (R = Ca, Ba, Sr) | 2.25 | 2.35 | | 1.85 |
| Va [° C.] | | | | |
| Ceram. temperature [° C.] | 770 | 810 | 790 | 830 |
| Ceram. duration [days] | 5 | 1 | 5 | 2.5 |
| Cryst. phase [% by volume] | 73 | 69 | 74 | 66 |
| Cryst. size [nm] | 43 | 47 | 56 | 41 |
| Average CTE(0; +50° C.) | −0.03 | −0.08 | −0.06 | 0.07 |
| [ppm/K] | | | | |
| TCL (0; +50° C.) | | | | 4.29 |
| \|Expansion at 50° C.\| | | | | 3.55 |
| Index F | | | | 1.21 |
| Hyst. @ 45° C. [ppm] | <0.1 | <0.1 | <0.1 | <0.1 |
| Hyst. @ 35° C. [ppm] | <0.1 | <0.1 | <0.1 | <0.1 |
| Hyst. @ 30° C. [ppm] | <0.1 | <0.1 | <0.1 | <0.1 |
| Hyst. @ 22° C. [ppm] | 0.13 | <0.1 | 0.16 | <0.1 |
| Hyst. @ 10° C. [ppm] | 0.44 | 0.3 | 0.44 | 0.15 |
| Hyst. @ +5° C. [ppm] | 0.67 | 0.55 | 0.63 | 0.23 |
| Hyst. @ 0° C. [ppm] | 0.97 | 0.84 | 0.85 | 0.35 |
| Hyst. @ −5° C. [ppm] | 1.3 | 1.13 | 1.0 | 0.5 |
| Ceram. temperature [° C.] | | | | |
| Ceram. duration [days] | | | | |
| Average CTE (−30; +70° C.)[ppm/K] | | | | |
| Average CTE (−40; +80° C.)[ppm/K] | | | | |

TABLE 3a
Alternative index f_{T.i.} for selected ex. from Table 1a and comp. ex.

| f_{T.i.} | Ti-dop. | | | | | | |
|---|---|---|---|---|---|---|---|
| [ppm/K] | SiO₂ | Ex. 6 | Ex. 7 | Ex. 12 | Ex. 14 | Ex. 17 | Ex. 18 |
| 20-40° C. | 0.024 | 0.010 | 0.009 | | 0.014 | 0.012 | 0.016 |
| 20-70° C. | 0.039 | 0.011 | 0.010 | 0.023 | 0.038 | 0.014 | 0.022 |
| −10-30° C. | 0.015 | | 0.004 | 0.011 | 0.006 | | |

TABLE 3b
Alternative index f_{T.i.} for selected ex. from Table 1b and comp. ex.

| f_{T.i.} | Ti-dop. | | | |
|---|---|---|---|---|
| [ppm/K] | SiO₂ | Ex. 6b | Ex. 7b | Ex. 9b |
| 20-40° C. | 0.024 | 0.004 | 0.0015 | 0.007 |
| 20-70° C. | 0.039 | 0.0036 | 0.005 | 0.023 |
| −10-30° C. | 0.015 | 0.003 | 0.012 | |

CTE Homogeneity

The components on which tests for determining the respective CTE homogeneity were carried out were prepared by taking the measures for increasing CTE homogeneity which are mentioned in WO 2015/124710 A1.

In accordance with the compositions mentioned in connection with the glass ceramics of example 7 in Table 1a and example 6b in Table 1b, the green glasses were first melted in a 28 m³ melting tank over a period of several days, the temperature being kept at about 1600° C. The decomposition of As₂O₃ or Sb₂O₃ gives rise to refining gases which entrain small gaseous inclusions and homogenize the melt. During the refining phase and during a subsequent cooling phase, the glass melt is further homogenized. In particular, by controlling the temperature of the tank surface, convection of the melt is induced in order to promote homogenization. During a subsequent cooling phase, which may likewise take several days, the temperature of the glass melt is reduced to approximately 1400° C. and then poured into molds having an edge length of 1.7 m and a height of 500 mm.

Ceramization was carried out under the following conditions:

First, the respective green glass block (or blank) was heated to a temperature between 630 and 680° C. at a heating rate of 0.5° C./h. The heating rate was then reduced to 0.01° C./h and heating was continued until a temperature of from 770 to 830° C. was reached. This temperature was maintained for about 60 hours. The blanks were then cooled to room temperature at a cooling rate of −1° C./h.

After removal of the edge regions, blocks in the following dimensions were cut from the glass ceramics produced in this way:
500×500×100 mm
700×700×200 mm
1400×1400×300 mm

The CTE homogeneity of the ceramized blocks obtained was determined as described below.

To determine the CTE homogeneity(0:50) and the CTE homogeneity(19:25) in the components, 64 samples were in each case cut from the respective glass ceramic component, these being measured separately. The CTE(0;50) was determined for each of the 64 samples of a component and the CTE(19;25) was determined for a further 64 samples. The thermal expansion of a sample taken was determined by a static method in which the length of the respective sample was determined at the beginning and at the end of the specific temperature interval, i.e. from 0° C. to 50° C. or from 19° C. to 25° C., and the average expansion coefficient α or CTE was calculated from the difference in length. The CTE is then indicated as the average for this temperature interval, e.g. for the temperature interval of from 0° C. to 50° C. as CTE(0;50) or α(0;50) or for the temperature interval of from 19° C. to 25° C. as CTE(19;25). Subsequently, the difference between the highest and lowest CTE(0;50) or the highest and the lowest CTE(19;25) was determined (peak-to-valley value). The lower this difference is (e.g. 3 ppb), the lower the CTE variance within the components investigated and the higher the CTE homogeneity.

The CTE homogeneities determined for the temperature ranges of from 0 to 50° C. and 19 to 25° C. are summarized in Tables 4a and 4b.

TABLE 4a

| | Example 7-1 | | Example 7-2 | | Example 7-3 | |
|---|---|---|---|---|---|---|
| Dimensions of glass ceramic | (500 × 500 × 100) | | (700 × 700 × 200) | | (1400 × 1400 × 300) | |
| component | mm | | mm | | mm | |
| (Width × Depth × Height) | | | | | | |
| Modulus of elasticity | 90 | GPa | 90 | GPa | 90 | GPa |
| Average CTE(0; 50) [ppm/K] | 0.007 | | 0.007 | | 0.007 | |
| CTE homogeneity(0; 50) | 3 | ppb/K | 4 | ppb/K | 5 | ppb/K |
| Average CTE (19; 25) | −0.002 | | −0.002 | | −0.002 | |
| [ppm/K] | | | | | | |
| CTE homogeneity(19; 25) | 2.5 | ppb/K | 3 | ppb/K | 4 | ppb/K |

| | | | |
|---|---|---|---|
| Inclusions > 0.3 mm | | | |
| Average number per | 1 | 1 | 3 |
| 100 cm³ | | | |
| Maximum size [mm] | 0.4 | 0.4 | 1.5 |

TABLE 4b

| | Example 6b-1 | | Example 6b-2 | | Example 6b-3 | |
|---|---|---|---|---|---|---|
| Dimensions of glass ceramic | (500 × 500 × 100) | | (700 × 700 × 200) | | (1400 × 1400 × 300) | |
| component | mm | | mm | | mm | |
| (Width × Depth × Height) | | | | | | |
| Modulus of elasticity | 90 | GPa | 90 | GPa | 90 | GPa |
| Average CTE (0; 50) | 0.000 | | 0.000 | | 0.000 | |
| [ppm/K] | | | | | | |
| CTE homogeneity(0; 50) | 3 | ppb/K | 4 | ppb/K | 5 | ppb/K |
| Average CTE (19; 25) | 0.001 | | 0.001 | | 0.001 | |
| [ppm/K] | | | | | | |
| CTE homogeneity(19; 25) | 2.5 | ppb/K | 3 | ppb/K | 4.5 | ppb/K |

| | | | |
|---|---|---|---|
| Inclusions > 0.3 mm | | | |
| Average number per | 1 | 1 | 3 |
| 100 cm³ | | | |
| Maximum size [mm] | 0.4 | 0.4 | 1.5 |

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A precision component having an average coefficient of thermal expansion (CTE) of at most 0±0.1×10⁻⁶/K in a range of from 0 to 50° C. and a thermal hysteresis of <0.1 ppm, at least in a temperature range of from 10° C. to 35° C., and an index F of <1.2, wherein F=TCL (0; 50° C.)/|expansion (0; 50° C.)|, wherein TCL is a total change of length.

2. The precision component of claim 1, wherein a CTE-T curve in a temperature interval having a width of at least 30 K has a slope of at most 0±2.5 ppb/K².

3. The precision component of claim 1, wherein a differential CTE is less than 0±0.025 ppm/K in a temperature interval T_{P} with a width of at least 40 K.

4. The precision component of claim 1, having a CTE homogeneity(0;50) of at most 5 ppb/K.

5. The precision component of claim 1, having a thermal hysteresis of <0.1 ppm, at least in a temperature range of from 5° C. to 45° C.

6. The precision component of claim 1, having a relative change in length (dl/l₀) of <|0.10| ppm in a temperature range of from 20° C. to 30° C. and/or a relative change in length (dl/l₀) of ≤|0.17| ppm in a temperature range of from 20° C. to 35° C.

7. The precision component of claim 1, having a relative change in length (dl/l₀) of <|0.30| ppm in a temperature range of from 20° C. to 40° C.

8. The precision component of claim 1, comprising at least one inorganic material selected from the group consisting of doped quartz glass, glass ceramic and ceramic, Ti-doped quartz glass, lithium aluminum silicate glass ceramic, and cordierite.

9. The precision component of claim 1, comprising a lithium aluminum silicate glass ceramic comprising the following components (in mol % on an oxide basis):

| | |
|---|---|
| SiO₂ | 60-71; |
| Li₂O | 7-9.4; |
| MgO + ZnO | 0-<0.6; |

at least one component selected from the group consisting of P₂O₅, R₂O, and RO, wherein R₂O is Na₂O and/or K₂O and/or Cs₂O and/or Rb₂O, wherein RO is CaO and/or BaO and/or SrO; and
nucleating agent having a content of 1.5 to 6 mol %, wherein the nucleating the agent is at least one component selected from the group consisting of TiO₂, ZrO₂, Ta₂O₅, Nb₂O₅, SnO₂, MoO₃, WO₃.

10. The precision component of claim 1, wherein the precision component is selected from the group consisting of mirrors or mirror supports for a segmented or monolithic astronomical telescope, a reduced-weight or ultralight mirror substrates for a space-based telescope, high-precision structural components for distance measurement, standards for precision measurement technology, precision rules, reference plates in interferometers, ring laser gyroscopes, spiral spring for the watch and clock making industry, prisms, mask holders, wafer tables, reference plates, reference frames, grid plates, photo mask substrates, reticle mask blanks, and mask blanks.

11. A precision component having an average coefficient of thermal expansion CTE of at most 0±0.1×10⁻⁶/K in a range of from 0 to 50° C. and a thermal hysteresis of <0.1 ppm, at least in a temperature range of from 10° C. to 35° C., and an alternative index f_{T.i.} selected from the group consisting of alternative index f_{(20;40)}<0.024 ppm/K, alternative index f_{(20;70)}<0.039 ppm/K, and alternative index f_{(-10;30)}<0.015 ppm/K.

12. The precision component of claim 11, wherein a CTE-T curve in a temperature interval having a width of at least 30 K has a slope of at most 0±2.5 ppb/K².

13. The precision component of claim 11, wherein a differential CTE is less than 0±0.025 ppm/K in a temperature interval T_{P} with a width of at least 40 K.

14. The precision component of claim 11, having a CTE homogeneity(0;50) of at most 5 ppb/K.

15. The precision component of claim 11, having a thermal hysteresis of <0.1 ppm, at least in a temperature range of from 5° C. to 45° C.

16. The precision component of claim 11, having a relative change in length (dl/l₀) of <|0.101 ppm in a temperature range of from 20° C. to 30° C. and/or a relative change in length (dl/l₀) of ≤|0.17| ppm in a temperature range of from 20° C. to 35° C.

17. The precision component of claim 11, having a relative change in length (dl/l₀) of ≤|0.30| ppm in a temperature range of from 20° C. to 40° C.

18. The precision component of claim 11, comprising at least one inorganic material selected from the group consisting of doped quartz glass, glass ceramic and ceramic, Ti-doped quartz glass, lithium aluminum silicate glass ceramic, and cordierite.

19. The precision component of claim 11, comprising a lithium aluminum silicate glass ceramic comprising the following components (in mol % on an oxide basis):

| | |
|---|---|
| SiO₂ | 60-71; |
| Li₂O | 7-9.4; |
| MgO + ZnO | 0-<0.6; |

at least one component selected from the group consisting of P₂O₅, R₂O, and RO, wherein R₂O is Na₂O and/or K₂O and/or Cs₂O and/or Rb₂O, wherein RO is CaO and/or BaO and/or SrO; and
nucleating agent having a content of 1.5 to 6 mol %, wherein the nucleating the agent is at least one component selected from the group consisting of TiO₂, ZrO₂, Ta₂O₅, Nb₂O₅, SnO₂, MoO₃, WO₃.

20. The precision component of claim 11, wherein the precision component is selected from the group consisting of mirrors or mirror supports for a segmented or monolithic astronomical telescope, a reduced-weight or ultralight mirror substrates for a space-based telescope, high-precision structural components for distance measurement, standards for precision measurement technology, precision rules, reference plates in interferometers, ring laser gyroscopes, spiral spring for the watch and clock making industry, prisms, mask holders, wafer tables, reference plates, reference frames, grid plates, photo mask substrates, reticle mask blanks, and mask blanks.
